(19) United States
(12) Patent Application Publication
(10) Pub. No.: US 2024/0276865 A1
(43) Pub. Date: Aug. 15, 2024

(54) ORGANOMETALLIC IRIDIUM COMPOUND AND APPLICATION THEREOF

(71) Applicant: GUANGDONG AGLAIA OPTOELECTRONIC MATERIALS CO., LTD., Foshan, Guangdong (CN)

(72) Inventors: Liangliang YAN, Foshan (CN); Fei NIE, Foshan (CN); Kangzhi YE, Foshan (CN); Lei DAI, Foshan (CN); Lifei CAI, Foshan (CN)

(73) Assignee: GUANGDONG AGLAIA OPTOELECTRONIC MATERIALS CO., LTD., Foshan, Guangdong (CN)

(21) Appl. No.: 18/562,194

(22) PCT Filed: Feb. 26, 2022
(86) PCT No.: PCT/CN2022/078119

§ 371 Date: Nov. 17, 2023

(30) Foreign Application Priority Data
Jun. 18, 2021 (CN) 202110676210.2

(51) Int. Cl. H10K 85/30; C07F 15/00; C09K 11/06; H10K 50/12

(52) U.S. Cl. CPC H10K 85/342; C07F 15/0033; C09K 11/06; C09K 2211/1033; C09K 2211/185; H10K 50/12

(57) ABSTRACT

The present invention relates to an organometallic iridium compound and application thereof. The organometallic iridium compound has a general formula of Ir(La)(Lb)(Lc), where La is a structure represented by Formula (1), and Lb is a structure represented by Formula (2). The compound provided by the present invention has the advantages of high optical and electrical stability, low sublimation temperature, small emission half-peak width, high color saturation, high luminous efficiency, long device life and the like, and can be used in organic electroluminescent devices. In particular, the compound has the potential for application in the AMOLED industry as a red light-emitting dopant, especially in display, lighting and automobile taillights.

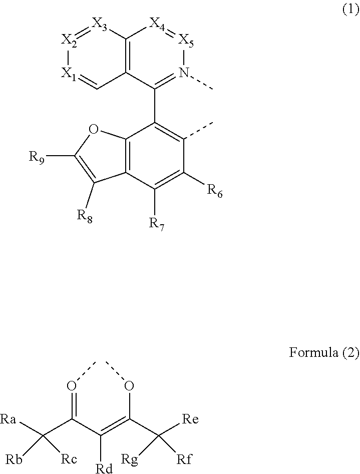

### TECHNICAL FIELD

The present invention relates to the technical field of organic electroluminescence, in particular to an organic light-emitting material applicable to organic electroluminescent devices, and specially relates to an organometallic iridium compound and application thereof in an organic electroluminescent device.

### BACKGROUND

At present, as a new-generation display technology, an organic electroluminescent device (OLED) has attracted more and more attention in display and lighting technologies, thus having a wide application prospect. However, compared with market application requirements, properties, such as luminous efficiency, driving voltage and service life, of the OLED still need to be strengthened and improved.

In generally, the OLED includes various organic functional material films with different functions sandwiched between metal electrodes as a basic structure, which is similar to a sandwich structure. Under the driving of a current, holes and electrons are injected from a cathode and an anode, respectively. After moving to a certain distance, the holes and the electrons are compounded in a light-emitting layer, and then released in the form of light or heat to achieve luminescence of the OLED.

However, organic functional materials are core components of the OLED, and the thermal stability, photochemical stability, electrochemical stability, quantum yield, film forming stability, crystallinity, color saturation and the like of the materials are main factors affecting properties of the device.

Generally, the organic functional materials include fluorescent materials and phosphorescent materials. The fluorescent materials are usually organic small-molecule materials, which can only utilize 25% of a singlet state for luminescence, so that the luminous efficiency is relatively low. Meanwhile, due to an earth-spin orbit coupling effect caused by a heavy atom effect, the phosphorescent materials can utilize 25% of a singlet state and can also utilize 75% of the energy of triplet excitons, so that the luminous efficiency can be improved. However, compared with the fluorescent materials, the phosphorescent materials are developed later, and the thermal stability, service life, color saturation and the like of the materials need to be improved. Thus, the phosphorescent materials have become a challenging topic. Various organometallic iridium compounds have been developed to serve as the phosphorescent materials. For example, a non-patent document published by Chou et al. in 2005 (Inorg. Chem. 2005, 44, 5677-5685) discloses iridium-based complexes shown as

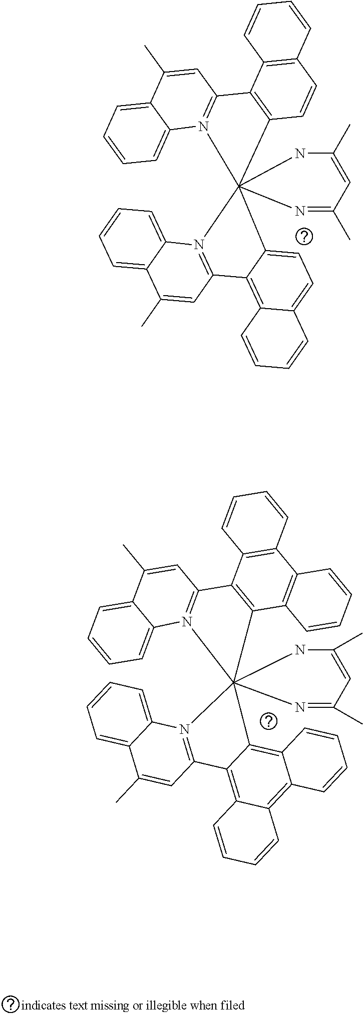

as red light-emitting materials. However, the two materials have extremely low luminous efficiency and extremely high operating voltage, which need to be further improved. A non-patent document published by Wu et al. in 2020 (Dalton. Trans. 2020, 49, 15633-156450) discloses platinum-based complexes shown as

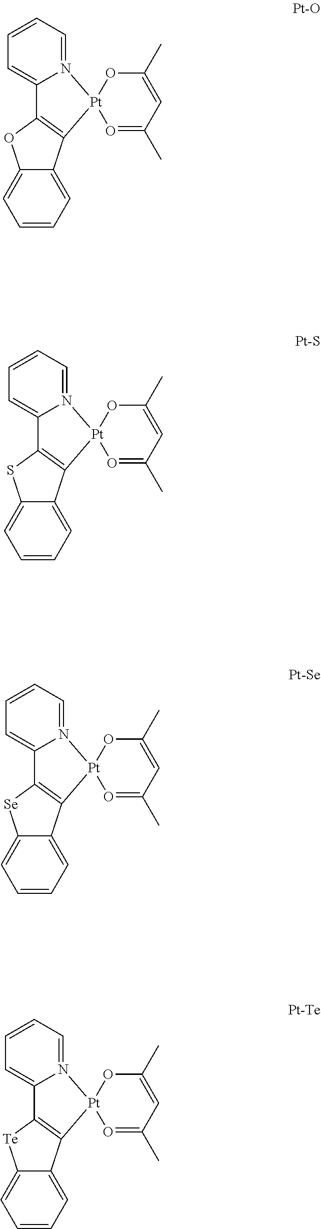

as red light-emitting materials.

Similarly, such materials have extremely low luminous efficiency and extremely high operating voltage. Moreover, such materials have many shoulder peaks at emission peaks, which are not conducive to improvement of the chromatographic purity and efficiency of a device and need to be further improved. A patent document (CN107892702) discloses iridium-based or platinum-based complexes with

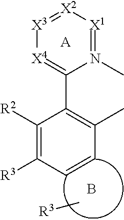

as a ligand. However, the operating voltage, device luminous efficiency and chromatographic purity of such materials need to be further improved. A patent document (KR101630317) discloses an iridium complex

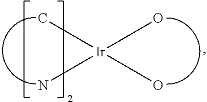

where

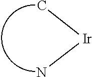

is

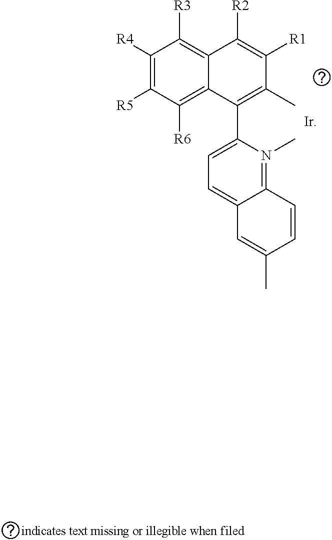

However, such material also has the problems of high device voltage, low current efficiency, low chromatographic purity and the like, which need to be improved. A patent document (KR10069600) discloses a naphthyl-isoquinoline iridium complex

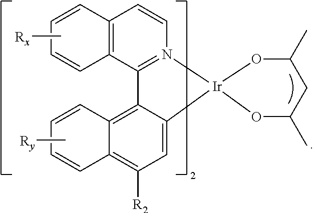

Such material also has the problems of high device voltage, low current efficiency, low chromatographic purity and the like, which need to be improved. A patent document (CN110041372) discloses

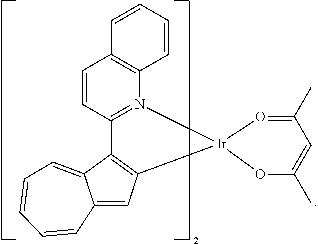

However, such compound has high device voltage, low current efficiency and too large emission wavelength not in a visible light region for human eyes, which is not applicable to the technical field of display. A patent document (CN111377969) discloses a dibenzofuran-isoquinoline iridium complex

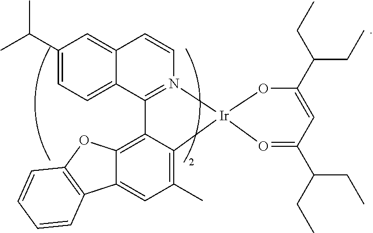

However, such material has a color saturation, CIE (x, y), of about 0.68, 0.32, which needs to be further improved.

### SUMMARY

In order to overcome the above disadvantages, the present invention provides an organic electroluminescent device with high properties and an organometallic iridium compound material capable of realizing the organic electroluminescent device.

An organometallic iridium compound of the present invention has a general formula of Ir(La)(Lb)(Lc), where La is a structure represented by Formula (1), and Lb is a structure represented by Formula (2). The iridium complex provided by the present invention has the advantages of high optical and electrical stability, low sublimation temperature, small emission half-peak width, high color saturation, high luminous efficiency, long device life and the like, and can be used in organic electroluminescent devices. In particular, the compound has the potential for application in the AMOLED industry as a red light-emitting dopant, especially in display, lighting and automobile taillights.

An organometallic iridium compound has a general formula of Ir(La)(Lb)(Lc), where La is a structure represented by Formula (1):

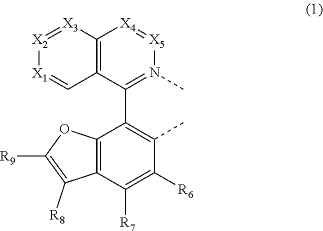

where dotted lines refer to positions connected to the metal Ir;
X₁ is N or CR₁, X₂ is N or CR₂, X₃ is N or CR₃, X₄ is N or CR₄, and X₅ is N or CR₅;
R₁-R₅ are independently selected from hydrogen, deuterium, halogen, cyano, substituted or unsubstituted C₁-C₁₀ alkyl, substituted or unsubstituted C₁-C₁₀ heteroalkyl, substituted or unsubstituted C₃-C₂₀ cycloalkyl, substituted or unsubstituted C₂-C₁₀ alkenyl, substituted or unsubstituted C₂-C₁₀ alkynyl, substituted or unsubstituted C₆-C₁₈ aryl, substituted or unsubstituted C₂-C₁₇ heteroaryl, substituted or unsubstituted tri-C₁-C₁₀ alkyl silyl, substituted or unsubstituted tri-C₆-C₁₂ aryl silyl, substituted or unsubstituted di-C₁-C₁₀ alkyl mono-C₆-C₃₀ aryl silyl, and substituted or unsubstituted mono-C₁-C₁₀ alkyl di-C₆-C₃₀ aryl silyl, or any two adjacent groups of the R₁-R₅ are connected to each other to form an aliphatic ring or an aromatic ring;
at most one of the X₁-X₅ is N, and when the X₁-X₅ are CR₁—CR₅, at least one of the R₁-R₅ is not H;
R₆-R₉ are independently selected from hydrogen, deuterium, halogen, substituted or unsubstituted C₁-C₁₀ alkyl, and substituted or unsubstituted C₃-C₂₀ cycloalkyl, and the R₆ is not hydrogen, deuterium, or halogen;
the heteroalkyl and the heteroaryl at least contain one O, N or S heteroatom;
and the “substituted” as described in R₁-R₉ refers to substitution with deuterium, F, Cl, Br, C₁-C₆ alkyl, C₃-C₆ cycloalkyl, amino substituted with C₁-C₆ alkyl, cyano, isocyano, or phosphino, and the substitution ranges from a single substitution number to a maximum substitution number;

Lb is a structure represented by Formula (2):

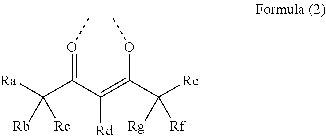

where dotted lines refer to positions connected to the metal Ir;
Ra-Rg are independently selected from hydrogen, deuterium, halogen, substituted or unsubstituted C₁-C₁₀ alkyl, substituted or unsubstituted C₃-C₂₀ cycloalkyl, substituted or unsubstituted C₁-C₁₀ heteroalkyl, and substituted or unsubstituted C₃-C₂₀ heterocyclic alkyl, or any two of the Ra, the Rb and the Rc are connected to form an aliphatic ring, and any two of the Re, the Rf and the Rg are connected to form an aliphatic ring;
the heteroalkyl and the heterocyclic alkyl at least contain one O, N or S heteroatom;
and the “substituted” as described in Ra-Rg refers to substitution with deuterium, F, Cl, Br, C₁-C₄ alkyl, C₁-C₄ alkoxyl, C₃-C₆ cycloalkyl, amino substituted with C₁-C₄ alkyl, cyano, isocyano, or phosphino;
Lc is a monoanionic bidentate ligand, and the Lc is different from the Lb and is not an OO ligand;
and the Lc and the La are the same or different, and the different indicates different parent nuclear structures, a same parent nuclear structure with different substituents, or a same parent nuclear structure with different substituent positions.

Optionally, the La is a structure represented by Formula (3):

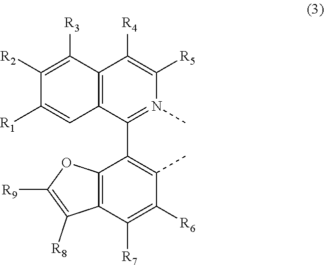

where dotted lines refer to positions connected to the metal Ir;
R₁-R₅ are independently selected from hydrogen, deuterium, halogen, cyano, substituted or unsubstituted C₁-C₁₀ alkyl, substituted or unsubstituted C₁-C₁₀ heteroalkyl, substituted or unsubstituted C₃-C₂₀ cycloalkyl, substituted or unsubstituted C₂-C₁₀ alkenyl, substituted or unsubstituted C₂-C₁₀ alkynyl, substituted or unsubstituted C₆-C₁₈ aryl, substituted or unsubstituted C₂-C₁₇ heteroaryl, substituted or unsubstituted tri-C₁-C₁₀ alkyl silyl, substituted or unsubstituted tri-C₆-C₁₂ aryl silyl, substituted or unsubstituted di-C₁-C₁₀ alkyl mono-C₆-C₃₀ aryl silyl, and substituted or unsubstituted mono-C₁-C₁₀ alkyl di-C₆-C₃₀ aryl silyl, or any two adjacent groups of the R₁-R₅ are connected to each other to form an aliphatic ring or an aromatic ring, and at least one of the R₁-R₅ is not H;
R₆-R₉ are independently selected from hydrogen, deuterium, halogen, substituted or unsubstituted C₁-C₁₀ alkyl, and substituted or unsubstituted C₃-C₂₀ cycloalkyl, and the R₆ is not hydrogen, deuterium, or halogen;
the heteroalkyl and the heteroaryl at least contain one O, N or S heteroatom;
and the “substituted” as described in R₁-R₉ refers to substitution with deuterium, F, Cl, Br, C₁-C₆ alkyl, C₃-C₆ cycloalkyl, amino substituted with C₁-C₆ alkyl, cyano, isocyano, or phosphino, and the substitution ranges from a single substitution number to a maximum substitution number.

Optionally, in Formula (3), the R₆ is substituted or unsubstituted C₁-C₆ alkyl, or substituted or unsubstituted C₃-C₁₀ cycloalkyl.

Further optionally, in Formula (3), the R₆ is substituted or unsubstituted methyl, substituted or unsubstituted isopropyl, or substituted or unsubstituted cyclopentyl; and the “substituted” as described in R₆ refers to substitution with deuterium, F, Cl, or Br.

Optionally, the R₇ is hydrogen, deuterium, or halogen.

At least one of the R₈ and the R₉ is not hydrogen. Optionally, both the R₈ and the R₉ are not hydrogen.

Further optionally, at least one of the R₈ and the R₉ is substituted or unsubstituted C₁-C₆ alkyl, or substituted or unsubstituted C₃-C₁₀ cycloalkyl.

In Formula (3), the R₂ and/or the R₅ is not hydrogen.

Optionally, in Formula (3), the R₂ is substituted or unsubstituted C₁-C₆ alkyl, or substituted or unsubstituted C₃-C₁₀ cycloalkyl, and the R₁ and the R₃-R₅ are independently selected from hydrogen.

Optionally, the Lc and the La are different.

Further optionally, the Lc is a structure represented by Formula (4):

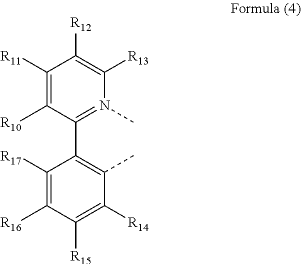

where dotted lines refer to positions connected to the metal Ir;
R₁₀-R₁₇ are independently selected from hydrogen, deuterium, halogen, cyano, hydroxyl, amino group, amino, substituted or unsubstituted C₁-C₁₀ alkyl, substituted or unsubstituted C₁-C₁₀ heteroalkyl, substituted or unsubstituted C₃-C₂₀ cycloalkyl, substituted or unsubstituted C₂-C₁₀ alkenyl, substituted or unsubstituted C₂-C₁₀ alkynyl, substituted or unsubstituted C₆-C₁₈ aryl, substituted or unsubstituted C₂-C₁₇ heteroaryl, substituted or unsubstituted tri-C₁-C₁₀ alkyl silyl, substituted or unsubstituted tri-C₆-C₁₂ aryl silyl, substituted or unsubstituted di-C₁-C₁₀ alkyl mono-C₆-C₃₀ aryl silyl, and substituted or unsubstituted mono-C₁-C₁₀ alkyl di-C₆-C₃₀ aryl silyl;
at least two of the R₁₄-R₁₇ are not hydrogen;
at least two adjacent groups of the R₁₀-R₁₃ may form an aromatic ring represented by the following Formula (5):

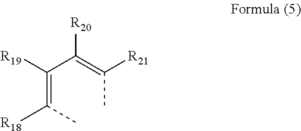

in Formula (5),
dotted lines refer to positions connected to a pyridine ring;
R₁₈-R₂₁ are independently selected from hydrogen, deuterium, halogen, cyano, substituted or unsubstituted C₁-C₁₀ alkyl, substituted or unsubstituted C₁-C₁₀ heteroalkyl, substituted or unsubstituted C₃-C₂₀ cycloalkyl, substituted or unsubstituted C₂-C₁₀ alkenyl, substituted or unsubstituted C₂-C₁₀ alkynyl, substituted or unsubstituted C₆-C₁₈ aryl, substituted or unsubstituted C₂-C₁₇ heteroaryl, substituted or unsubstituted tri-C₁-C₁₀ alkyl silyl, substituted or unsubstituted tri-C₆-C₁₂ aryl silyl, substituted or unsubstituted di-C₁-C₁₀ alkyl mono-C₆-C₃₀ aryl silyl, and substituted or unsubstituted mono-C₁-C₁₀ alkyl di-C₆-C₃₀ aryl silyl, or any two adjacent groups of the R₁₈-R₂₁ are connected to each other to form an aliphatic ring or an aromatic ring;
the heteroalkyl and the heteroaryl at least contain one O, N or S heteroatom;
and the “substituted” as described in R₁₀-R₂₁ refers to substitution with deuterium, F, Cl, Br, C₁-C₆ alkyl, C₃-C₆ cycloalkyl, amino substituted with C₁-C₆ alkyl, cyano, isocyano, or phosphino, and the substitution ranges from a single substitution number to a maximum substitution number.

As a optional organometallic iridium compound, the La optionally has one of the following structural formulas, or is partially or completely deuterated or fluorinated correspondingly.

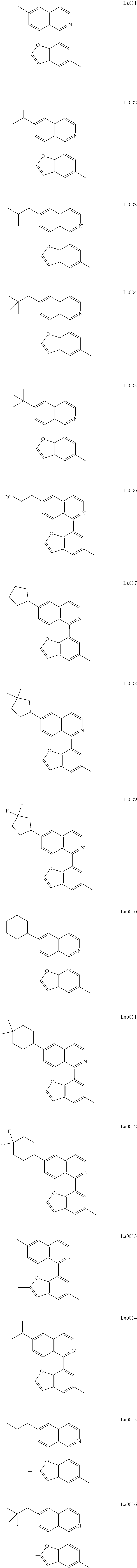

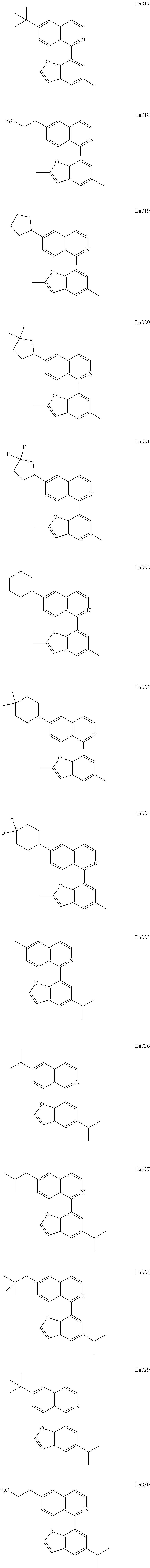

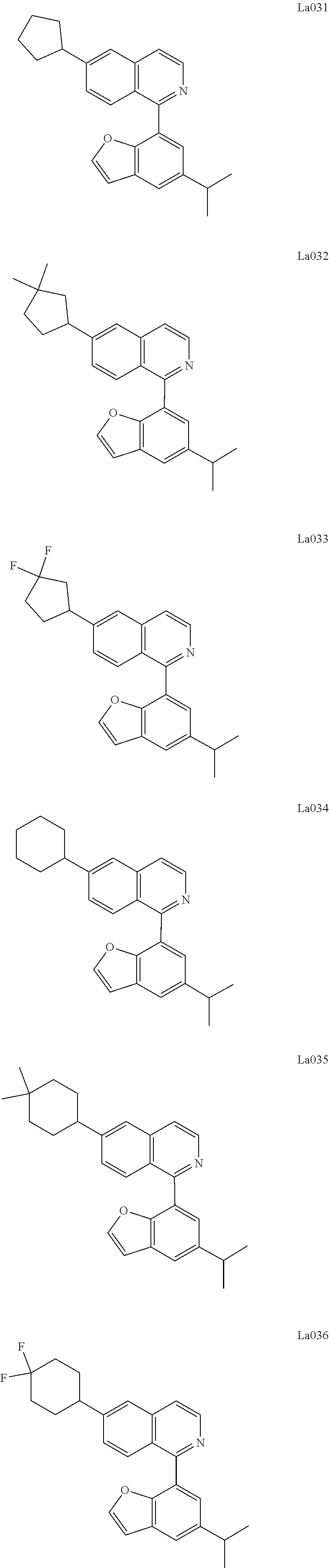

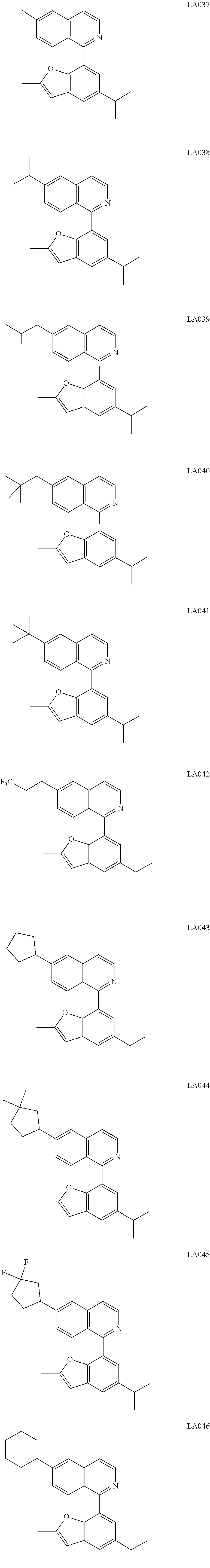

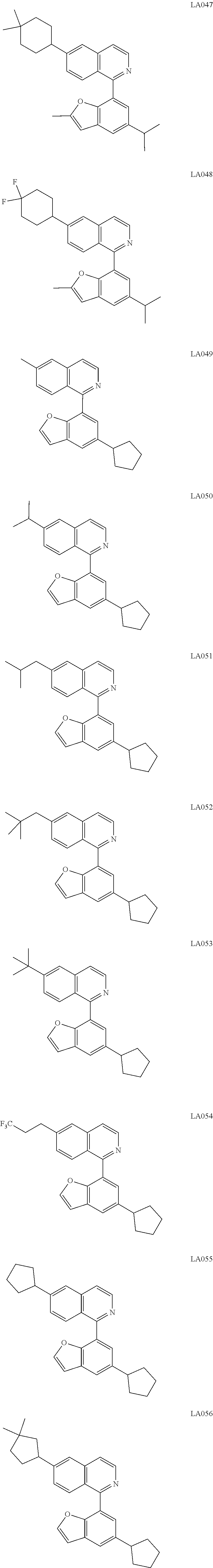

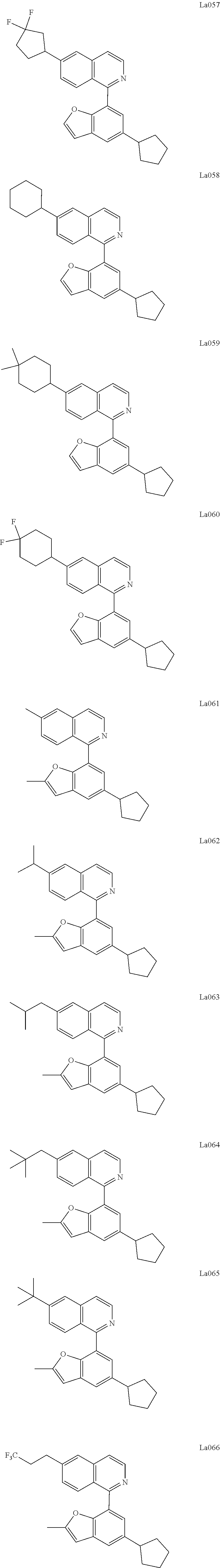

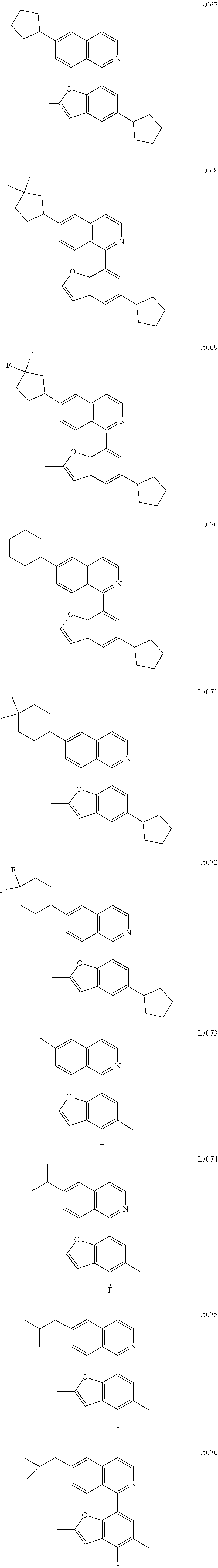

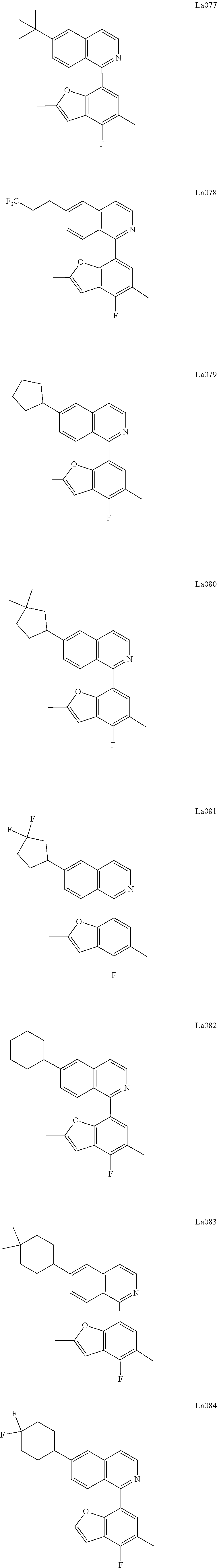

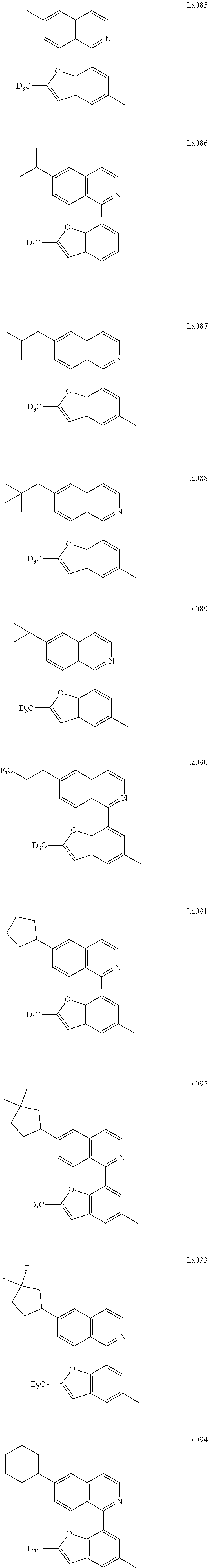

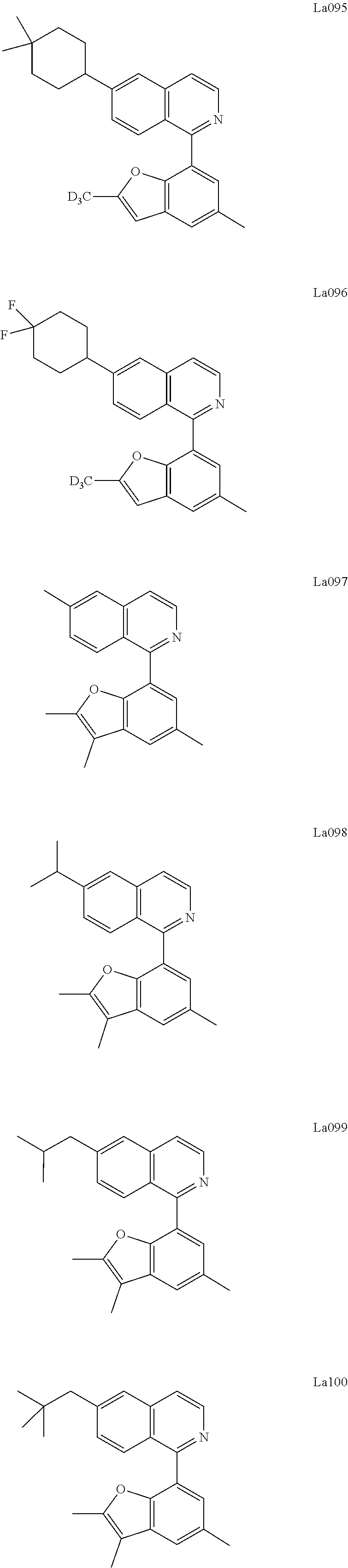

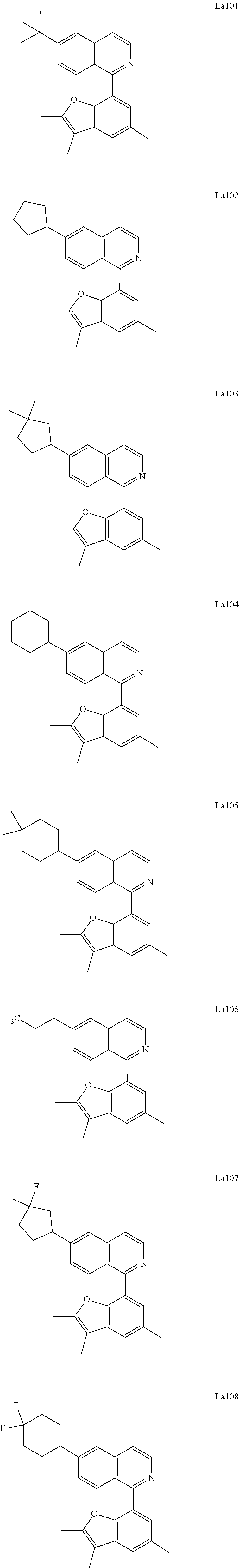

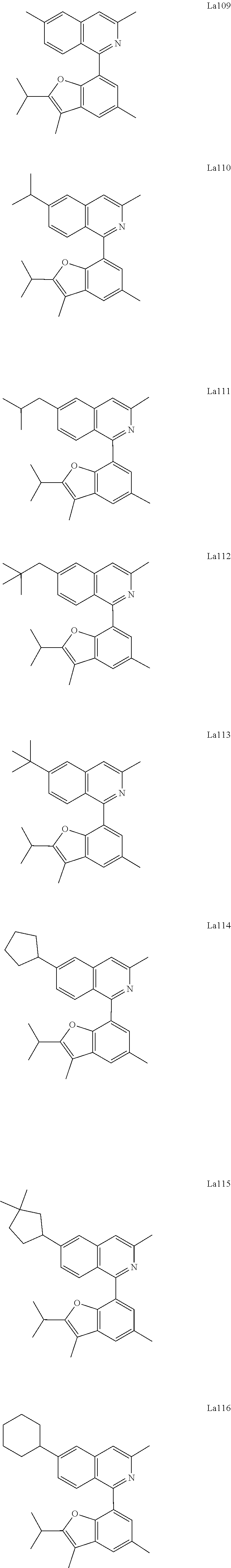

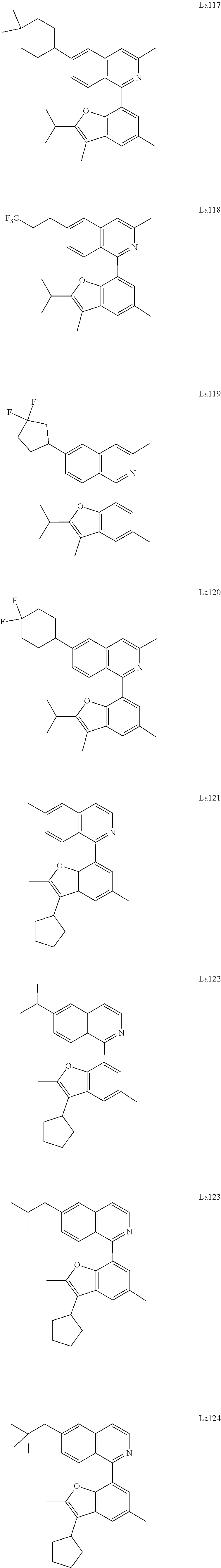

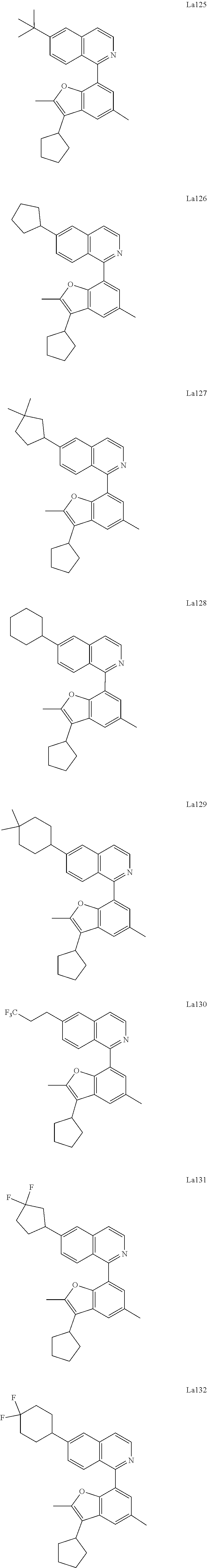

As a optional organometallic iridium compound, the Lb optionally has one of the following structural formulas, or is partially or completely deuterated or fluorinated correspondingly,

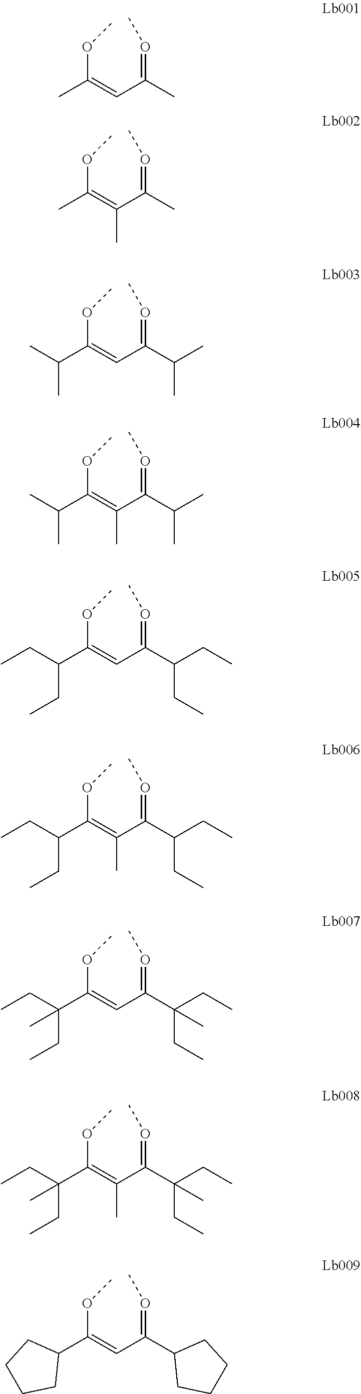

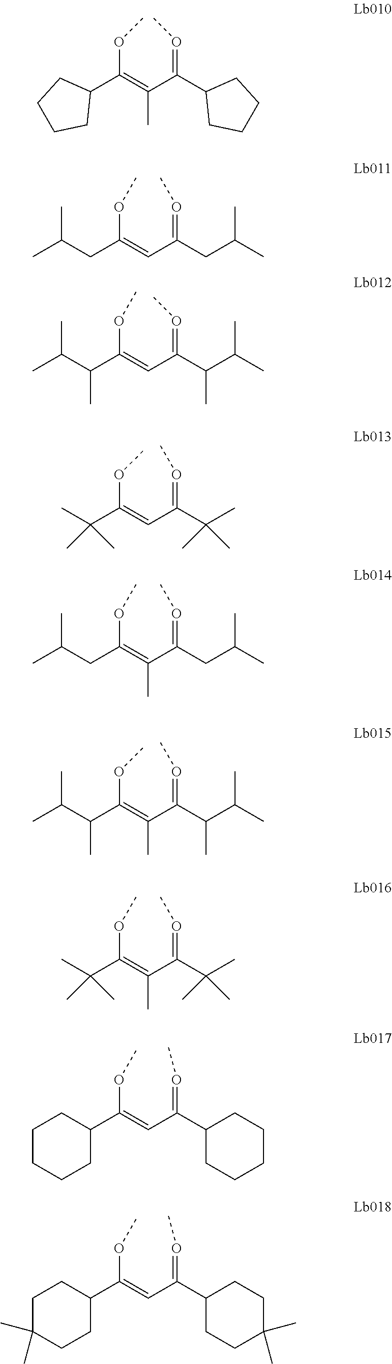

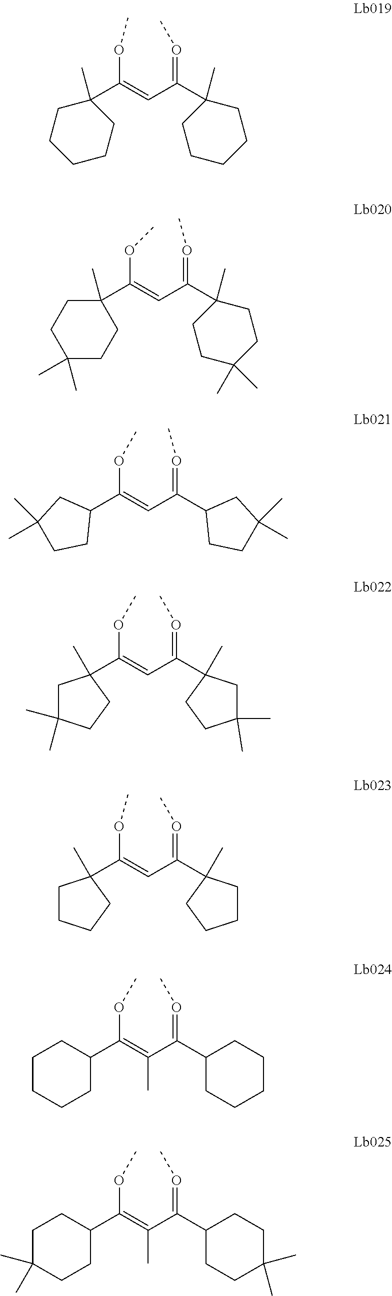

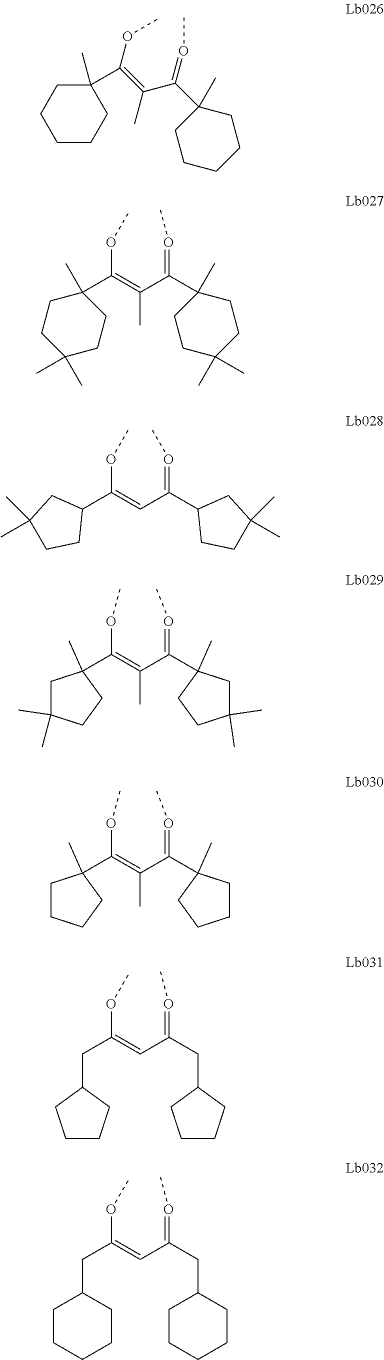

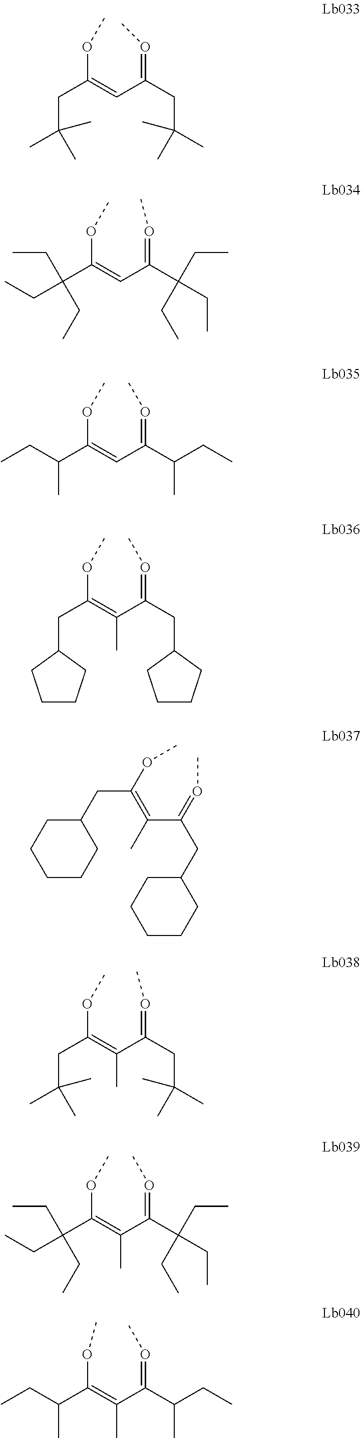

As a optional organometallic iridium compound, the Lc optionally has one of the following structural formulas, or is partially or completely deuterated or fluorinated correspondingly,

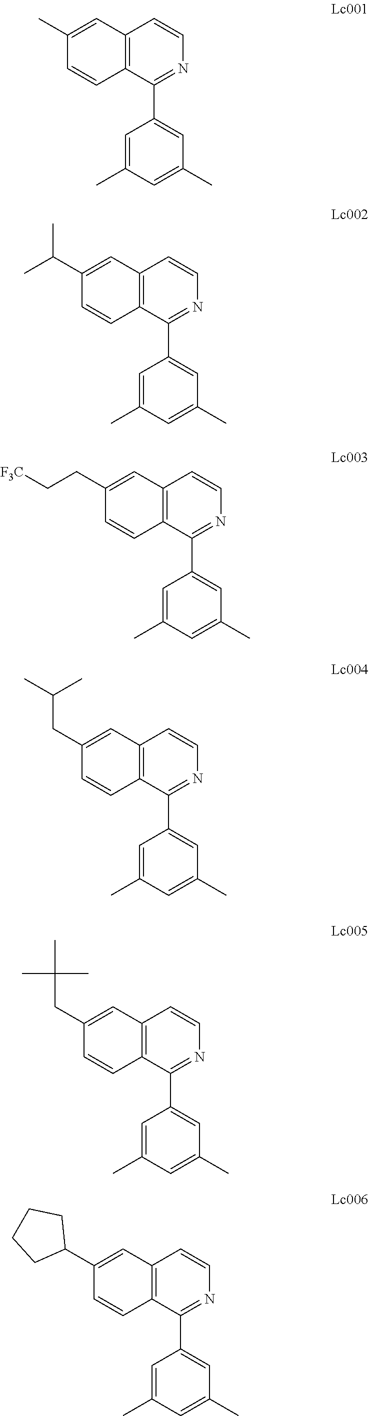

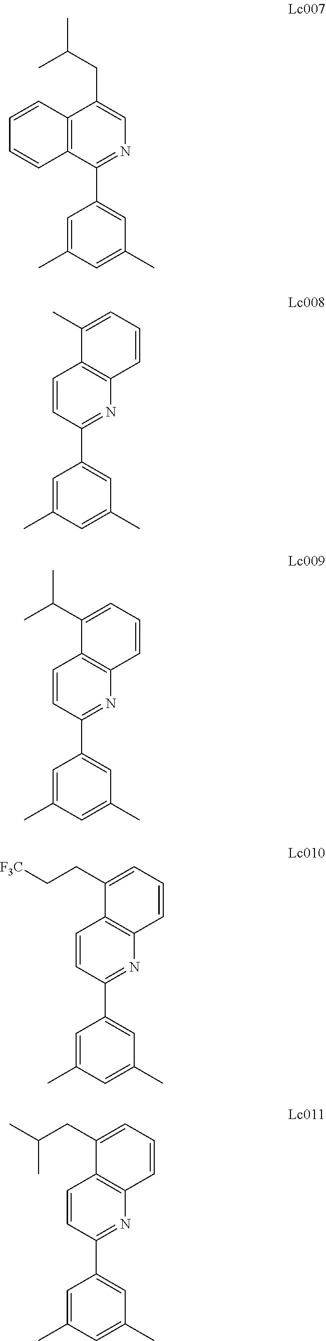

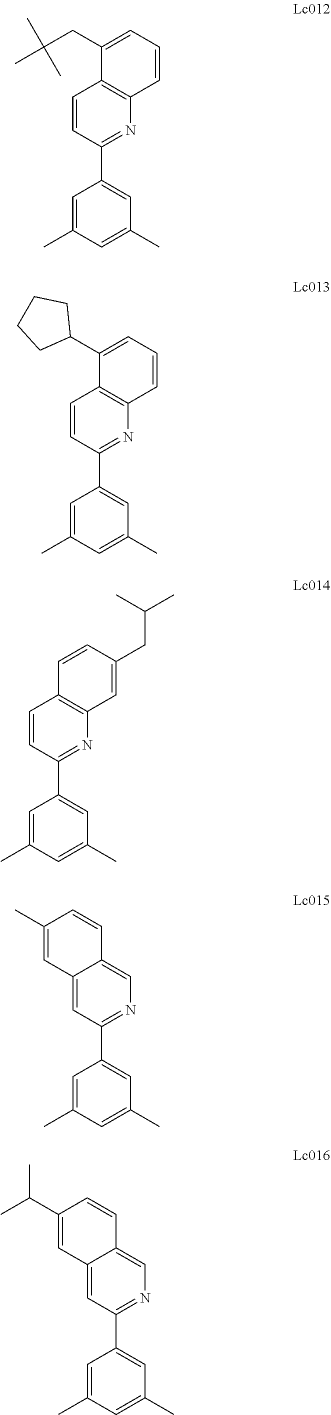

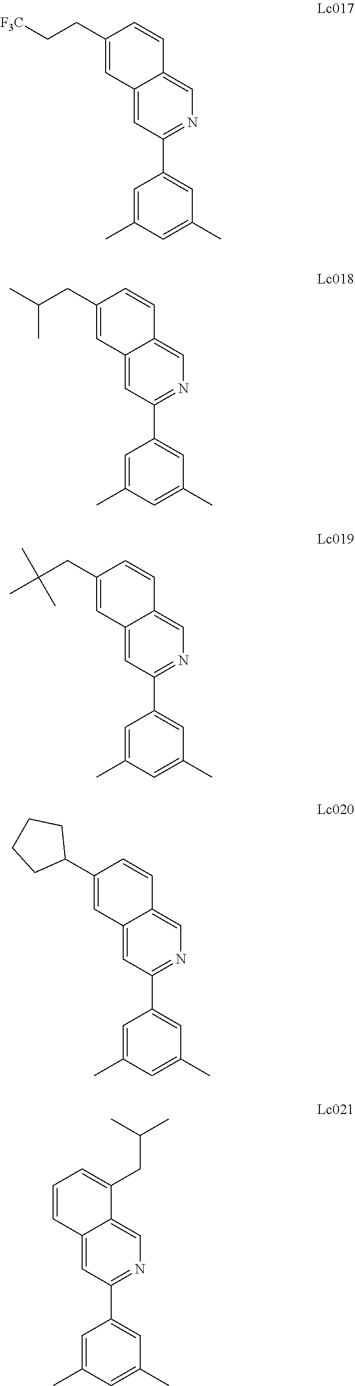

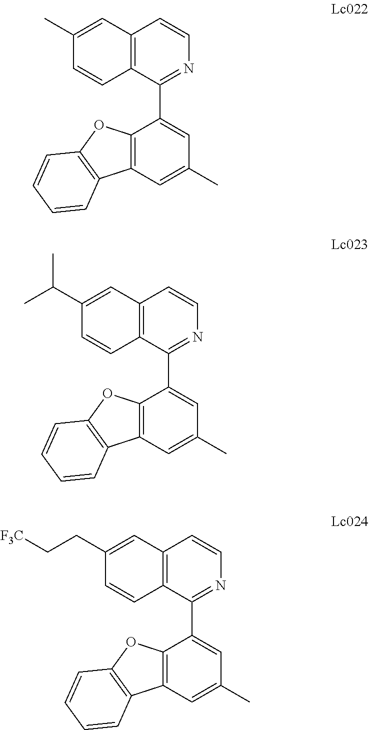

One of objectives of the present invention is to provide OLED phosphorescent material containing the compound.

One of objectives of the present invention is to provide an OLED containing the compound.

The material of the present invention has the advantages of high optical and electrical stability, low sublimation temperature, small emission half-peak width, high color saturation, high luminous efficiency, long device life and the like. As a phosphorescent material, the material of the present invention can convert a triplet excited state into light, thereby improving the luminous efficiency of organic electroluminescent devices and reducing energy consumption. In particular, the compound has the potential for application in the AMOLED industry as a red light-emitting dopant.

### BRIEF DESCRIPTION OF DRAWINGS

FIG. 1 shows the 1HNMR spectrum of a compound Ir(La002)₂(Lb005) of the present invention in a deuterated chloroform solution.

FIG. 2 shows the ultraviolet absorption spectrum and emission spectrum of a compound Ir(La002)₂(Lb005) of the present invention in a dichloromethane solution.

FIG. 3 shows the 1HNMR spectrum of a compound Ir(La003)₂(Lb005) of the present invention in a deuterated chloroform solution.

FIG. 4 shows the ultraviolet absorption spectrum and emission spectrum of a compound Ir(La003)₂(Lb005) of the present invention in a dichloromethane solution.

FIG. 5 shows the 1HNMR spectrum of a compound Ir(La007)₂(Lb005) of the present invention in a deuterated chloroform solution.

FIG. 6 shows the ultraviolet absorption spectrum and emission spectrum of a compound Ir(La007)₂(Lb005) of the present invention in a dichloromethane solution.

FIG. 7 shows the 1HNMR spectrum of a ligand La002 of the present invention in a deuterated chloroform solution.

FIG. 8 shows the 1HNMR spectrum of a ligand La003 of the present invention in a deuterated chloroform solution.

FIG. 9 shows the 1HNMR spectrum of a ligand La007 of the present invention in a deuterated chloroform solution.

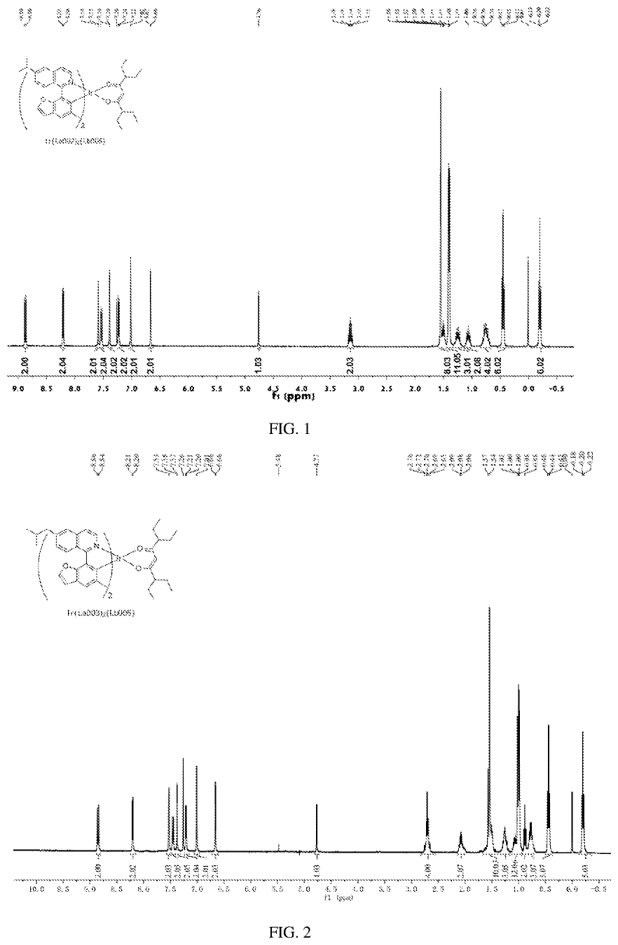

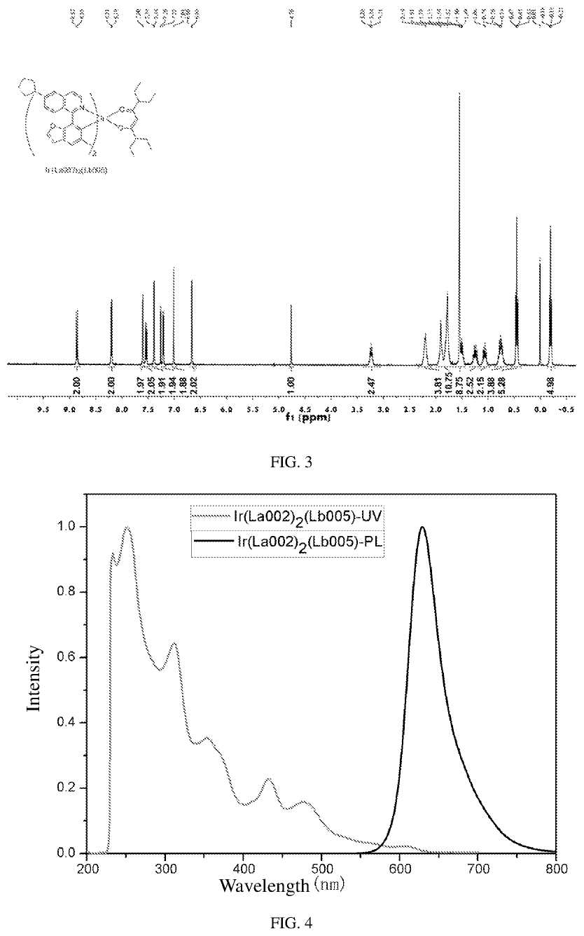

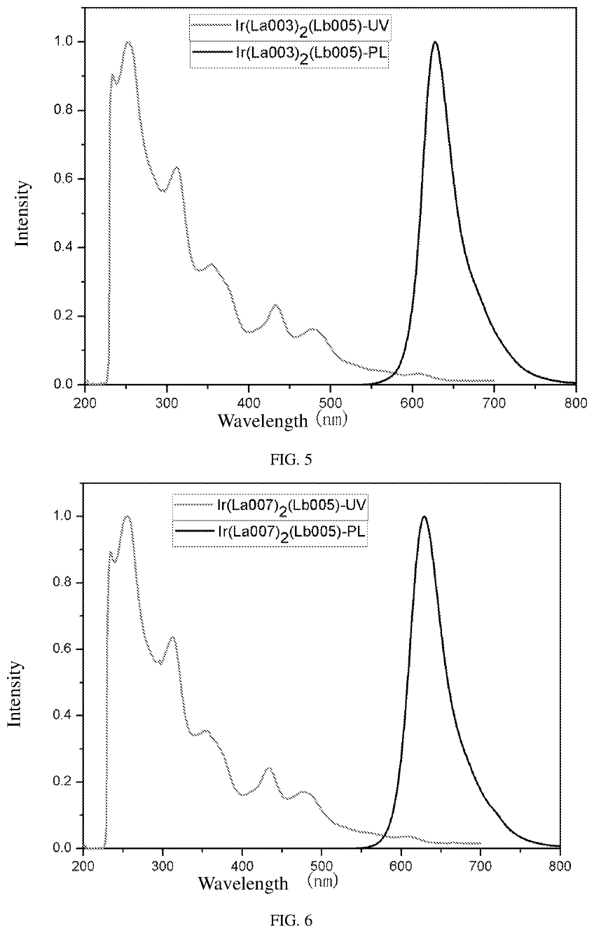

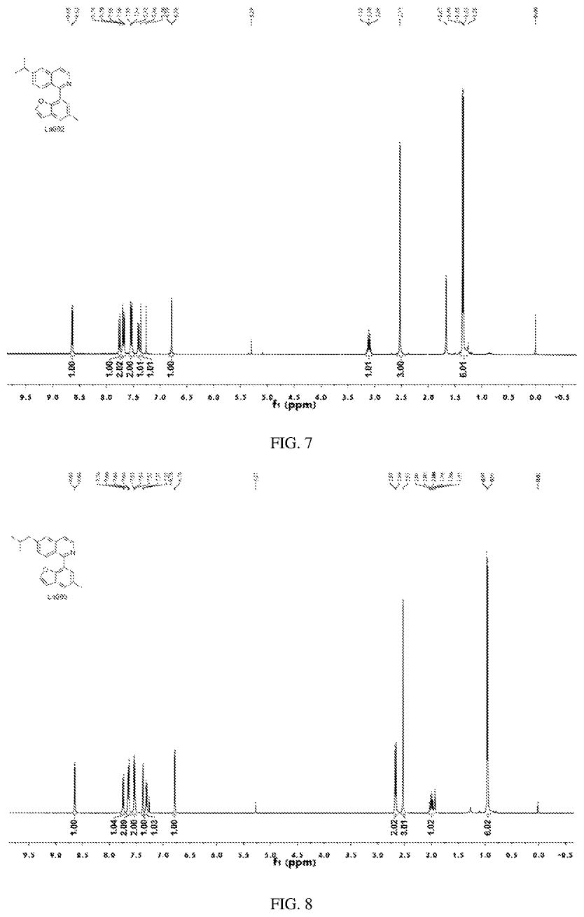

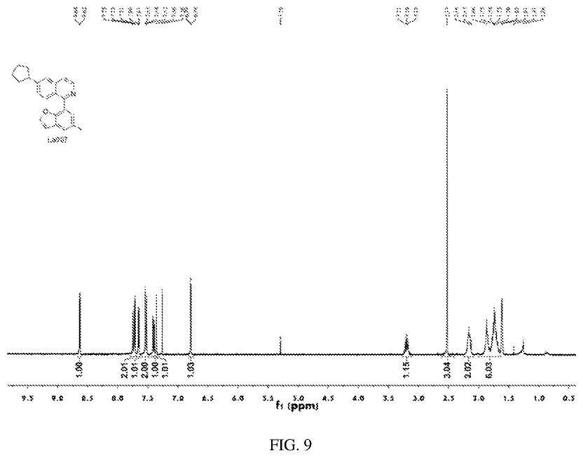

### DETAILED DESCRIPTION OF EMBODIMENTS

A compound of the present invention is an organometallic iridium compound having a general formula of Ir(La)(Lb)(Lc), where La is a structure represented by Formula (1):

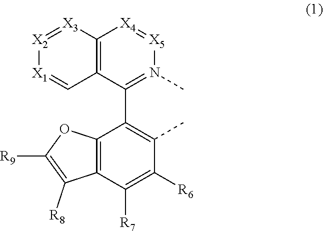

where dotted lines refer to positions connected to the metal Ir;
X₁ is N or CR₁, X₂ is N or CR₂, X₃ is N or CR₃, X₄ is N or CR₄, and X₅ is N or CR₅;
R₁-R₅ are independently selected from hydrogen, deuterium, halogen, cyano, substituted or unsubstituted C₁-C₁₀ alkyl, substituted or unsubstituted C₁-C₁₀ heteroalkyl, substituted or unsubstituted C₃-C₂₀ cycloalkyl, substituted or unsubstituted C₂-C₁₀ alkenyl, substituted or unsubstituted C₂-C₁₀ alkynyl, substituted or unsubstituted C₆-C₁₈ aryl, substituted or unsubstituted C₂-C₁₇ heteroaryl, substituted or unsubstituted tri-C₁-C₁₀ alkyl silyl, substituted or unsubstituted tri-C₆-C₁₂ aryl silyl, substituted or unsubstituted di-C₁-C₁₀ alkyl mono-C₆-C₃₀ aryl silyl, and substituted or unsubstituted mono-C₁-C₁₀ alkyl di-C₆-C₃₀ aryl silyl, or any two adjacent groups of the R₁-R₅ may be connected to each other to form an aliphatic ring structure or an aromatic ring structure;
at most one of the X₁-X₅ is N, and when the X₁-X₅ are CR₁—CR₅, at least one of the R₁-R₅ is not H;
R₆-R₉ are independently selected from hydrogen, deuterium, halogen, substituted or unsubstituted C₁-C₁₀ alkyl, and substituted or unsubstituted C₃-C₂₀ cycloalkyl, and the R₆ is not hydrogen, deuterium, or halogen;
the heteroalkyl and the heteroaryl at least contain one O, N or S heteroatom;
and the “substituted” as described in R₁-R₉ refers to substitution with deuterium, F, Cl, Br, C₁-C₆ alkyl, C₃-C₆ cycloalkyl, amino substituted with C₁-C₆ alkyl, cyano, isocyano, or phosphino, and the substitution ranges from a single substitution number to a maximum substitution number.

Lb is a structure represented by Formula (2):

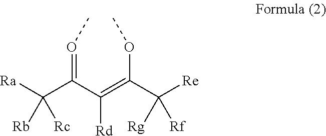

where dotted lines refer to positions connected to the metal Ir;
Ra-Rg are independently selected from hydrogen, deuterium, halogen, substituted or unsubstituted C₁-C₁₀ alkyl, substituted or unsubstituted C₃-C₂₀ cycloalkyl, substituted or unsubstituted C₁-C₁₀ heteroalkyl, and substituted or unsubstituted C₃-C₂₀ heterocyclic alkyl;
the heteroalkyl and the heterocyclic alkyl at least contain one O, N or S heteroatom;
the “substituted” as described in Rₐ-R_{g} refers to substitution with deuterium, F, Cl, Br, C₁-C₄ alkyl, C₁-C₄ alkoxyl, C₃-C₆ cycloalkyl, amino substituted with C₁-C₄ alkyl, cyano, isocyano, or phosphino;
and any two of the Ra, the Rb and the Re may be connected to form an aliphatic ring structure, and any two of the Re, the Rf and the Rg may also be connected to form an aliphatic ring;
Lc is a monoanionic bidentate ligand, and the Lc is different from the Lb and is not an OO ligand;
the Lc and the La are the same or different, and the different indicates different parent nuclear structures, a same parent nuclear structure with different substituents, or a same parent nuclear structure with different substituent positions;
and any two or three of the La, the Lb and the Lc are connected to each other to form a polydentate ligand.

In Formula (1) to Formula (5), in a case of 2 or more substituents, multiple substituents may be the same or different, respectively.

Examples of various groups of compounds represented by Formula (1) to Formula (5) are described below.

It is to be noted that in the specification, “Cₐ-C_{b}” in the term “substituted or unsubstituted Cₐ-C_{b} X group” refers to the number of carbons when the X group is unsubstituted, excluding the number of carbons of a substituent when the X group is substituted.

As a linear or branched alkyl, the C₁-C₁₀ alkyl specifically includes methyl, ethyl, propyl, isopropyl, n-butyl, isobutyl, sec-butyl, tert-butyl, n-pentyl and isomers thereof, n-hexyl and isomers thereof, n-heptyl and isomers thereof, n-octyl and isomers thereof, n-nonyl and isomers thereof, and n-decyl and isomers thereof, optionally includes methyl, ethyl, propyl, isopropyl, n-butyl, isobutyl, sec-butyl, and tert-butyl, and more optionally includes propyl, isopropyl, isobutyl, sec-butyl, and tert-butyl.

The C₃-C₂₀ cycloalkyl may include cyclopropyl, cyclobutyl, cyclopentyl, cyclohexyl, 1-adamantyl, 2-adamantyl, 1-norbornyl, and 2-norbornyl, and optionally includes cyclopentyl and cyclohexyl.

The C₂-C₁₀ alkenyl may include vinyl, propenyl, allyl, 1-butadienyl, 2-butadienyl, 1-hexatrienyl, 2-hexatrienyl, and 3-hexatrienyl, and optionally includes propenyl and allyl.

As a linear or branched alkyl or cycloalkyl consisting of atoms other than carbon and hydrogen, the C₁-C₁₀ heteroalkyl may include mercaptomethyl methyl, methoxymethyl, ethoxymethyl, tert-butoxyl methyl, N,N-dimethyl methyl, epoxy butyl, epoxy pentyl, and epoxy hexyl, and optionally includes methoxymethyl and epoxy pentyl.

Specific examples of the aryl include phenyl, naphthyl, anthracyl, phenanthryl, tetracenyl, pyrenyl, chrysenyl, benzo[c]phenanthryl, benzo[g]chrysenyl, fluorenyl, benzofluorenyl, dibenzofluorenyl, biphenyl, triphenyl, tetraphenyl, and fluoranthracyl, and optionally include phenyl and naphthyl.

Specific examples of the heteroaryl may include pyrrolyl, pyrazinyl, pyridyl, pyrimidinyl, triazinyl, indolyl, isoindolyl, imidazolyl, furyl, benzofuryl, isobenzofuryl, dibenzofuryl, dibenzothienyl, azodibenzofuryl, azodibenzothienyl, diazodibenzofuryl, diazodibenzothienyl, quinolyl, isoquinolyl, quinoxalinyl, carbazolyl, phenanthridinyl, acridinyl, phenanthrolinyl, phenazinyl, phenothiazinyl, phenoxazinyl, oxazolinyl, oxadiazolyl, furzanyl, thienyl, benzothienyl, dihydroacridinyl, azocarbazolyl, diazocarbazolyl, and quinazolinyl, and optionally include pyridyl, pyrimidinyl, triazinyl, dibenzofuryl, dibenzothienyl, azodibenzofuryl, azodibenzothienyl, diazodibenzofuryl, diazodibenzothienyl, carbazolyl, azocarbazolyl, and diazocarbazolyl.

The following embodiments are merely described to facilitate the understanding of the technical invention, and should not be considered as specific limitations of the present invention.

All raw materials, solvents and the like involved in the synthesis of compounds in the present invention are purchased from Alfa, Acros, and other suppliers known to persons skilled in the art.

### Synthesis of a Ligand La002

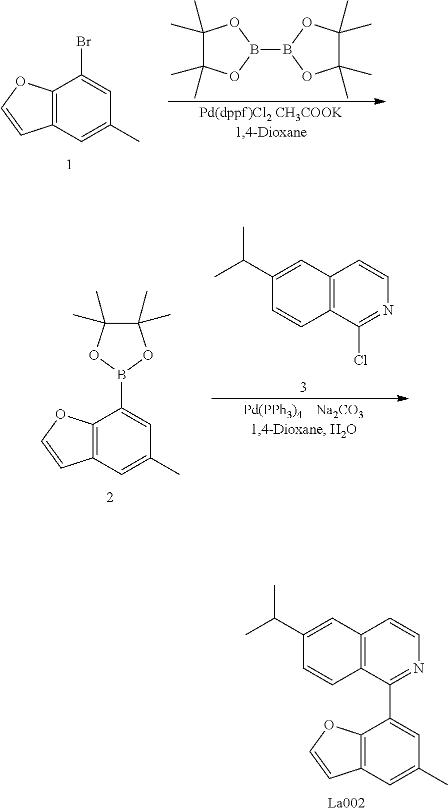

### Synthesis of an Intermediate 2

A compound 1 (27.85 g, 0.13 mol, 1.0 eq), bis(pinacolato)diboron (67.02 g, 0.26 mol, 2.0 eq), Pd(dppf)Cl₂ (9.66 g, 0.013 mol, 0.1 eq), potassium acetate (25.90 g, 0.26 mol, 2.0) and 1,4-dioxane (350 ml) were added into a 1 L three-necked flask, vacuumization was performed for nitrogen replacement for 3 times, and the above compounds were stirred at 100° C. for 2 hours under the protection of nitrogen. According to monitoring by thin-layer chromatography (TLC), the raw material 1 was completely reacted. Cooling was performed to room temperature, concentration was performed under reduce pressure to remove an organic solvent, and dichloromethane and deionized water were added for extraction. A resulting mixture was spin-dried, separated by column chromatography (with an eluting agent including ethyl acetate and n-hexane at a ratio of 1:20) and then concentrated to obtain a light yellow solid. The light yellow solid was beaten with 3 V (90 mL) of n-hexane and stirred at 70° C. for 15 minutes, followed by dissolved clarification. Then, heating was stopped, stirring was performed continuously for 2 hours, suction filtration was performed, and a filter cake was dried to obtain 19.86 g of a white solid intermediate 2 with a yield of 58.3%. The mass spectrum was: 259.14 (M+H).

### Synthesis of a Ligand La002

An intermediate 3 (17.00 g, 0.08 mol, 1.0 eq), the intermediate 2 (23.47 g, 0.09 mol, 1.1 eq), Pd(PPh₃)₄ (4.78 g, 0.004 mol, 0.05 eq), sodium carbonate (17.52 g, 0.16 mol, 2.00 eq), 1,4-dioxane (255 ml) and deionized water (85 ml) were added into a 1 L three-necked flask, vacuumization was performed for nitrogen replacement for 3 times, and the above compounds were stirred at 90° C. for 3 hours under the protection of nitrogen. According to monitoring by TLC, the raw material 3 was completely reacted. Cooling was performed to room temperature, concentration was performed under reduce pressure to remove an organic solvent, and dichloromethane and deionized water were added for extraction. A resulting mixture was spin-dried, separated by column chromatography (with an eluting agent including ethyl acetate and n-hexane at a ratio of 1:25) and then concentrated to obtain 21.48 g of a light yellow sugar-like solid compound La002 with a yield of 86.23%. The mass spectrum was: 302.38 (M+H).

### Synthesis of a Compound Ir(La002)₂(Lb005)

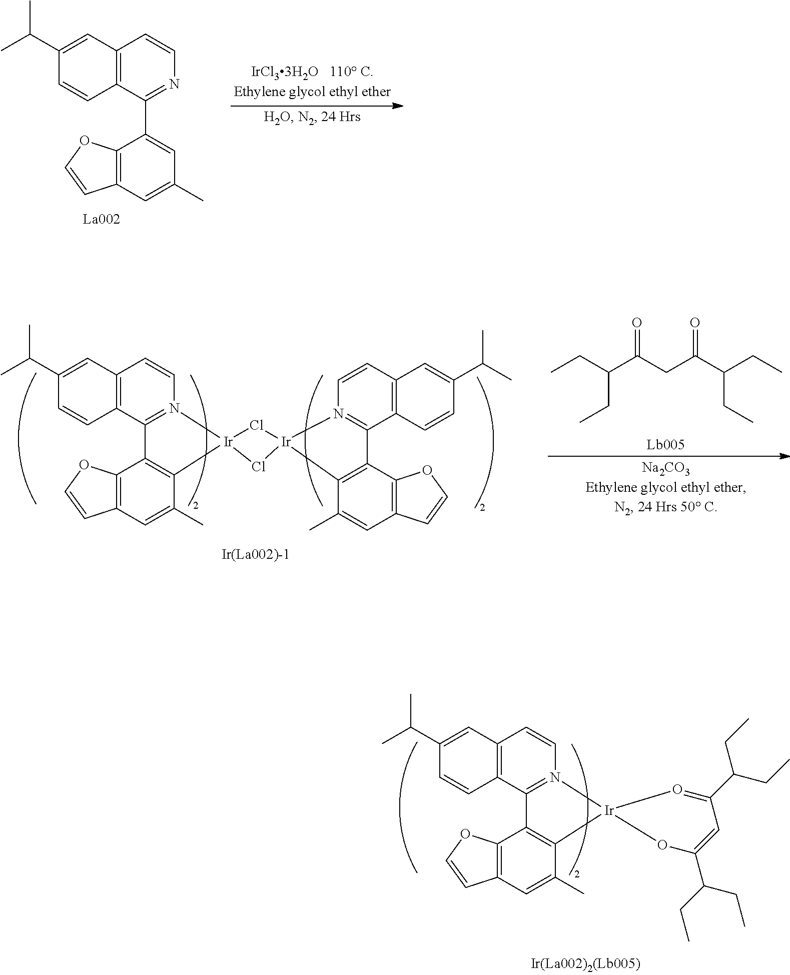

### Synthesis of a Compound Ir(La002)-1

The compound La002 (12.30 g, 40.81 mmol, 3.5 eq) and IrCl₃·3H₂O (4.11 g, 11.66 mmol, 1.0 eq) were put into a 500 ml one-necked round-bottomed flask, ethylene glycol ethyl ether (120 ml) and deionized water (40 ml) were added, vacuumization was performed for replacement for 3 times, and a resulting mixture was stirred at 110° C. for 24 hours under the protection of N₂. After cooling was performed to room temperature, concentration was performed to remove a solvent, and a resulting product was dissolved in dichloromethane (DCM) and filtered with silica gel. Then, a filtrate was washed with deionized water, and an organic phase was concentrated to obtain 9.33 g of a dark red oily compound Ir(La002)-1 with a yield of 96.56%. The obtained compound was directly used in the next step without further purification.

### Synthesis of a Compound Ir(La002)₂(Lb005)

The compound Ir(La002)-1 (6.56 g, 7.92 mmol, 1.0 eq), Lb005 (8.41 g, 39.59 mmol, 5.0 eq) and sodium carbonate (8.39 g, 79.19 mmol, 10.0 eq) were put into a 250 ml one-necked round-bottomed flask, ethylene glycol ethyl ether (66 ml) was added, vacuumization was performed for replacement for 3 times, and a resulting mixture was stirred at 50° C. for 24 hours under the protection of N₂. According to monitoring by TLC, the Ir(La002)-1 was completely reacted. After cooling was performed to room temperature, 132 ml of methanol was added for beating at room temperature for 2 hours. Suction filtration was performed, a filter cake was dissolved in dichloromethane (100 ml) and filtered with silica gel, and a filtrate was washed with deionized water (120 ml), followed by liquid separation. Then, an organic phase was collected, concentrated and dried to obtain a dark red solid, and the dark red solid was recrystallized with N,N-dimethylformamide (DMF)/methyl cyanide (MeCN) (30 V/20 V) for two times to obtain 2.65 g of a dark red solid compound Ir(La002)₂(Lb005) with a yield of 33.32%. 2.65 g of the crude product Ir(La002)₂(Lb005) was sublimated and purified to obtain 1.52 g of sublimated and purified Ir(La002)₂(Lb005) with a yield of 57.35%. The mass spectrum was: 1005.28 (M+H). ¹H NMR (400 MHz, CDCl₃) δ 8.87 (d, J=8.9 Hz, 2H), 8.21 (d, J=6.4 Hz, 2H), 7.59 (s, 2H), 7.53 (d, J=8.9 Hz, 2H), 7.39 (d, J=2.1 Hz, 2H), 7.23 (d, J=6.4 Hz, 2H), 7.02 (s, 2H), 6.66 (d, J=2.1 Hz, 2H), 4.76 (s, 1H), 3.14 (dt, J=13.5, 6.7 Hz, 2H), 1.54 (dd, J=12.1, 3.8 Hz, 8H), 1.40 (dd, J=6.9, 2.7 Hz, 11H), 1.33-1.12 (m, 3H), 1.14-1.02 (m, 2H), 0.75 (dd, J=16.9, 9.6 Hz, 4H), 0.45 (t, J=7.4 Hz, 6H), −0.20 (t, J=7.4 Hz, 6H).

### Synthesis of a Ligand La003

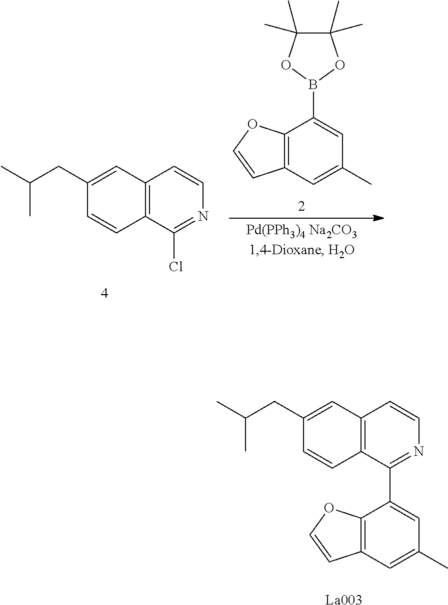

With reference to synthesis and purification methods of the compound La002, only the corresponding raw materials were required to be changed, and a target compound La003 was obtained. The mass spectrum was: 316.16 (M+H).

### Synthesis of a Compound Ir(La003)₂(Lb005)

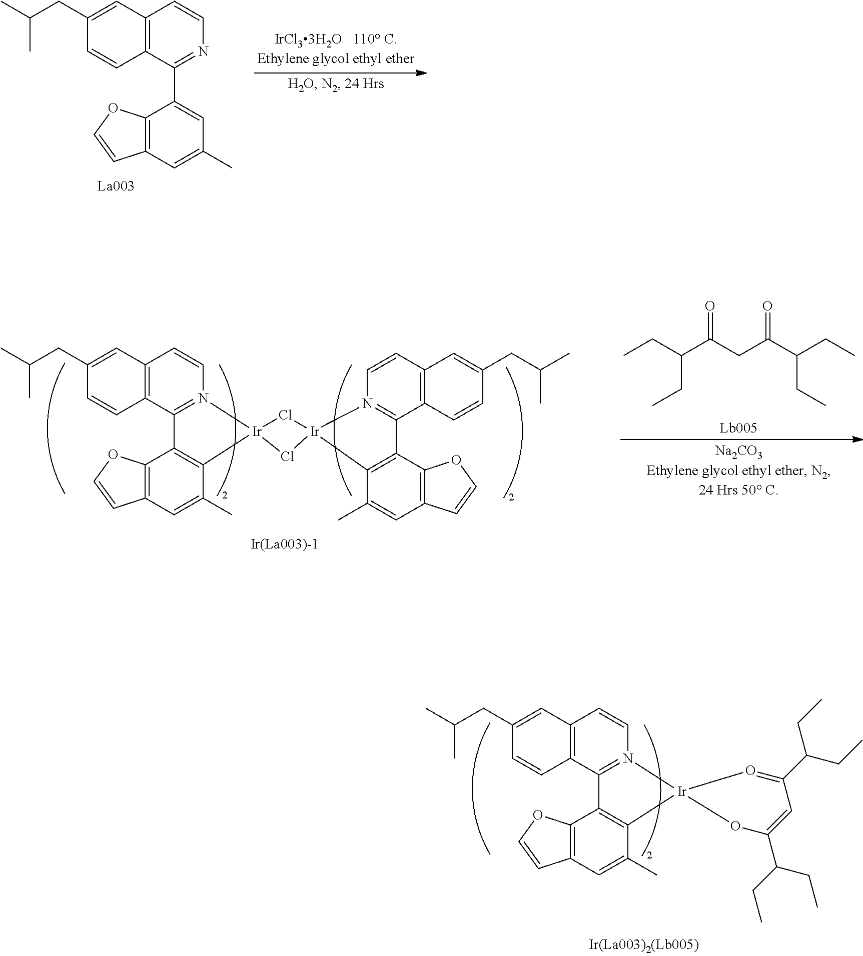

### Synthesis of a Compound Ir(La003)-1

With reference to synthesis and purification methods of the compound Ir(Lb002)-1, only the corresponding raw materials were required to be changed, and an obtained compound Ir(La003)-1 was directly used in the next step without purification.

### Synthesis of a Compound Ir(La003)₂(Lb005)

With reference to synthesis and purification methods of the compound Ir(La002)₂(Lb005), only the corresponding raw materials were required to be changed, and 2.31 g of a red solid compound Ir(La003)₂(Lb005) with a yield of 32.57% was obtained. 2.31 g of the crude product Ir(La003)₂(Lb005) was sublimated and purified to obtain 1.21 g of sublimated and purified Ir(La003)₂(Lb005) with a yield of 52.38%. The mass spectrum was 1033.44 (M+H). ¹H NMR (400 MHz, CDCl₃) δ 8.85 (d, J=8.7 Hz, 2H), 8.21 (d, J=6.4 Hz, 2H), 7.53 (s, 2H), 7.45 (d, J=8.8 Hz, 2H), 7.38 (d, J=2.1 Hz, 2H), 7.21 (d, J=6.3 Hz, 2H), 7.01 (s, 2H), 6.66 (d, J=2.1 Hz, 2H), 4.77 (s, 1H), 2.70 (p, J=13.4 Hz, 4H), 2.14-2.01 (m, 2H), 1.66-1.39 (m, 10H), 1.33-1.16 (m, 3H), 1.04 (ddd, J=15.7, 10.9, 6.1 Hz, 12H), 0.88 (t, J=7.4 Hz, 2H), 0.77 (dd, J=14.7, 7.7 Hz, 3H), 0.44 (t, J=7.4 Hz, 5H), −0.20 (t, J=7.3 Hz, 5H).

### Synthesis of a Ligand La004

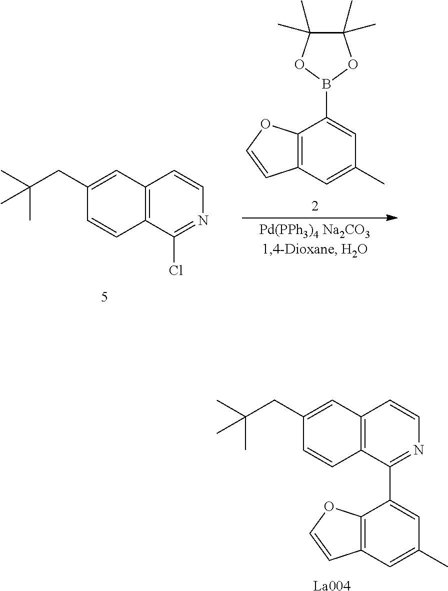 [SMILES: CC(C)(C)Cc1ccc2c(Cl)nccc2c1 ; Cc1cc(B2OC(C)(C)C(C)(C)O2)c2occc2c1 ; Cc1cc(-c2nccc3cc(CC(C)(C)C)ccc23)c2occc2c1 ; "La004"]

With reference to synthesis and purification methods of the compound La002, only the corresponding raw materials were required to be changed, and a target compound La004 was obtained. The mass spectrum was: 330.43 (M+H).

### Synthesis of a Compound Ir(La004)₂(Lb005)

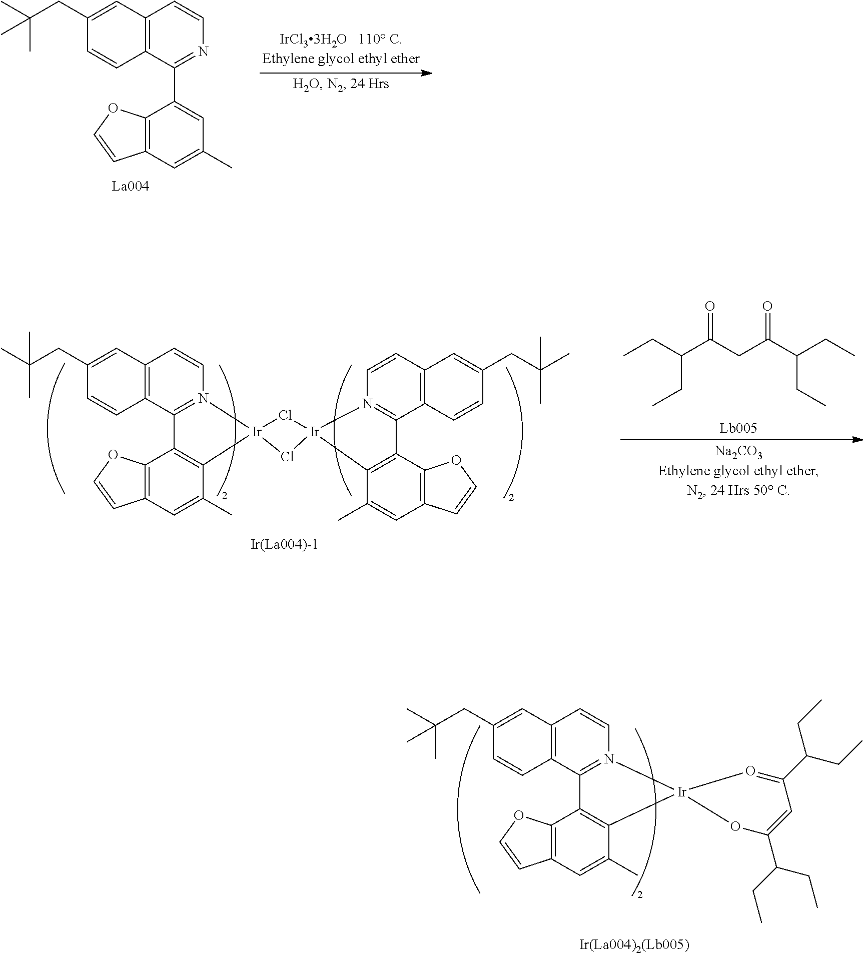

### Synthesis of a Compound Ir(La004)-1

With reference to synthesis and purification methods of the compound Ir(Lb002)-1, only the corresponding raw materials were required to be changed, and an obtained compound Ir(La004)-1 was directly used in the next step without purification.

### Synthesis of a Compound Ir(La004)₂(Lb005)

With reference to synthesis and purification methods of the compound Ir(La002)₂(Lb005), only the corresponding raw materials were required to be changed, and 1.89 g of a red solid compound Ir(La004)₂(Lb005) with a yield of 36.21% was obtained. 1.89 g of the crude product Ir(La004)₂(Lb005) was sublimated and purified to obtain 1.02 g of sublimated and purified Ir(La004)₂(Lb005) with a yield of 53.96%. The mass spectrum was 1061.39 (M+H). ¹H NMR (400 MHz, CDCl₃) δ 8.86 (d, J=8.7 Hz, 2H), 8.22 (d, J=6.4 Hz, 2H), 7.53 (s, 2H), 7.45 (d, J=8.8 Hz, 2H), 7.38 (d, J=2.1 Hz, 2H), 7.21 (d, J=6.3 Hz, 2H), 7.01 (s, 2H), 6.66 (d, J=2.1 Hz, 2H), 4.77 (s, 1H), 2.70 (p, J=13.4 Hz, 4H), 1.66-1.39 (m, 10H), 1.33-1.16 (m, 3H), 1.04 (m, 18H), 0.88 (t, J=7.4 Hz, 2H), 0.77 (dd, J=14.7, 7.7 Hz, 3H), 0.44 (t, J=7.4 Hz, 5H), −0.15 (t, J=7.3 Hz, 5H).

### Synthesis of a Ligand La007

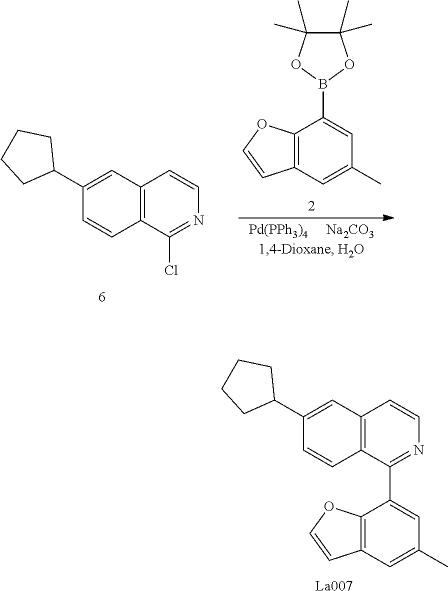 [SMILES: Clc1nccc2cc(C3CCCC3)ccc12 ; Cc1cc(B2OC(C)(C)C(C)(C)O2)c2occc2c1 ; Cc1cc(-c2nccc3cc(C4CCCC4)ccc23)c2occc2c1 ; "La007"]

With reference to synthesis and purification methods of the compound La002, only the corresponding raw materials were required to be changed, and a target compound La007 was obtained. The mass spectrum was: 328.42 (M+H).

### Synthesis of a Compound Ir(La007)₂(Lb005)

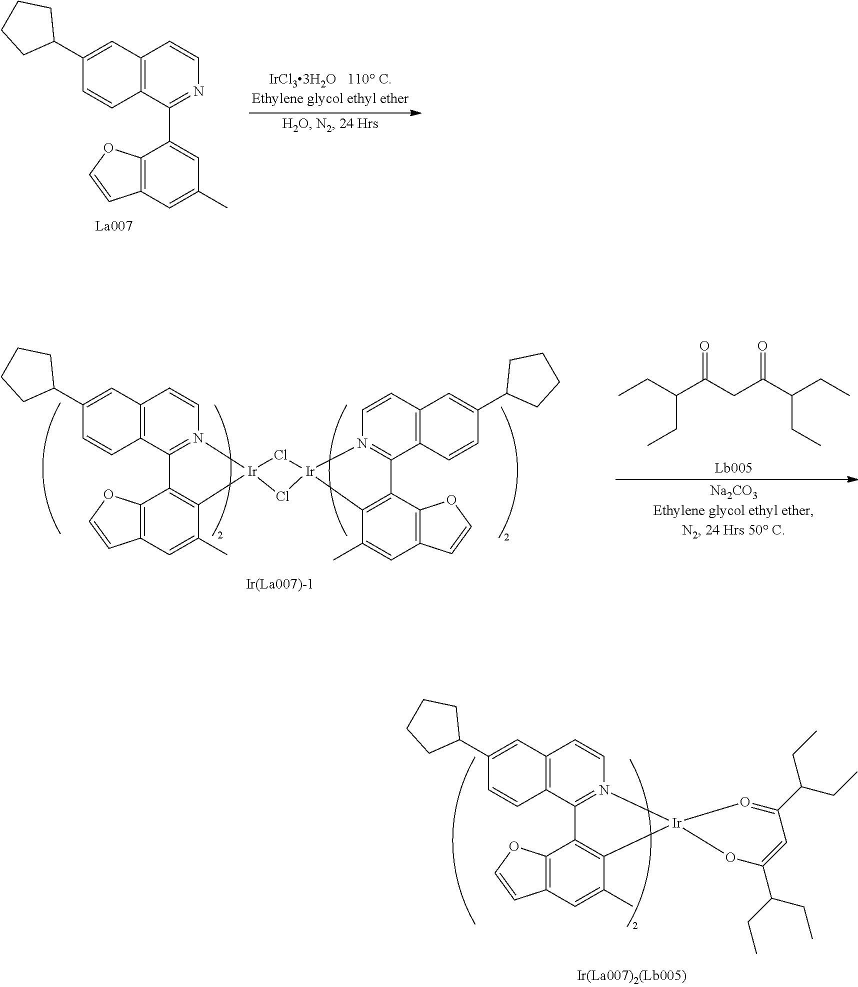

### Synthesis of a Compound Ir(La007)-1

With reference to synthesis and purification methods of the compound Ir(La002)-1, only the corresponding raw materials were required to be changed, and an obtained compound Ir(La007)-1 was directly used in the next step without purification.

### Synthesis of a Compound Ir(La007)₂(Lb005)

With reference to synthesis and purification methods of the compound Ir(La002)₂(Lb005), only the corresponding raw materials were required to be changed, and 2.66 g of a dark red solid compound Ir(La007)₂(Lb005) with a yield of 35.20% was obtained. 2.66 g of the crude product Ir(La007)₂(Lb005) was sublimated and purified to obtain 1.63 g of sublimated and purified Ir(La007)₂(Lb005) with a yield of 61.27%. The mass spectrum was 1057.44 (M+H). ¹H NMR (400 MHz, CDCl₃) δ 8.86 (d, J=8.8 Hz, 2H), 8.20 (d, J=6.4 Hz, 2H), 7.60 (s, 2H), 7.54 (d, J=9.0 Hz, 2H), 7.38 (d, J=2.1 Hz, 2H), 7.21 (d, J=6.4 Hz, 2H), 7.01 (s, 2H), 6.66 (d, J=2.1 Hz, 2H), 4.76 (s, 1H), 3.37-3.07 (m, 2H), 2.19 (s, 4H), 1.84 (d, J=51.8 Hz, 11H), 1.62-1.44 (m, 9H), 1.24 (dd, J=14.9, 7.6 Hz, 3H), 1.16-0.97 (m, 2H), 0.75 (dd, J=16.5, 8.4 Hz, 4H), 0.45 (t, J=7.4 Hz, 5H), −0.19 (t, J=7.4 Hz, 5H).

### Synthesis of a Ligand La011

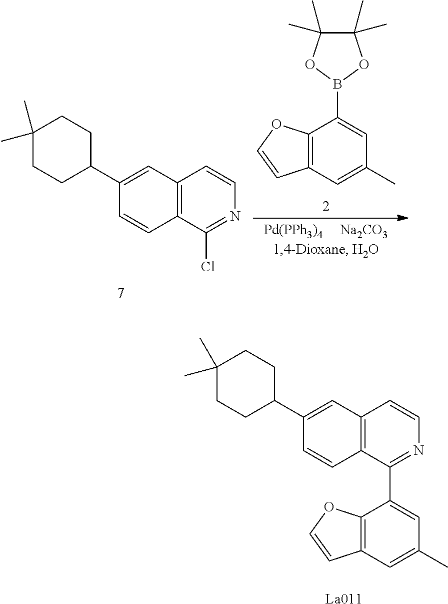

With reference to synthesis and purification methods of the compound La002, only the corresponding raw materials were required to be changed, and a target compound La011 was obtained. The mass spectrum was: 370.5 (M+H).

### Synthesis of a Compound Ir(La011)₂(Lb007)

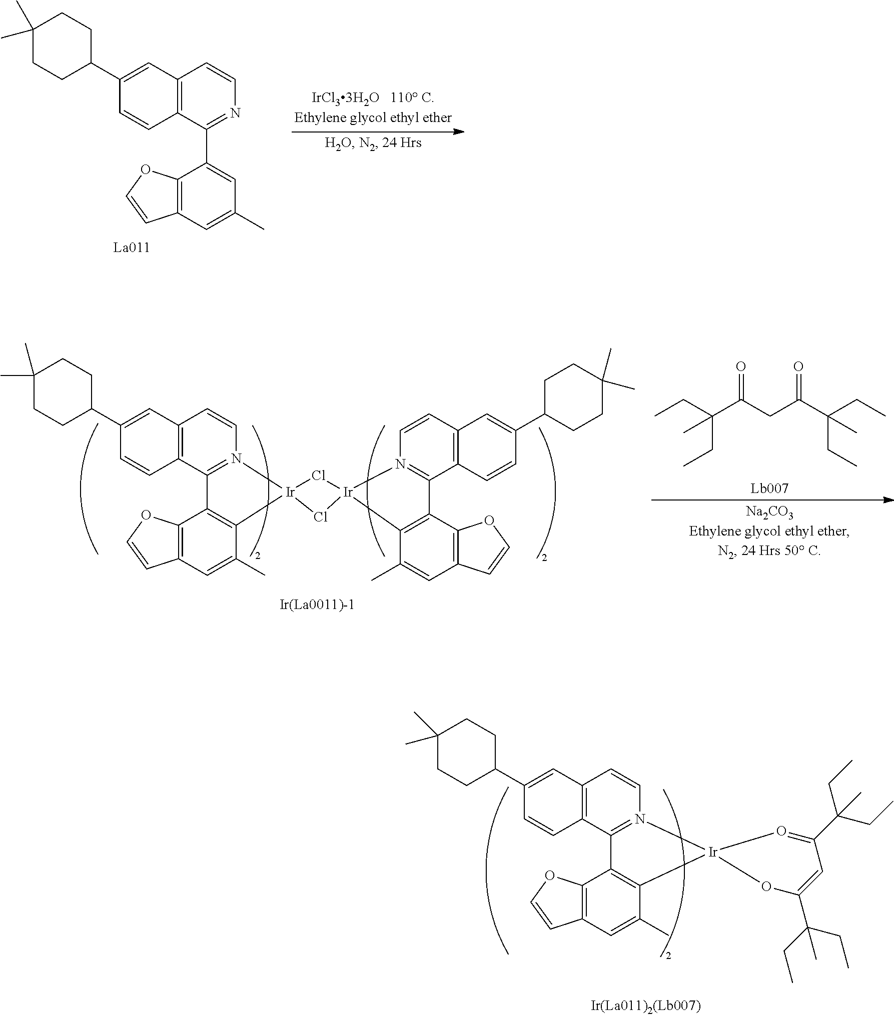

### Synthesis of a Compound Ir(La011)-1

With reference to synthesis and purification methods of the compound Ir(La002)-1, only the corresponding raw materials were required to be changed, and an obtained compound Ir(La011)-1 was directly used in the next step without purification.

### Synthesis of a Compound Ir(La011)₂(Lb007)

With reference to synthesis and purification methods of the compound Ir(La002)₂(Lb005), only the corresponding raw materials were required to be changed, and 2.11 g of a dark red solid compound Ir(La011)₂(Lb007) with a yield of 34.91% was obtained. 2.11 g of the crude product Ir Ir(La011)₂(Lb007) was sublimated and purified to obtain 0.95 g of sublimated and purified Ir(La011)₂(Lb007) with a yield of 45.02%. The mass spectrum was: 1069.57 (M+H). ¹H NMR (400 MHz, CDCl₃) δ 8.86 (d, J=8.7 Hz, 2H), 8.22 (d, J=6.4 Hz, 2H), 7.53 (s, 2H), 7.45 (d, J=8.8 Hz, 2H), 7.38 (d, J=2.1 Hz, 2H), 7.21 (d, J=6.3 Hz, 2H), 7.01 (s, 2H), 6.66 (d, J=2.1 Hz, 2H), 2.22 (m, 2H), 1.55 (m, 6H), 1.47 (m, 16H), 1.33-1.16 (m, 8H), 1.03 (m, 12H), 0.89 (m, 12H), 0.77 (s, 6H).

### Synthesis of a Compound Ir(La003)₂(Lb006)

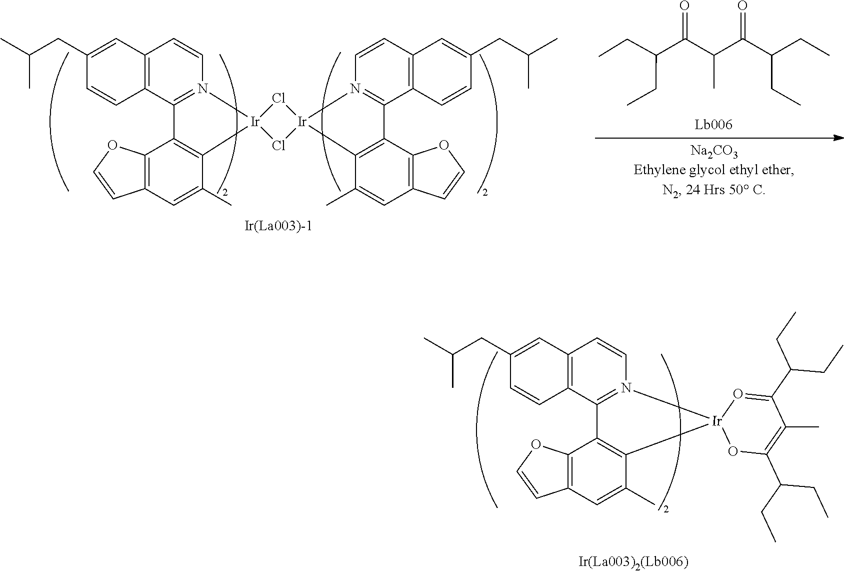

### Synthesis of a Compound Ir(La003)₂(Lb006)

With reference to synthesis and purification methods of the compound Ir(La002)₂(Lb005), only the corresponding raw materials were required to be changed, and 1.97 g of a dark red solid compound Ir(La003)₂(Lb006) with a yield of 31.70% was obtained. 1.97 g of the crude product Ir(La003)₂(Lb006) was sublimated and purified to obtain 1.11 g of sublimated and purified Ir(La003)₂(Lb006) with a yield of 56.34%. The mass spectrum was 1047.34 (M+H). ¹H NMR (400 MHz, CDCl₃) δ 8.85 (d, J=8.7 Hz, 2H), 8.21 (d, J=6.4 Hz, 2H), 7.53 (s, 2H), 7.45 (d, J=8.8 Hz, 2H), 7.38 (d, J=2.1 Hz, 2H), 7.21 (d, J=6.3 Hz, 2H), 7.01 (s, 2H), 6.66 (d, J=2.1 Hz, 2H), 2.70 (p, J=13.4 Hz, 4H), 2.14-2.01 (m, 2H), 1.88 (s, 3H), 1.66-1.39 (m, 10H), 1.33-1.16 (m, 3H), 1.04 (ddd, J=15.7, 10.9, 6.1 Hz, 12H), 0.88 (t, J=7.4 Hz, 2H), 0.77 (dd, J=14.7, 7.7 Hz, 3H), 0.44 (t, J=7.4 Hz, 5H), −0.20 (t, J=7.3 Hz, 5H).

### Synthesis of a Ligand La039

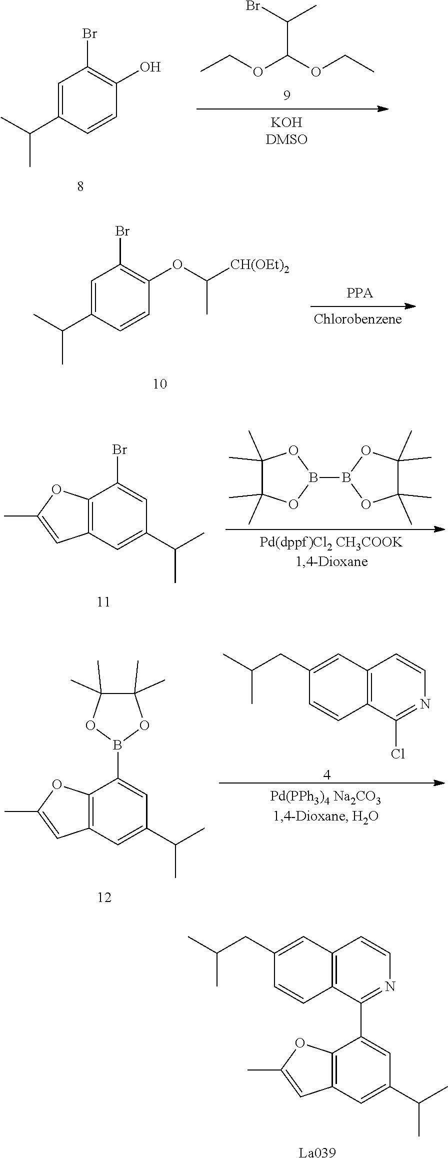

### Synthesis of an Intermediate 10

A compound 8 (18.5 g, 86.01 mmol, 1.0 eq), a compound 9 (19.97 g, 94.61 mmol, 1.1 eq) and dimethyl sulfoxide (277 ml) were added into a 1 L three-necked flask and evenly stirred at room temperature, a potassium hydroxide aqueous solution (5.79 g, 103.2 mmol, 1.2 eq, 150 ml of deionized water) was slowly added dropwise, and after the dropping was completed, a reaction solution was heated to 120° C. for 16 hours. According to monitoring by TLC, the raw material 8 was completely reacted. Cooling was performed to room temperature, ethyl acetate (250 ml) was added for extracting the reaction solution for several times, and an organic phase was washed with deionized water for two times (100 ml/time), followed by liquid separation. Then, an organic phase was collected and concentrated to obtain 24.3 g of a light yellow oily compound 10 with a yield of 81.83%, which was directly used in a reaction in the next step. The mass spectrum was: 346.2 (M+H).

### Synthesis of an Intermediate 11

The compound 10 (20.0 g, 57.93 mmol, 1.0 eq), polyphosphoric acid (100 g) and chlorobenzene (250 ml) were added into a 1 L three-necked flask, and a reaction solution was heated for reflux for 16 hours. According to monitoring by TLC, the raw material 10 was basically completely reacted. Cooling was performed to room temperature, ethyl acetate (300 ml) was added for extracting the reaction solution, and a resulting organic phase was washed with a 5% sodium bicarbonate solution (250 ml) for three times, followed by liquid separation. Then, an organic phase was concentrated and separated by column chromatography (with n-hexane as an eluting agent) to obtain 6.87 g of a white solid compound 11 with a yield of 46.82%. The mass spectrum was: 254.13 (M+H).

### Synthesis of an Intermediate 12

With reference to synthesis and purification methods of the compound 2, only the corresponding raw materials were required to be changed, and a target compound 12 was obtained. The mass spectrum was: 301.22 (M+H).

### Synthesis of a Ligand La039

With reference to synthesis and purification methods of the compound La002, only the corresponding raw materials were required to be changed, and a target compound La039 was obtained. The mass spectrum was: 358.49 (M+H).

### Synthesis of a Compound Ir(La039)₂(Lb006)

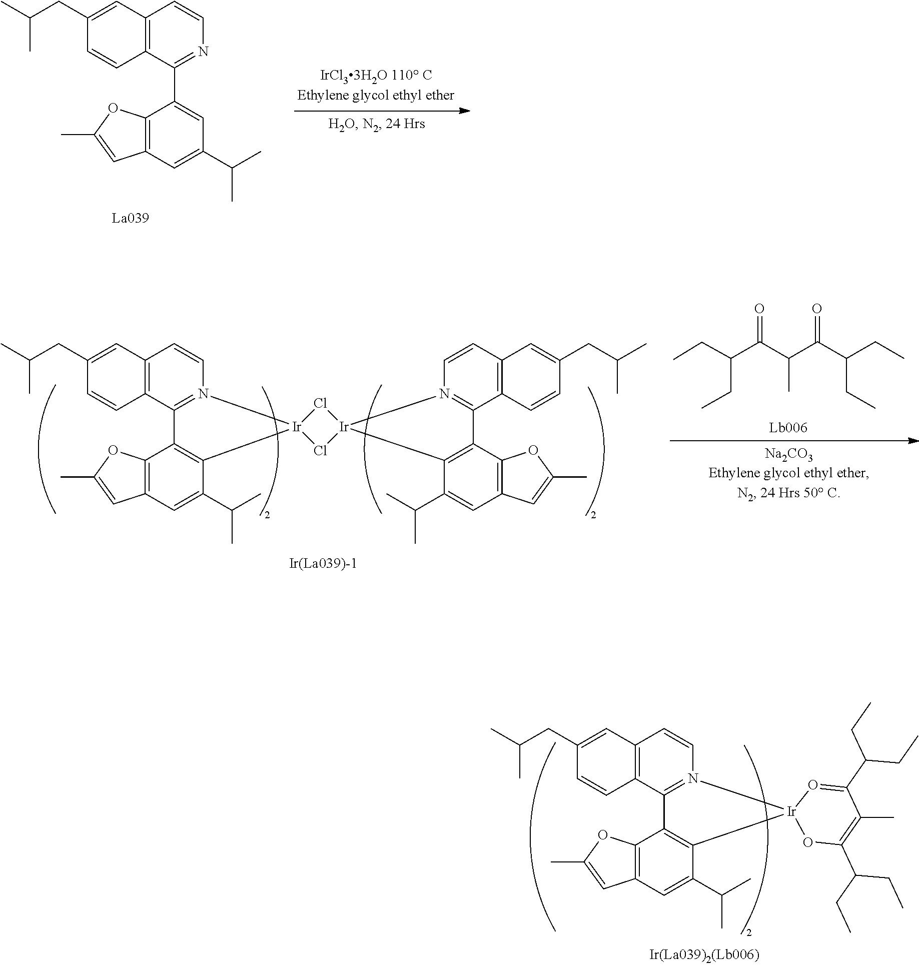

### Synthesis of a Compound Ir(La039)-1

With reference to synthesis and purification methods of the compound Ir(La002)-1, only the corresponding raw materials were required to be changed, and an obtained compound Ir(La039)-1 was directly used in the next step without purification.

### Synthesis of a Compound Ir(La039)₂(Lb006)

With reference to synthesis and purification methods of the compound Ir(La002)₂(Lb005), only the corresponding raw materials were required to be changed, and 2.73 g of a dark red solid compound Ir(La039)₂(Lb006) with a yield of 41.72% was obtained. 2.73 g of the crude product Ir(La039)₂(Lb006) was sublimated and purified to obtain 1.22 g of sublimated and purified Ir(La039)₂(Lb006) with a yield of 44.68%. The mass spectrum was 1031.52 (M+H). ¹H NMR (400 MHz, CDCl₃) δ 8.87 (d, J=8.8 Hz, 2H), 8.22 (d, J=6.4 Hz, 2H), 7.60 (s, 2H), 7.54 (d, J=9.0 Hz, 2H), 7.38 (d, J=2.1 Hz, 2H), 7.21 (d, J=6.4 Hz, 2H), 7.01 (s, 2H), 2.87 (m, 2H), 2.43 (m, 4H), 2.25 (s, 6H), 1.87 (s, 3H), 1.82 (m, 2H), 1.24 (m, 18H), 1.06-0.76 (m, 28H).

### Synthesis of a Ligand La087

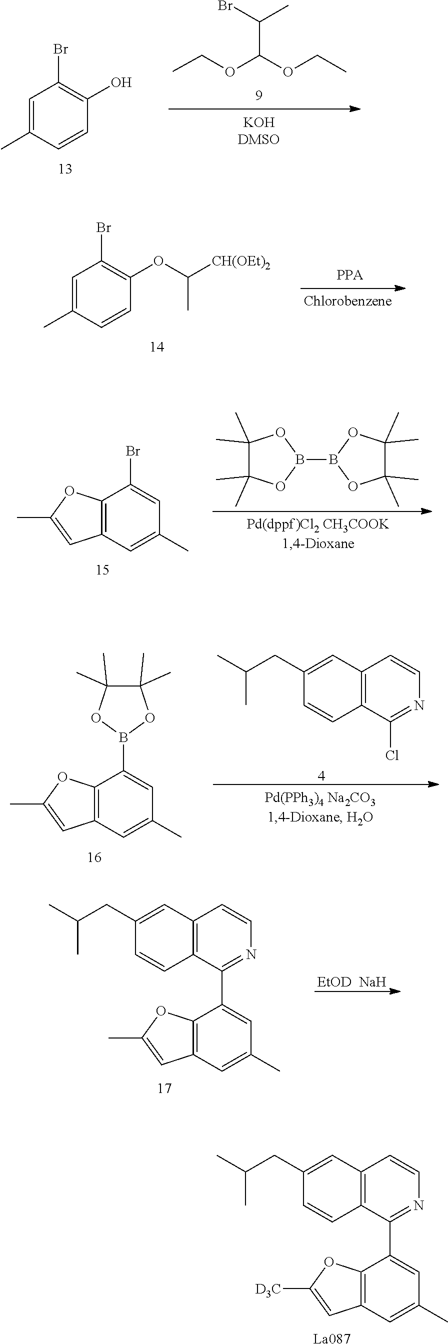

### Synthesis of an Intermediate 14

With reference to synthesis and purification methods of the compound 10, only the corresponding raw materials were required to be changed, and a target compound 14 was obtained. The mass spectrum was: 318.22 (M+H).

### Synthesis of an Intermediate 15

With reference to synthesis and purification methods of the compound 10, only the corresponding raw materials were required to be changed, and a target compound 15 was obtained. The mass spectrum was: 226.08 (M+H).

### Synthesis of an Intermediate 16

With reference to synthesis and purification methods of the compound 2, only the corresponding raw materials were required to be changed, and a target compound 16 was obtained. The mass spectrum was: 273.15 (M+H).

### Synthesis of an Intermediate 17

With reference to synthesis and purification methods of the compound La002, only the corresponding raw materials were required to be changed, and a target intermediate compound 17 was obtained. The mass spectrum was: 330.43 (M+H).

### Synthesis of a Ligand La087

The intermediate 17 (9.5 g, 28.84 mmol, 1.0 eq), 60% sodium hydride (3.46 g, 86.51 mmol, 3.0 eq) and deuterated ethanol (100 ml) were put into a 1 L one-necked flask. Vacuumization was performed for nitrogen replacement for three times, and the above compounds were heated to 75° C. to carry out a reaction for 16 hours under the protection of nitrogen. The reaction was lowered to room temperature. Heavy water (40 mL) was added and stirred to precipitate a solid, and the solid was collected by filtration. The crude product was separated by column chromatography with silica gel (with an eluting agent including ethyl acetate and n-hexane at a ratio of 1:30) to obtain 5.98 g of a light yellow solid compound La087 with a yield of 62.4%.

### Synthesis of a Compound Ir(La087)₂(Lb006)

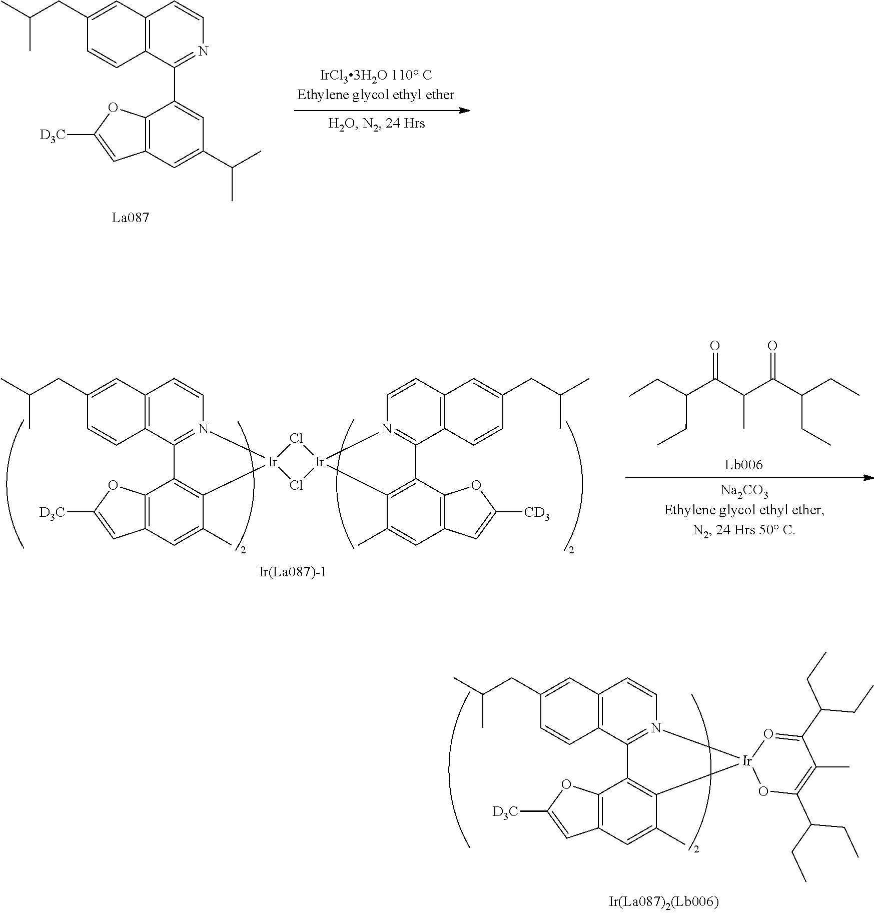

### Synthesis of a Compound Ir(La087)-1

With reference to synthesis and purification methods of the compound Ir(La002)-1, only the corresponding raw materials were required to be changed, and an obtained compound Ir(La087)-1 was directly used in the next step without purification.

### Synthesis of a Compound Ir(La087)₂(Lb006)

With reference to synthesis and purification methods of the compound Ir(La002)₂(Lb005), only the corresponding raw materials were required to be changed, and 1.68 g of a dark red solid compound Ir(La087)₂(Lb006) with a yield of 31.61% was obtained. 1.68 g of the crude product Ir(La087)₂(Lb006) was sublimated and purified to obtain 0.84 g of sublimated and purified Ir(La087)₂(Lb006) with a yield of 50.0%. The mass spectrum was 1081.53 (M+H). ¹H NMR (400 MHz, CDCl₃) δ 8.84 (d, J=8.7 Hz, 2H), 8.19 (d, J=6.4 Hz, 2H), 7.53 (s, 2H), 7.45 (d, J=8.8 Hz, 2H), 7.38 (d, J=2.1 Hz, 2H), 7.22 (d, J=6.3 Hz, 2H), 7.02 (s, 2H), 2.71 (p, J=13.4 Hz, 4H), 2.14-2.01 (m, 2H), 1.88 (s, 3H), 1.66-1.39 (m, 10H), 1.33-1.16 (m, 3H), 1.04 (ddd, J=15.7, 10.9, 6.1 Hz, 12H), 0.88 (t, J=7.4 Hz, 2H), 0.77 (dd, J=14.7, 7.7 Hz, 3H), 0.44 (t, J=7.4 Hz, 5H), −0.20 (t, J=7.3 Hz, 5H).

### Synthesis of a Ligand La099

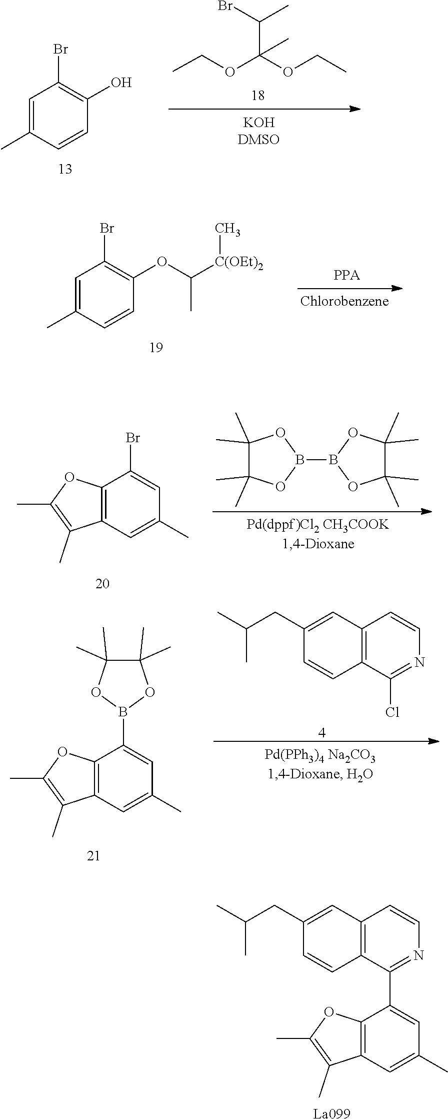

### Synthesis of an Intermediate 19

With reference to synthesis and purification methods of the compound 10, only the corresponding raw materials were required to be changed, and a target compound 19 was obtained. The mass spectrum was: 332.25 (M+H).

### Synthesis of an Intermediate 20

With reference to synthesis and purification methods of the compound 10, only the corresponding raw materials were required to be changed, and a target compound 20 was obtained. The mass spectrum was: 240.11 (M+H).

### Synthesis of an Intermediate 21

With reference to synthesis and purification methods of the compound 2, only the corresponding raw materials were required to be changed, and a target compound 21 was obtained. The mass spectrum was: 287.17 (M+H).

### Synthesis of a Ligand La099

With reference to synthesis and purification methods of the compound La002, only the corresponding raw materials were required to be changed, and a target compound La099 was obtained. The mass spectrum was: 344.46 (M+H).

### Synthesis of a Compound Ir(La099)₂(Lb006)

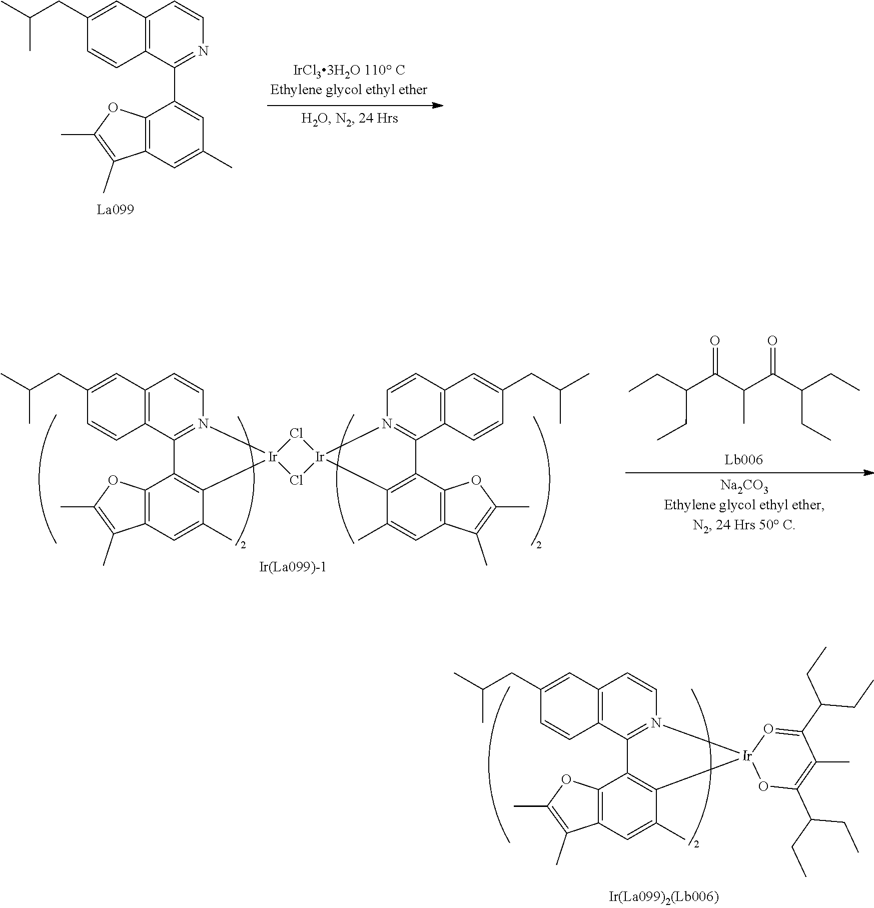

### Synthesis of a Compound Ir(La099)-1

With reference to synthesis and purification methods of the compound Ir(La002)-1, only the corresponding raw materials were required to be changed, and an obtained compound Ir(La099)-1 was directly used in the next step without purification.

### Synthesis of a Compound Ir(La099)₂(Lb006)

With reference to synthesis and purification methods of the compound Ir(La002)₂(Lb005), only the corresponding raw materials were required to be changed, and 1.89 g of a dark red solid compound Ir(La099)₂(Lb006) with a yield of 33.67% was obtained. 1.89 g of the crude product Ir(La099)₂(Lb006) was sublimated and purified to obtain 1.09 g of sublimated and purified Ir(La099)₂(Lb006) with a yield of 57.67%. The mass spectrum was 1103.47 (M+H). ¹H NMR (400 MHz, CDCl₃) δ 8.85 (d, J=8.8 Hz, 2H), 8.20 (d, J=6.4 Hz, 2H), 7.60 (s, 2H), 7.54 (d, J=9.0 Hz, 2H), 7.38 (d, J=2.1 Hz, 2H), 7.21 (d, J=6.4 Hz, 2H), 2.43 (s, 4H), 2.30 (d, J=40.0 Hz, 12H), 2.02 (s, 6H), 1.87 (s, 3H), 1.85-1.77 (m, 2H), 1.27 (m, 8H), 1.01 (m, 4H), 0.91 (m, 22H).

### Synthesis of a Ligand La111

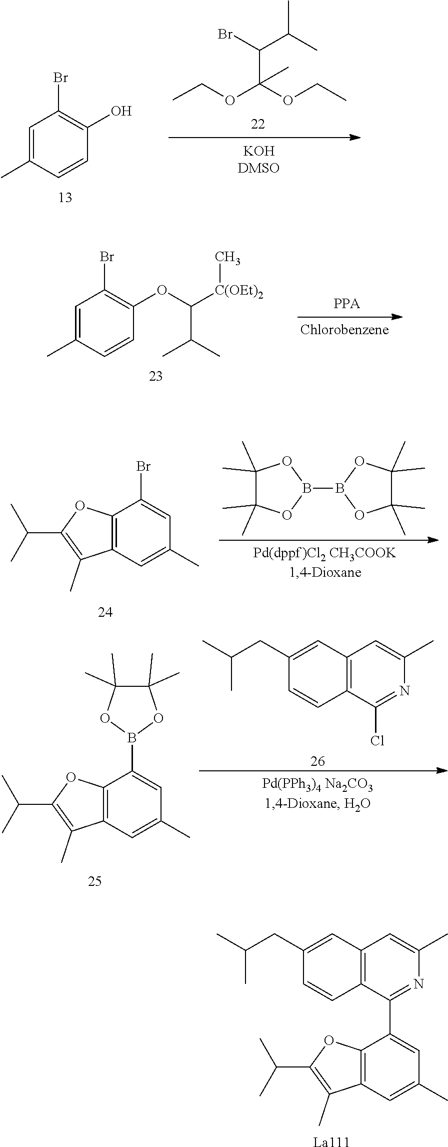

### Synthesis of an intermediate 23

With reference to synthesis and purification methods of the compound 10, only the corresponding raw materials were required to be changed, and a target compound 23 was obtained. The mass spectrum was: 360.3 (M+H).

### Synthesis of an Intermediate 24

With reference to synthesis and purification methods of the compound 10, only the corresponding raw materials were required to be changed, and a target compound 24 was obtained. The mass spectrum was: 267.16 (M+H).

### Synthesis of an Intermediate 25

With reference to synthesis and purification methods of the compound 2, only the corresponding raw materials were required to be changed, and a target compound 25 was obtained. The mass spectrum was: 315.23 (M+H).

### Synthesis of a Ligand La111

With reference to synthesis and purification methods of the compound La002, only the corresponding raw materials were required to be changed, and a target compound La111 was obtained. The mass spectrum was: 386.54 (M+H).

### Synthesis of a Compound Ir(La111)₂(Lb006)

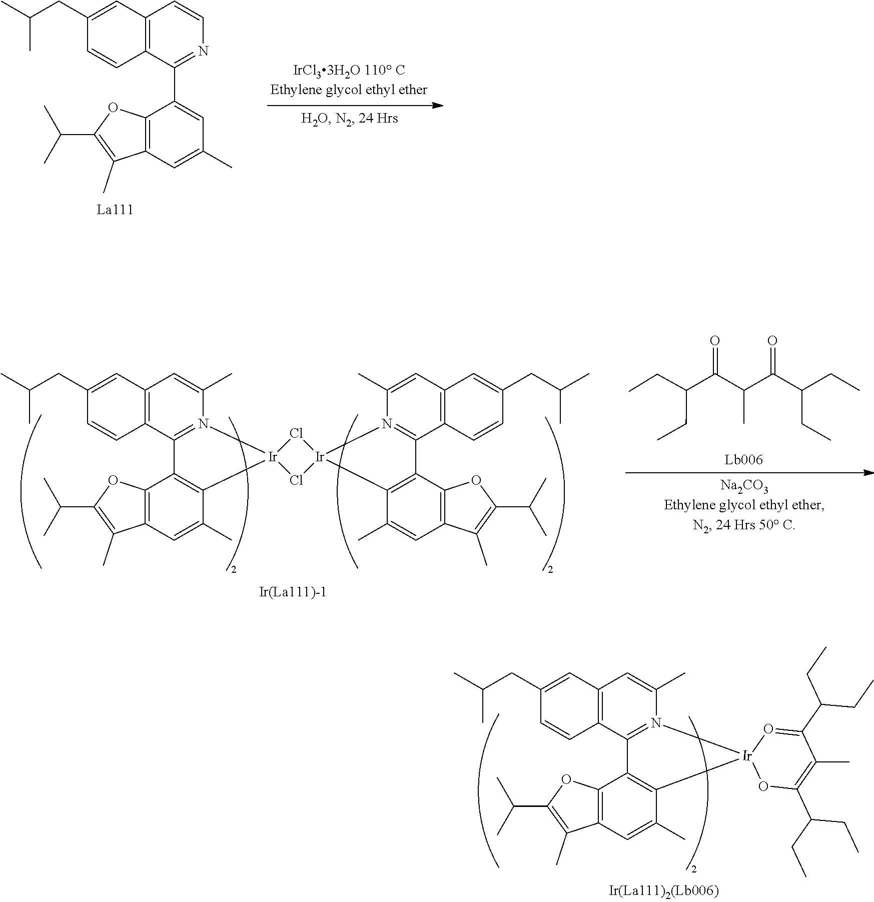

### Synthesis of a Compound Ir(La111)-1

With reference to synthesis and purification methods of the compound Ir(La002)-1, only the corresponding raw materials were required to be changed, and an obtained compound Ir(La111)-1 was directly used in the next step without purification.

### Synthesis of a Compound Ir(La111)₂(Lb006)

With reference to synthesis and purification methods of the compound Ir(La002)₂(Lb005), only the corresponding raw materials were required to be changed, and 1.59 g of a dark red solid compound Ir(La111)₂(Lb006) with a yield of 30.87% was obtained. 1.59 g of the crude product Ir(La111)₂(Lb006) was sublimated and purified to obtain 0.87 g of sublimated and purified Ir(La111)₂(Lb006) with a yield of 54.71%. The mass spectrum was 1187.63 (M+H). ¹H NMR (400 MHz, CDCl₃) δ 8.23 (d, J=6.4 Hz, 2H), 7.61 (s, 2H), 7.55 (d, J=9.0 Hz, 2H), 7.39 (d, J=2.1 Hz, 2H), 7.212 (d, J=6.4 Hz, 2H), 2.69 (s, 6H), 2.43 (m, 4H), 2.34 (s, 6H), 2.02 (s, 6H), 1.87 (s, 3H), 1.82 (m, 2H), 1.27 (m, 6H), 1.19 (m, 12H), 1.07-0.90 (m, 18H), 0.87 (m, 12H).

### Synthesis of a Ligand La123

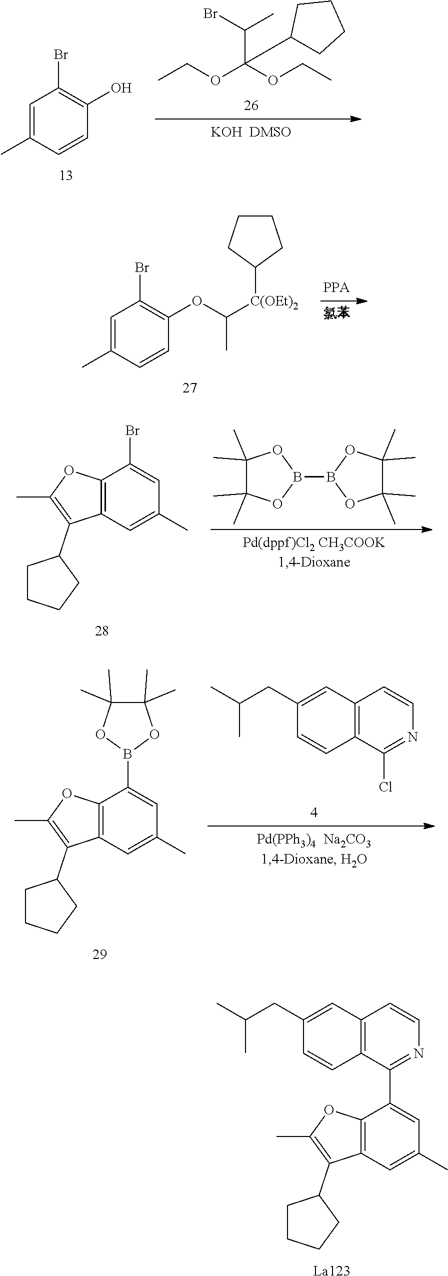

### Synthesis of an Intermediate 27

With reference to synthesis and purification methods of the compound 10, only the corresponding raw materials were required to be changed, and a target compound 27 was obtained. The mass spectrum was: 386.34 (M+H).

### Synthesis of an Intermediate 28

With reference to synthesis and purification methods of the compound 10, only the corresponding raw materials were required to be changed, and a target compound 28 was obtained. The mass spectrum was: 294.20 (M+H).

### Synthesis of an Intermediate 29

With reference to synthesis and purification methods of the compound 2, only the corresponding raw materials were required to be changed, and a target compound 29 was obtained. The mass spectrum was: 341.26 (M+H).

### Synthesis of a Ligand La123

With reference to synthesis and purification methods of the compound La002, only the corresponding raw materials were required to be changed, and a target compound La123 was obtained. The mass spectrum was: 398.55 (M+H).

### Synthesis of a Compound Ir(La123)₂(Lb006)

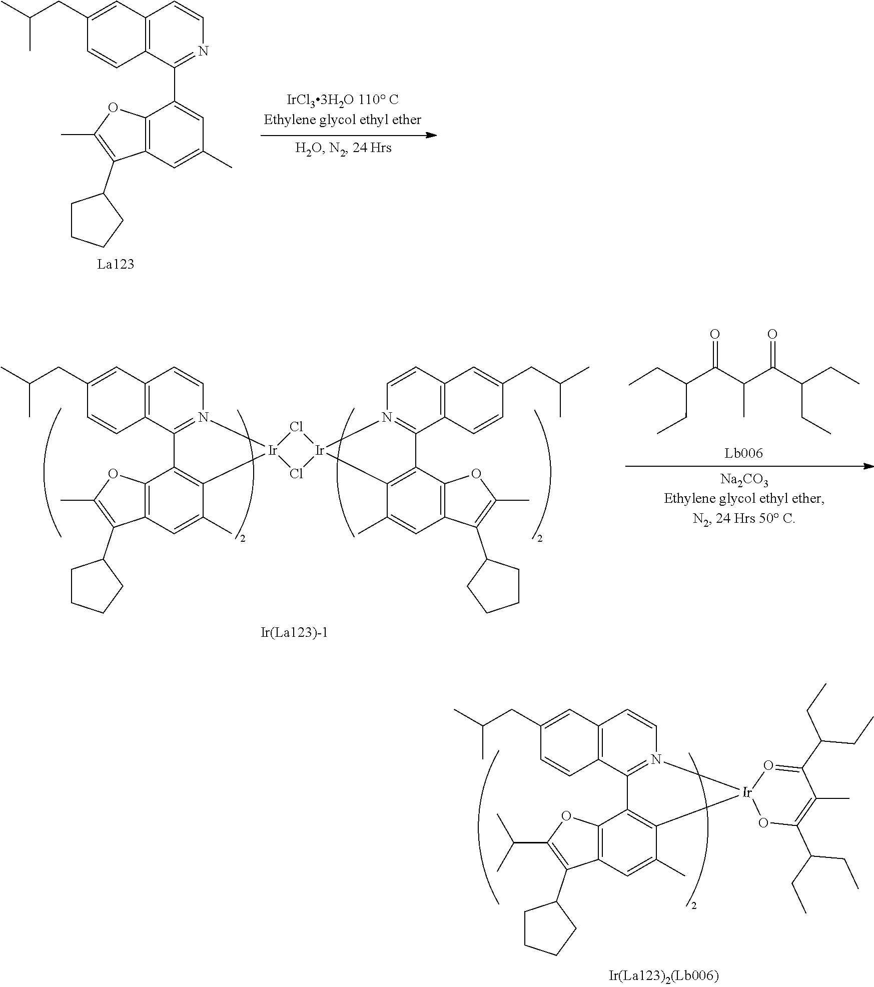

### Synthesis of a Compound Ir(La123)-1

With reference to synthesis and purification methods of the compound Ir(La002)-1, only the corresponding raw materials were required to be changed, and an obtained compound Ir(La123)-1 was directly used in the next step without purification.

### Synthesis of a Compound Ir(La123)₂(Lb006)

With reference to synthesis and purification methods of the compound Ir(La002)₂(Lb005), only the corresponding raw materials were required to be changed, and 1.76 g of a dark red solid compound Ir(La123)₂(Lb006) with a yield of 30.87% was obtained. 1.76 g of the crude product Ir(La123)₂(Lb006) was sublimated and purified to obtain 1.04 g of sublimated and purified Ir(La123)₂(Lb006) with a yield of 61.17%. The mass spectrum was 1121.65 (M+H). ¹H NMR (400 MHz, CDCl₃) δ 8.87 (d, J=8.8 Hz, 2H), 8.23 (d, J=6.4 Hz, 2H), 7.62 (s, 2H), 7.55 (d, J=9.0 Hz, 2H), 7.39 (d, J=2.1 Hz, 2H), 7.23 (d, J=6.4 Hz, 2H), 2.43 (m, 4H), 2.30 (m, 12H), 1.99-1.56 (m, 21H), 1.27 (m, 6H), 1.10-0.81 (m, 30H).

### Synthesis of a Ligand Lc002

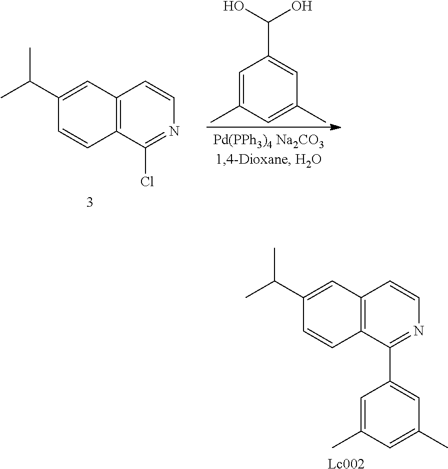

With reference to synthesis and purification methods of the compound La002, only the corresponding raw materials were required to be changed, and a target compound Lc002 was obtained. The mass spectrum was: 276.39 (M+H).

### Synthesis of a Compound Ir(La004)(Lb005)(Lc002)

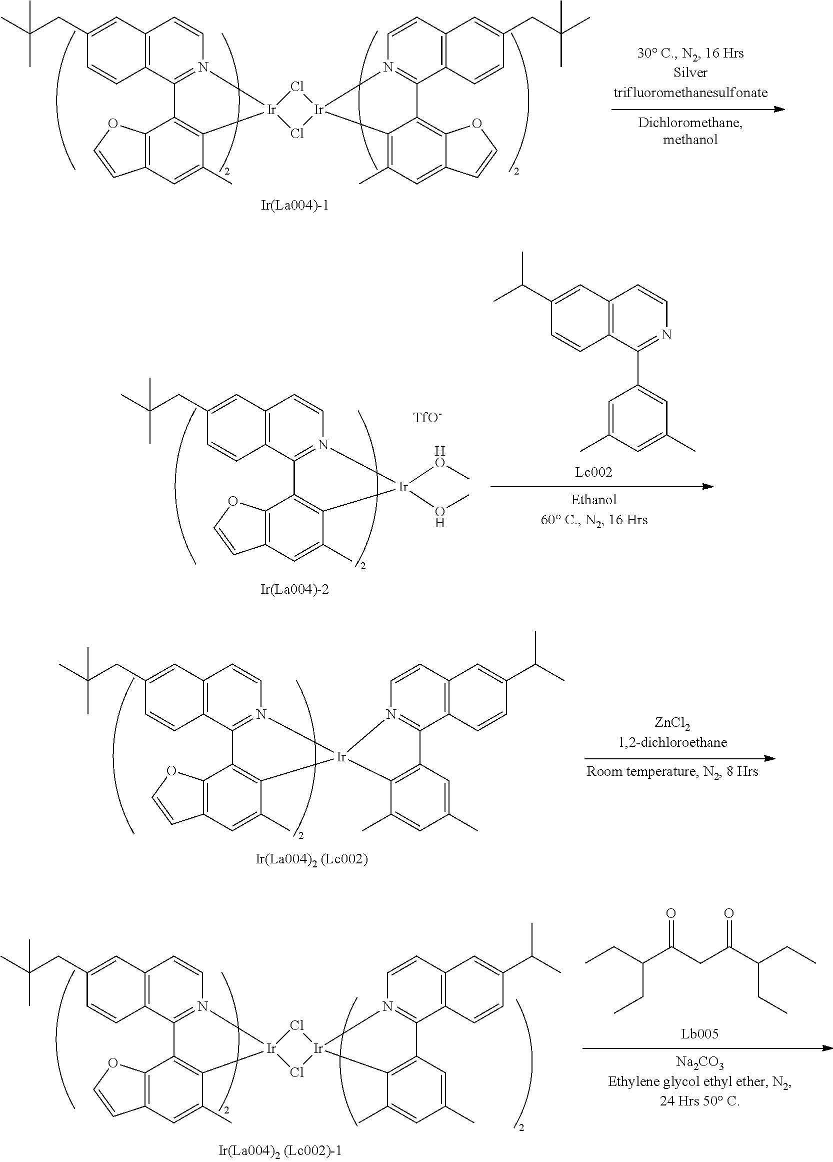

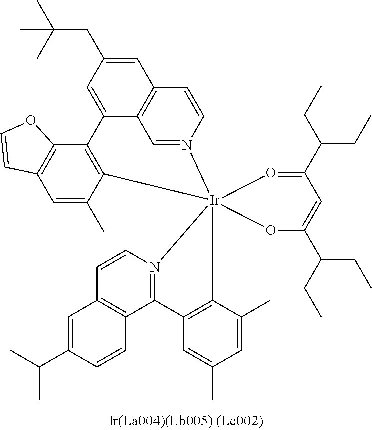

### Synthesis of a Compound Ir(La004)-2

The dimer Ir(La004)-1 (8.64 g, 9.77 mmol, 1.0 eq) and dichloromethane (650 ml) were added into a 3 L three-necked flask and stirred for dissolution. Silver trifluoromethanesulfonate (5.02 g, 19.54 mmol, 2.0 eq) was dissolved in methanol (510 ml) and then added into the original reaction solution flask, vacuumization was performed for replacement for 3 times, and a mixture was stirred at room temperature for 16 hours under the protection of N₂. Then, a reaction solution was filtered with diatomite. A filter residue was rinsed with dichloromethane (150 ml), and a filtrate was spin-dried to obtain 7.3 g of a compound Ir(La004)-2 with a yield of 70.32%. The obtained compound was directly used in the next step without purification.

### Synthesis of a Compound Ir(La004)₂(Lc002)

The compound Ir(La004)-2 (6.8 g, 6.4 mmol, 1.0 eq) and Lc002 (4.41 g, 16.0 mmol, 2.5 eq) were added into a 250 ml three-necked flask, ethanol (70 ml) was added, vacuumization was performed for replacement for 3 times, and a resulting mixture was stirred for reflux for 16 hours under the protection of N₂. After cooling was performed to room temperature, filtration was performed. A solid was collected, dissolved in dichloromethane (150 ml) and filtered with silica gel. Then, a filter cake was rinsed with dichloromethane (50 ml), and a filtrate was spin-dried, recrystallized with tetrahydrofuran/methanol for 2 times (the ratio of the product to the tetrahydrofuran to the methanol was 1:5:10) and then dried to obtain 2.92 g of a compound Ir(La004)₂(Lc002) with a yield of 40.62%. The mass spectrum was: 1124.45 (M+H).

### Synthesis of a Compound Ir(La004)₂(Lc002)-1

The compound Ir(La004)₂(Lc002) (5.9 g, 5.25 mmol, 1.0 eq) and zinc chloride (35.79 g, 262.5 mmol, 50 eq) were put into a 1 L one-necked flask, 1,2-dichloroethane (360 ml) was added, vacuumization was performed for replacement for 3 times, and a resulting mixture was stirred to carry out a reflux reaction for 18 hours under the protection of N₂. According to point-plate monitoring by TLC, the raw material Ir(La004)₂(Lc002) was basically completely reacted. After cooling was performed to room temperature, deionized water (150 ml) was added for washing for 3 times, and a filtrate was spin-dried to obtain 3.71 g of a compound Ir(La004)₂(Lc002)-1 with a yield of 83.40%. The obtained compound was directly used in the next step without purification.

### Synthesis of a Compound Ir(La004)(Lb005)(Lc002)

The compound Ir(La004)₂(Lc002)-1 (3.7 g, 4.37 mmol, 1.0 eq), Lb005 (4.64 g, 21.58 mmol, 5.0 eq) and sodium carbonate (4.63 g, 43.71 mmol, 10.0 eq) were put into a 250 ml one-necked round-bottomed flask, ethylene glycol ethyl ether (55 ml) was added, vacuumization was performed for replacement for 3 times, and a resulting mixture was stirred at 50° C. for 24 hours under the protection of N₂. According to monitoring by TLC, the Ir(La004)₂(Lc002)-1 was completely reacted. After cooling was performed to room temperature, 110 ml of methanol was added for beating at room temperature for 2 hours. Suction filtration was performed, a filter cake was dissolved in dichloromethane (80 ml) and filtered with silica gel, and a filtrate was washed with deionized water (60 ml), followed by liquid separation. Then, an organic phase was collected, concentrated and dried to obtain a dark red solid, and the dark red solid was recrystallized with DMF/MeCN (30 V/20 V) for two times to obtain 1.64 g of a dark red solid compound Ir(La004)(Lb005)(Lc002) with a yield of 37.33%. 1.64 g of the crude product Ir(La004)(Lb005) (Lc002) was sublimated and purified to obtain 0.79 g of sublimated and purified Ir(La004)(Lb005)(Lc002) with a yield of 48.17%. The mass spectrum was: 1007.34 (M+H). ¹H NMR (400 MHz, CDCl₃) δ 8.86 (m, 1H), 8.23 (d, J=6.4 Hz, 2H), 8.07 (m, 2H), 7.78 (d, J=5.0 Hz, 2H), 7.61 (m, 2H), 7.49 (d, J=20.0 Hz, 2H), 6.92 (m, 2H), 6.76 (m, 2H), 4.77 (s, 1H), 2.87 (s, 1H), 2.36 (m, 12H), 1.43-1.12 (m, 14H), 1.10-0.75 (m, 24H).

### Synthesis of a Ligand Lc004

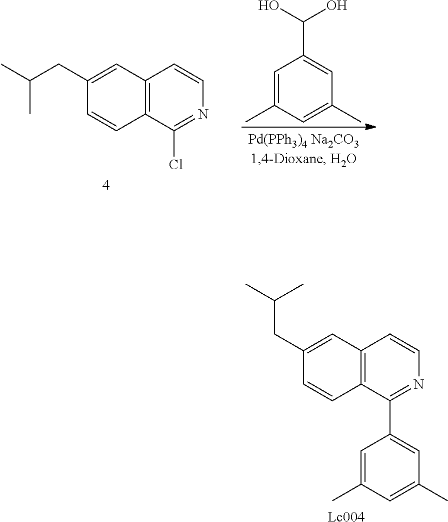

With reference to synthesis and purification methods of the compound La002, only the corresponding raw materials were required to be changed, and a target compound Lc004 was obtained. The mass spectrum was: 290.41 (M+H).

### Synthesis of a Compound Ir(La004)(Lb005)(Lc004)

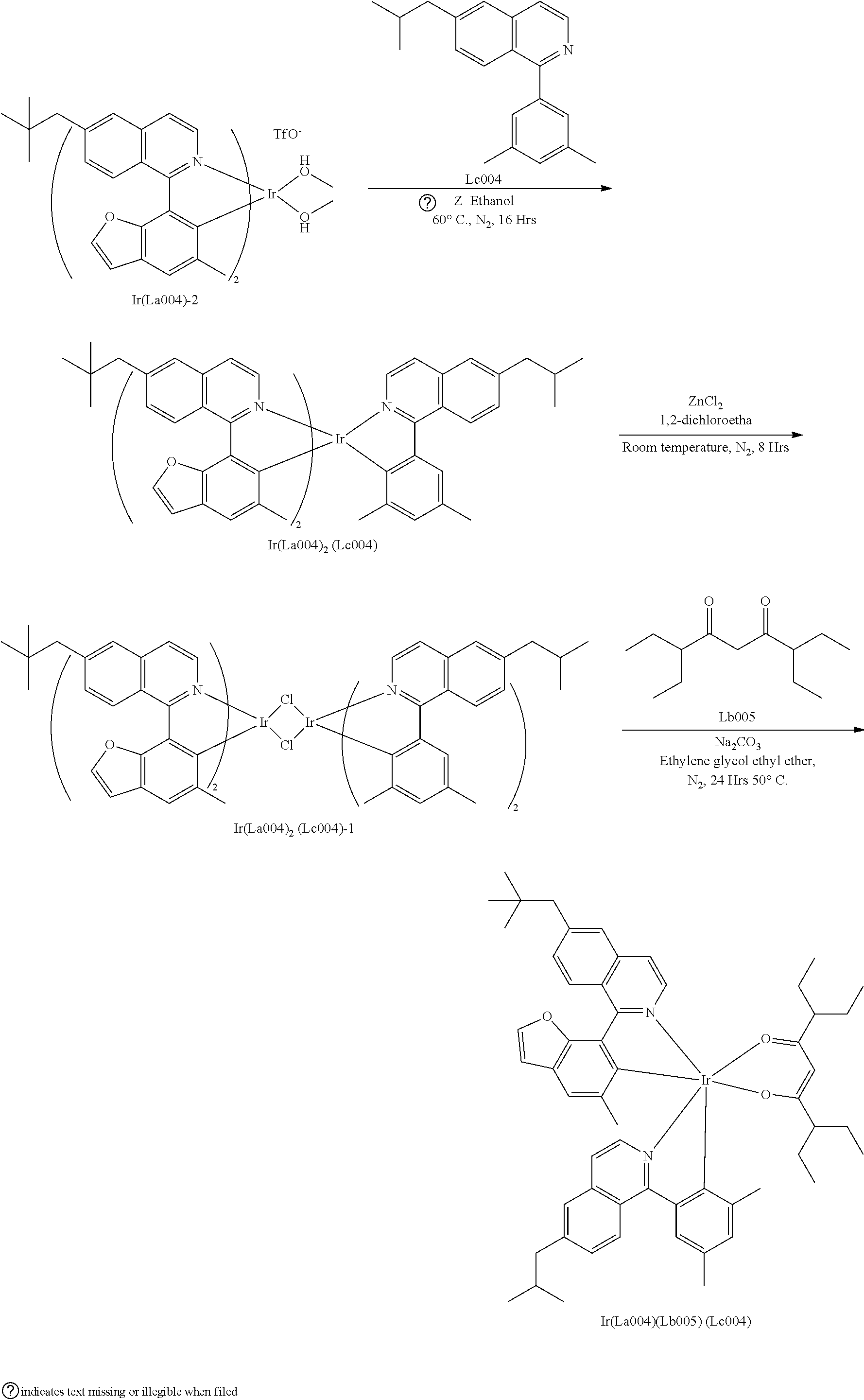

### Synthesis of a Compound Ir(La004)₂(Lc004)

With reference to synthesis and purification methods of the compound Ir(La004)₂(Lc002), only the corresponding raw materials were required to be changed, and a target compound Ir(La004)₂(Lc004) was obtained. The mass spectrum was: 1138.48 (M+H).

### Synthesis of a Compound Ir(La004)₂(Lc004)-1

With reference to synthesis and purification methods of the compound Ir(La004)₂(Lc002)-1, only the corresponding raw materials were required to be changed, and an obtained target compound Ir(La004)₂(Lc004)-1 was directly used in the next step without purification.

### Synthesis of a Compound Ir(La004)(Lb005)(Lc004)

With reference to synthesis and purification methods of the compound Ir(La004)(Lb005)(Lc002), only the corresponding raw materials were required to be changed, and 1.48 g of a dark red solid compound Ir(La004)(Lb005)(Lc004) with a yield of 36.61% was obtained. 1.48 g of the crude product Ir(La004)(Lb005) (Lc004) was sublimated and purified to obtain 0.78 g of sublimated and purified Ir(La004)(Lb005)(Lc004) with a yield of 52.70%. The mass spectrum was: 1121.37 (M+H). ¹H NMR (400 MHz, CDCl₃) δ 8.85 (m, 1H), 8.23 (d, J=6.4 Hz, 2H), 8.07 (m, 2H), 7.78 (d, J=5.0 Hz, 2H), 7.61 (m, 2H), 7.50 (d, J=20.0 Hz, 2H), 6.90 (m, 2H), 6.76 (m, 2H), 4.77 (s, 1H), 2.43 (s, 4H), 2.32 (m, 9H), 1.82 (m, 1H), 1.27 (m, 8H), 1.01 (m, 5H), 0.97-0.80 (m, 24H).

### Synthesis of a Ligand Lc006

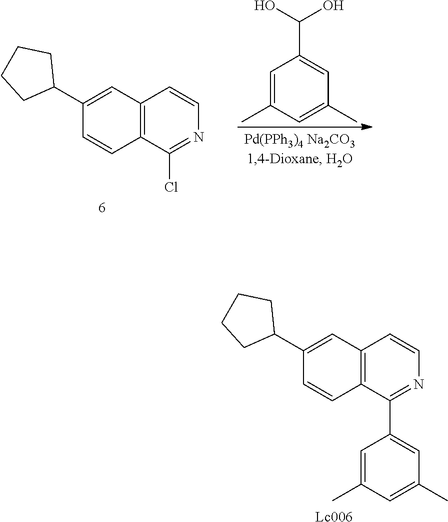

With reference to synthesis and purification methods of the compound La002, only the corresponding raw materials were required to be changed, and a target compound Lc006 was obtained. The mass spectrum was: 302.42 (M+H).

### Synthesis of a Compound Ir(La004)(Lb005)(Lc006)

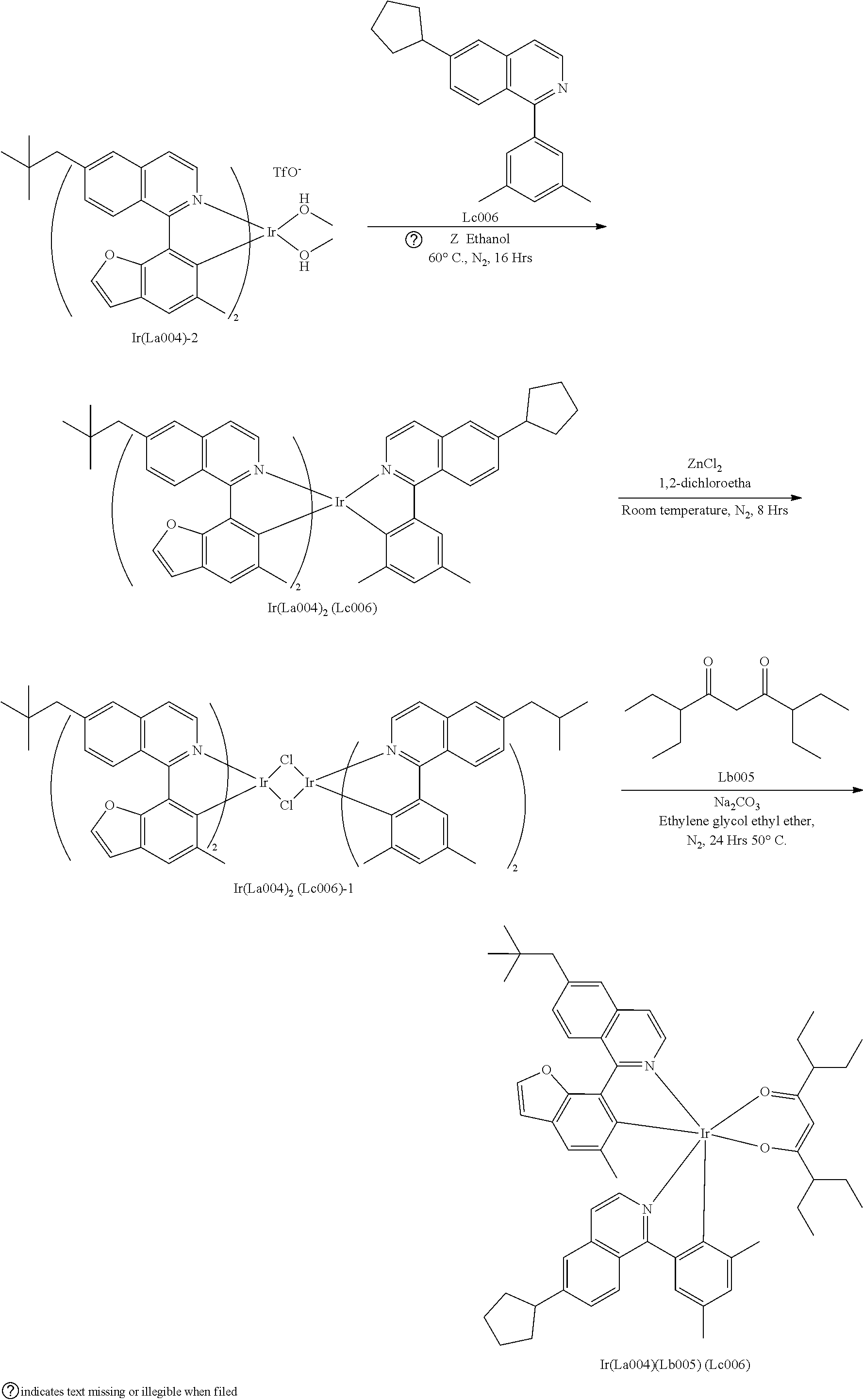

### Synthesis of a compound Ir(La004)₂(Lc006)

With reference to synthesis and purification methods of the compound Ir(La004)₂(Lc002), only the corresponding raw materials were required to be changed, and a target compound Ir(La004)₂(Lc006) was obtained. The mass spectrum was: 1150.48 (M+H).

### Synthesis of a Compound Ir(La004)₂(Lc006)-1

With reference to synthesis and purification methods of the compound Ir(La004)₂(Lc002)-1, only the corresponding raw materials were required to be changed, and an obtained target compound Ir(La004)₂(Lc006)-1 was directly used in the next step without purification.

### Synthesis of a Compound Ir(La004)(Lb005)(Lc006)

With reference to synthesis and purification methods of the compound Ir(La004)(Lb005)(Lc002), only the corresponding raw materials were required to be changed, and 1.87 g of a dark red solid compound Ir(La004)(Lb005)(Lc006) with a yield of 38.98% was obtained. 1.87 g of the crude product Ir(La004)(Lb005) (Lc006) was sublimated and purified to obtain 1.03 g of sublimated and purified Ir(La004)(Lb005)(Lc006) with a yield of 55.08%. The mass spectrum was: 1133.38 (M+H). ¹H NMR (400 MHz, CDCl₃) δ8.86 (d, 1H), 8.23 (d, J=6.4 Hz, 2H), 8.07 (m, 2H), 7.78 (d, J=5.0 Hz, 2H), 7.61 (m, 2H), 7.50 (d, J=20.0 Hz, 2H), 6.90 (m, 2H), 6.76 (m, 2H), 4.78 (s, 1H), 2.44 (s, 2H), 2.32 (d, J=15.0 Hz, 9H), 1.88 (m, 3H), 1.76 (m, 2H), 1.66 (m, 4H), 1.27 (m, 8H), 1.01 (m, 5H), 0.90 (m, 18H).

### Application Example: Manufacturing of an Organic Electroluminescent Device

A glass substrate with a size of 50 mm*50 mm*1.0 mm including an indium tin oxide (ITO, 100 nm) transparent electrode was ultrasonically cleaned in ethanol for 10 minutes, dried at 150° C., and then treated with N₂ plasma for 30 minutes. The washed glass substrate was installed on a substrate support of a vacuum evaporation device. At first, a compound HATCN for covering the transparent electrode was evaporated on the surface of the side having a transparent electrode line to form a thin film with a thickness of 5 nm. Then, a layer of HTM1 was evaporated to form a thin film with a thickness of 60 nm. Then, a layer of HTM2 was evaporated on the HTM1 thin film to form a thin film with a thickness of 10 nm. Then, a host material and a doping compound (including a reference compound X and the compound AX of the present invention) were co-evaporated on the HTM2 film layer to obtain a film with a thickness of 30 nm, where the ratio of the host material to the doping material was 90%:10%. Then, an electron transport layer (ETL, 25 nm) and a LiQ film layer (1 nm) was sequentially evaporated on a light-emitting layer. Finally, a metal Al layer (100 nm) was evaporated to serve as an electrode.

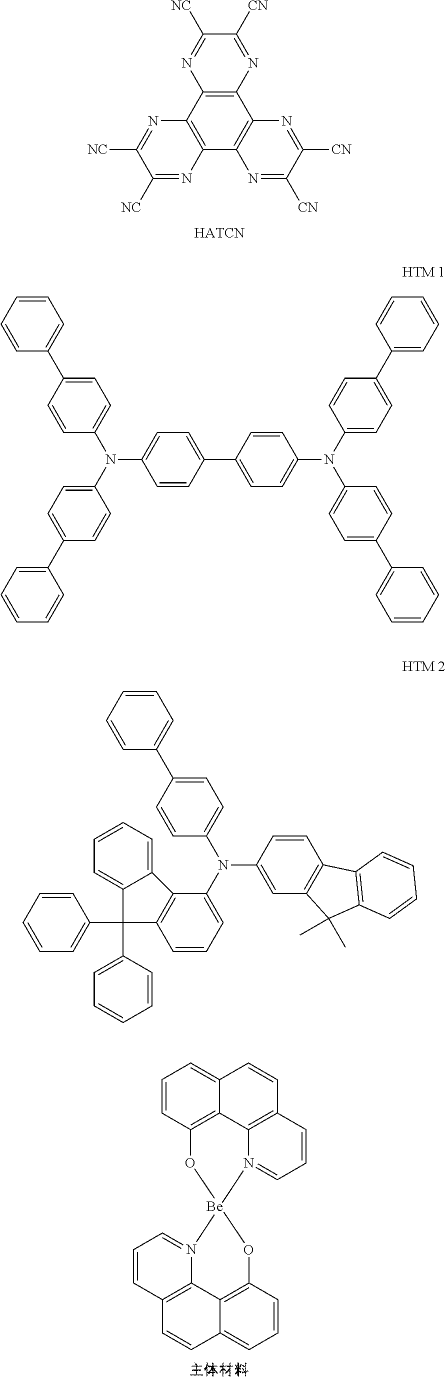

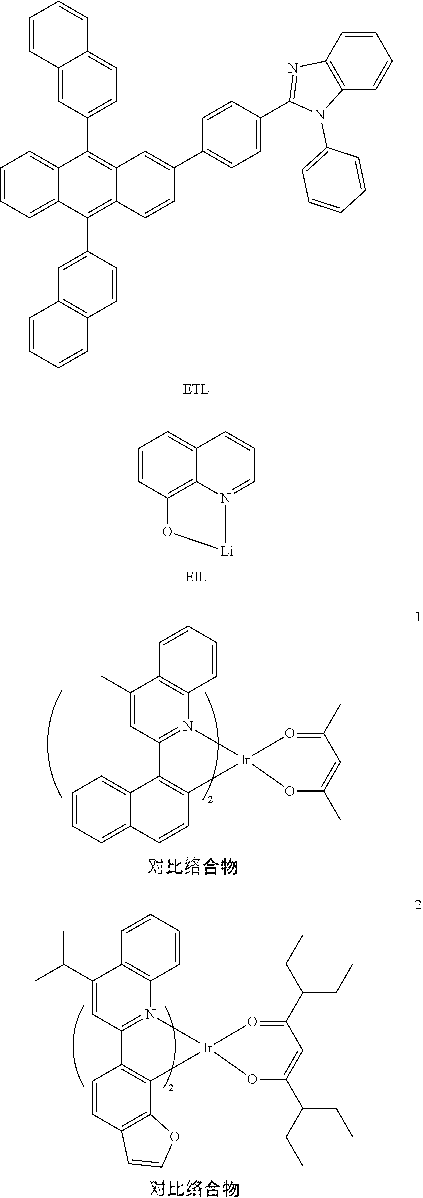

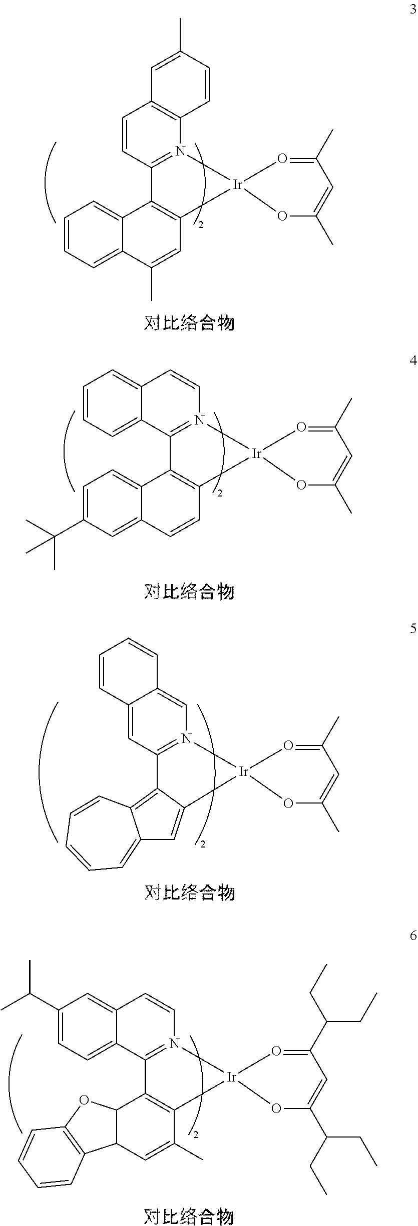

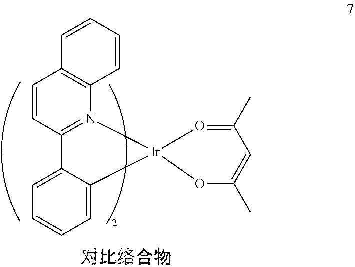

### Evaluation:

Properties of a device obtained above were tested. In various examples and comparative examples, a constant-current power supply (Keithley 2400) was used, a current at a fixed density was used for flowing through light-emitting elements, and a spectroradiometer (CS 2000) was used for testing the light-emitting spectrum. Meanwhile, the voltage value was measured, and the time (LT90) when the brightness was reduced to 90% of the initial brightness was tested. Results are shown as follows.

| | | Peak | | Starting | Current | Chromaticity | |
|---|---|---|---|---|---|---|---|
| | | wavelength | FWHM | voltage | efficiency | coordinate | LT95@ |
| | Doping material | nm | nm | V | Cd/A | CIE x, y | 3000 nits |
| Device 1 | Ir(La002)₂(Lb005) | 628.0 | 50 | 4.16 | 20.8 | 0.69, 0.30 | 242 |
| Device 2 | Ir(La003)₂(Lb005) | 627.5 | 46 | 4.17 | 24.3 | 0.69, 0.30 | 265 |
| Device 3 | Ir(La004)₂(Lb005) | 627.5 | 45 | 4.18 | 24.9 | 0.69, 0.30 | 272 |
| Device 4 | Ir(La007)₂(Lb005) | 628.0 | 50 | 4.21 | 21.6 | 0.69, 0.30 | 283 |
| Device 5 | Ir(La011)₂(Lb007) | 628.0 | 49 | 4.22 | 25.2 | 0.69, 0.30 | 253 |
| Device 6 | Ir(La011)₂(Lb017) | 628.0 | 50 | 4.23 | 25.3 | 0.69, 0.30 | 261 |
| Device 7 | Ir(La003)₂(Lb006) | 627.5 | 46 | 4.19 | 24.5 | 0.69, 0.30 | 278 |
| Device 8 | Ir(La039)₂(Lb006) | 628.5 | 45 | 4.22 | 23.2 | 0.69, 0.30 | 272 |
| Device 9 | Ir(La087)₂(Lb006) | 627.5 | 46 | 4.20 | 24.5 | 0.69, 0.30 | 312 |
| Device 10 | Ir(La099)₂(Lb006) | 628.0 | 47 | 4.21 | 23.9 | 0.69, 0.30 | 288 |
| Device 11 | Ir(La111)₂(Lb006) | 627.5 | 48 | 4.20 | 24.2 | 0.69, 0.30 | 295 |
| Device 12 | Ir(La123)₂(Lb006) | 628.5 | 50 | 4.22 | 22.9 | 0.69, 0.30 | 276 |
| Device 13 | Ir ( La004 ) | 626.5 | 52 | 4.24 | 21.9 | 0.69, 0.30 | 241 |
| | (Lb005) (Lc002) | | | | | | |
| Device 14 | Ir ( La004 ) | 626.5 | 51 | 4.22 | 23.2 | 0.69, 0.30 | 252 |
| | (Lb005) (Lc004) | | | | | | |
| Device 15 | Ir ( La004 ) | 626.5 | 51 | 4.23 | 23.7 | 0.69, 0.30 | 247 |
| | (Lb005) (Lc006) | | | | | | |
| Comparative | Reference | 638 | 50 | 4.8 | 9.7 | 0.69, 0.30 | 78 |
| Example 1 | complex 1 | | | | | | |
| Comparative | Reference | 643 | 48 | 5.0 | 10.0 | 0.70, 0.29 | 131 |
| Example 2 | complex 2 | | | | | | |
| Comparative | Reference | 640 | 49 | 4.9 | 9.8 | 0.69, 0.30 | 85 |
| Example 3 | complex 3 | | | | | | |
| Comparative | Reference | 642 | 60 | 5.1 | 11.8 | 0.67, 0.31 | 98 |
| Example 4 | complex 4 | | | | | | |
| Comparative | Reference | 678 | 82 | 4.6 | 4.5 | 0.70, 0.29 | 55 |
| Example 5 | complex 5 | | | | | | |
| Comparative | Reference | 616 | 43 | 4.16 | 30.3 | 0.68, 0.32 | 222 |
| Example 6 | complex 6 | | | | | | |
| Comparative | Reference | 606 | 56 | 4.39 | 20.2 | 0.62, 0.38 | 148 |
| Example 7 | complex 7 | | | | | | |

Through comparison of the data in the above table, it can be seen that compared with reference compounds, the compound of the present invention used as a dopant in an organic electroluminescent device has more excellent properties, such as driving voltage, luminous efficiency and device life. In particular, compared with a reference complex 6, the compound of the present invention has the surprising advantages that under the condition of reducing conjugation and an electron pushing property at a highest occupied molecular orbital (HOMO) energy level, a device has a more saturated luminescence property and a deeper red emission wavelength, and the device life is improved by 10% or above. Compared with Comparative Example 2, more blue shift emission is brought by changes of a connection mode, thereby improving the luminous efficiency.

The above results show that the compound of the present invention has the advantages of high optical and electrical stability, low sublimation temperature, small emission half-peak width, high color saturation, high luminous efficiency, long device life and the like, and can be used in organic electroluminescent devices. In particular, the compound has the potential for application in the OLED industry as a red light-emitting dopant.

1. An organometallic iridium compound, having a general formula of Ir(La)(Lb)(Lc), wherein La is a structure represented by Formula (1): 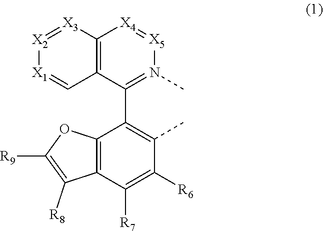
wherein dotted lines refer to positions connected to the metal Ir;
X₁ is N or CR₁, X₂ is N or CR₂, X₃ is N or CR₃, X₄ is N or CR₄, and X₅ is N or CR₅;
R₁-R₅ are independently selected from hydrogen, deuterium, halogen, cyano, substituted or unsubstituted C₁-C₁₀ alkyl, substituted or unsubstituted C₁-C₁₀ heteroalkyl, substituted or unsubstituted C₃-C₂₀ cycloalkyl, substituted or unsubstituted C₂-C₁₀ alkenyl, substituted or unsubstituted C₂-C₁₀ alkynyl, substituted or unsubstituted C₆-C₁₈ aryl, substituted or unsubstituted C₂-C₁₇ heteroaryl, substituted or unsubstituted tri-C₁-C₁₀ alkyl silyl, substituted or unsubstituted tri-C₆-C₁₂ aryl silyl, substituted or unsubstituted di-C₁-C₁₀ alkyl mono-C₆-C₃₀ aryl silyl, and substituted or unsubstituted mono-C₁-C₁₀ alkyl di-C₆-C₃₀ aryl silyl, or any two adjacent groups of the R₁-R₅ are connected to each other to form an aliphatic ring or an aromatic ring;
at most one of the X₁-X₅ is N, and when the X₁-X₅ are CR₁-CR₅, at least one of the R₁-R₅ is not H;
R₆-R₉ are independently selected from hydrogen, deuterium, halogen, substituted or unsubstituted C₁-C₁₀ alkyl, and substituted or unsubstituted C₃-C₂₀ cycloalkyl, and the R₆ is not hydrogen, deuterium, or halogen;
the heteroalkyl and the heteroaryl at least contain one O, N or S heteroatom;
and the “substituted” as described in R₁-R₉ refers to substitution with deuterium, F, Cl, Br, C₁-C₆ alkyl, C₃-C₆ cycloalkyl, amino substituted with C₁-C₆ alkyl, cyano, isocyano, or phosphino, and the substitution ranges from a single substitution number to a maximum substitution number;
Lb is a structure represented by Formula (2): 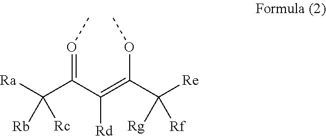
wherein dotted lines refer to positions connected to the metal Ir;
Ra-Rg are independently selected from hydrogen, deuterium, halogen, substituted or unsubstituted C₁-C₁₀ alkyl, substituted or unsubstituted C₃-C₂₀ cycloalkyl, substituted or unsubstituted C₁-C₁₀ heteroalkyl, and substituted or unsubstituted C₃-C₂₀ heterocyclic alkyl, or any two of the Ra, the Rb and the Rc are connected to form an aliphatic ring, and any two of the Re, the Rf and the Rg are connected to form an aliphatic ring;
the heteroalkyl and the heterocyclic alkyl at least contain one O, N or S heteroatom;
and the “substituted” as described in Ra-Rg refers to substitution with deuterium, F, Cl, Br, C₁-C₄ alkyl, C₁-C₄ alkoxyl, C₃-C₆ cycloalkyl,
amino substituted with C₁-C₄ alkyl, cyano, isocyano, or phosphino;
Le is a monoanionic bidentate ligand, and the Le is different from the Lb and is not an OO ligand;
and the Lc and the La are the same or different, and the different indicates different parent nuclear structures, a same parent nuclear structure with different substituents, or a same parent nuclear structure with different substituent positions.

2. The organometallic iridium compound according to claim 1, wherein the La is a structure represented by Formula (3): 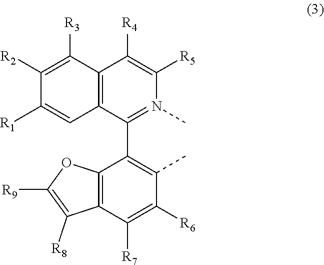
wherein dotted lines refer to positions connected to the metal Ir;
R₁-R₅ are independently selected from hydrogen, deuterium, halogen, cyano, substituted or unsubstituted C₁-C₁₀ alkyl, substituted or unsubstituted C₁-C₁₀ heteroalkyl, substituted or unsubstituted C₃-C₂₀ cycloalkyl, substituted or unsubstituted C₂-C₁₀ alkenyl, substituted or unsubstituted C₂-C₁₀ alkynyl, substituted or unsubstituted C₆-C₁₈ aryl, substituted or unsubstituted C₂-C₁₇ heteroaryl, substituted or unsubstituted tri-C₁-C₁₀ alkyl silyl, substituted or unsubstituted tri-C₆-C₁₂ aryl silyl, substituted or unsubstituted di-C₁-C₁₀ alkyl mono-C₆-C₃₀ aryl silyl, and substituted or unsubstituted mono-C₁-C₁₀ alkyl di-C₆-C₃₀ aryl silyl, or any two adjacent groups of the R₁-R₅ are connected to each other to form an aliphatic ring or an aromatic ring, and at least one of the R₁-R₅ is not H;
R₆-R₉ are independently selected from hydrogen, deuterium, halogen, substituted or unsubstituted C₁-C₁₀ alkyl, and substituted or unsubstituted C₃-C₂₀ cycloalkyl, and the R₆ is not hydrogen, deuterium, or halogen;
the heteroalkyl and the heteroaryl at least contain one O, N or S heteroatom;
and the “substituted” as described in R₁-R₉ refers to substitution with deuterium, F, Cl, Br, C₁-C₆ alkyl, C₃-C₆ cycloalkyl, amino substituted with C₁-C₆ alkyl, cyano, iso cyano, or phosphino, and the substitution ranges from a single substitution number to a maximum substitution number.

3. The organometallic iridium compound according to claim 2, wherein in Formula (3), the R₆ is substituted or unsubstituted C₁-C₆ alkyl, or substituted or unsubstituted C₃-C₁₀ cycloalkyl.

4. The organometallic iridium compound according to claim 3, wherein in Formula (3), the R₆ is substituted or unsubstituted methyl, substituted or unsubstituted isopropyl, or substituted or unsubstituted cyclopentyl; and the “substituted” as described in R₆ refers to substitution with deuterium, F, Cl, or Br.

5. The organometallic iridium compound according to claim 4, wherein in Formula (3), the R₇ is hydrogen, deuterium, or halogen.

6. The organometallic iridium compound according to claim 2, wherein at least one of the R₈ and the R₉ is not hydrogen.

7. The organometallic iridium compound according to claim 6, wherein both the R₈ and the R₉ are not hydrogen.

8. The organometallic iridium compound according to claim 7, wherein at least one of the R₈ and the R₉ is substituted or unsubstituted C₁-C₆ alkyl, or substituted or unsubstituted C₃-C₁₀ cycloalkyl.

9. The organometallic iridium compound according to claim 2, wherein in Formula (3), the R₂ and/or the R₅ is not hydrogen.

10. The organometallic iridium compound according to claim 9, wherein in Formula (3), the R₂ is substituted or unsubstituted C₁-C₆ alkyl, or substituted or unsubstituted C₃-C₁₀ cycloalkyl, and the R₁ and the R₃-R₅ are independently selected from hydrogen.

11. The organometallic iridium compound according to claim 2, wherein the Lc and the La are different.

12. The organometallic iridium compound according to claim 11, wherein the Lc is a structure represented by Formula (4): 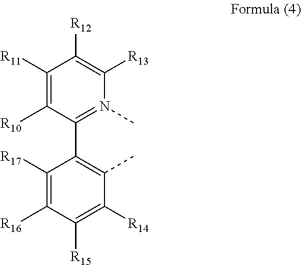
wherein dotted lines refer to positions connected to the metal Ir;
R₁₀-R₁₇ are independently selected from hydrogen, deuterium, halogen, cyano, hydroxyl, amino group, amino, substituted or unsubstituted C₁-C₁₀ alkyl, substituted or unsubstituted C₁-C₁₀ heteroalkyl, substituted or unsubstituted C₃-C₂₀ cycloalkyl, substituted or unsubstituted C₂-C₁₀ alkenyl, substituted or unsubstituted C₂-C₁₀ alkynyl, substituted or unsubstituted C₆-C₁₈ aryl, substituted or unsubstituted C₂-C₁₇ heteroaryl, substituted or unsubstituted tri-C₁-C₁₀ alkyl silyl, substituted or unsubstituted tri-C₆-C₁₂ aryl silyl, substituted or unsubstituted di-C₁-C₁₀ alkyl mono-C₆-C₃₀ aryl silyl, and substituted or unsubstituted mono-C₁-C₁₀ alkyl di-C₆-C₃₀ aryl silyl;
at least two of the R₁₄-R₁₇ are not hydrogen;
at least two adjacent groups of the R₁₀-R₁₃ may form an aromatic ring represented by the following Formula (5): 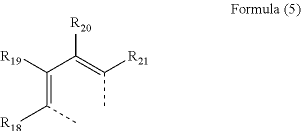
in Formula (5),
dotted lines refer to positions connected to a pyridine ring;
R₁₈-R₂₁ are independently selected from hydrogen, deuterium, halogen, cyano, substituted or unsubstituted C₁-C₁₀ alkyl, substituted or unsubstituted C₁-C₁₀ heteroalkyl, substituted or unsubstituted C₃-C₂₀ cycloalkyl, substituted or unsubstituted C₂-C₁₀ alkenyl, substituted or unsubstituted C₂-C₁₀ alkynyl, substituted or unsubstituted C₆-C₁₈ aryl, substituted or unsubstituted C₂-C₁₇ heteroaryl, substituted or unsubstituted tri-C₁-C₁₀ alkyl silyl, substituted or unsubstituted tri-C₆-C₁₂ aryl silyl, substituted or unsubstituted di-C₁-C₁₀ alkyl mono-C₆-C₃₀ aryl silyl, and substituted or unsubstituted mono-C₁-C₁₀ alkyl di-C₆-C₃₀ aryl silyl, or any two adjacent groups of the R₁₈-R₂₁ are connected to each other to form an aliphatic ring or an aromatic ring;
the heteroalkyl and the heteroaryl at least contain one O, N or S heteroatom;
and the “substituted” as described in R₁₀-R₂₁ refers to substitution with deuterium, F, Cl, Br, C₁-C₆ alkyl, C₃-C₆ cycloalkyl, amino substituted with C₁-C₆ alkyl, cyano, isocyano, or phosphino, and the substitution ranges from a single substitution number to a maximum substitution number.

13. The organometallic iridium compound according to claim 2, wherein the La has one of the following structural formulas, or is partially or completely deuterated or fluorinated correspondingly,

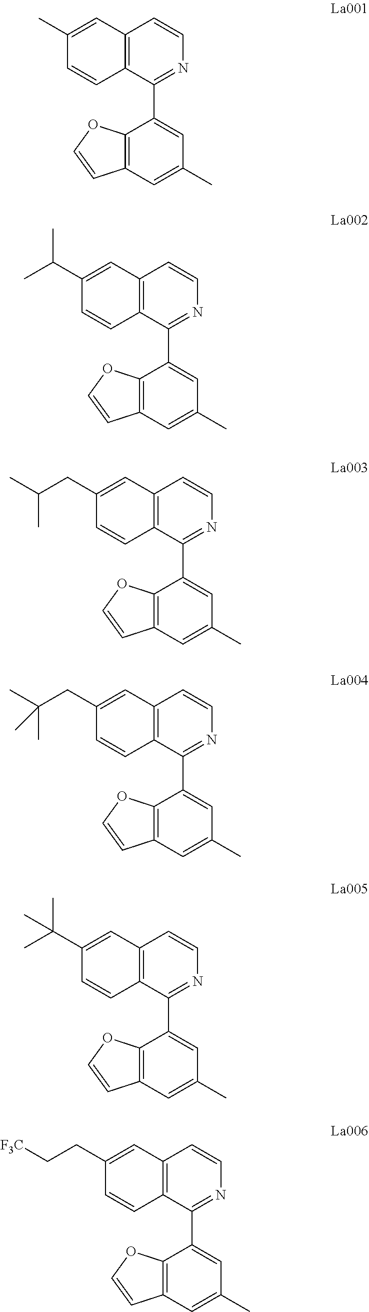

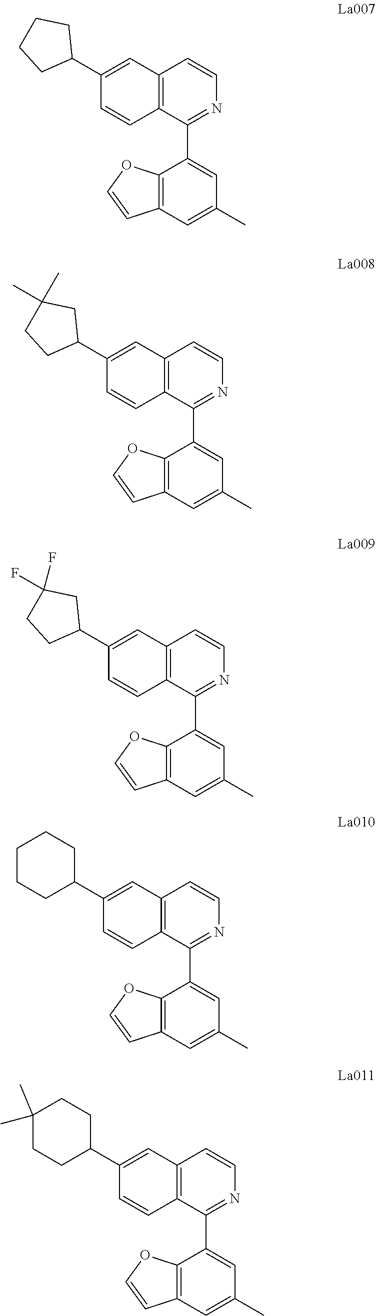

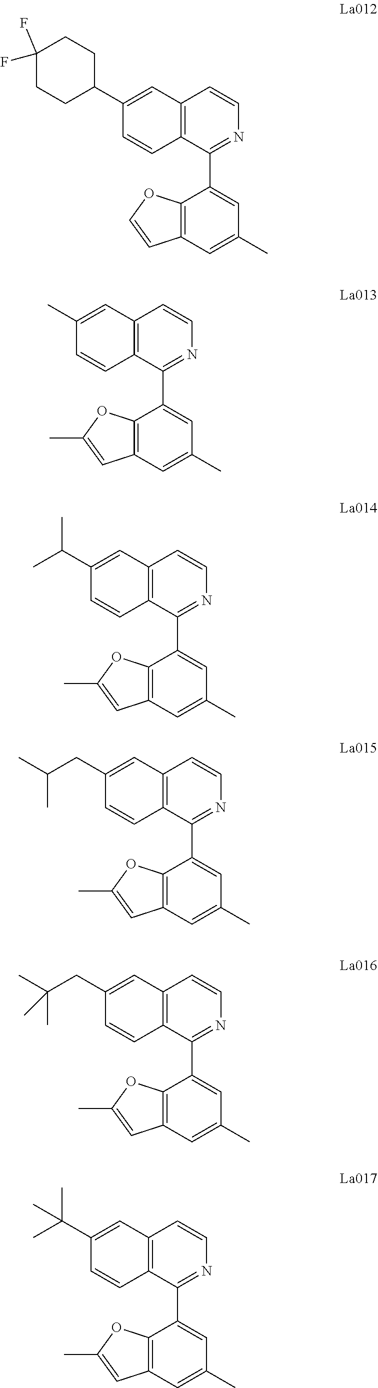

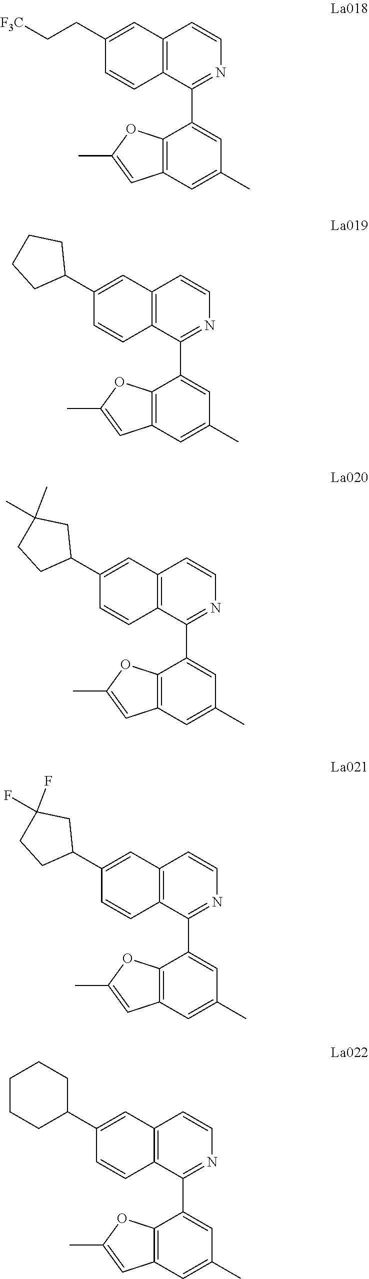

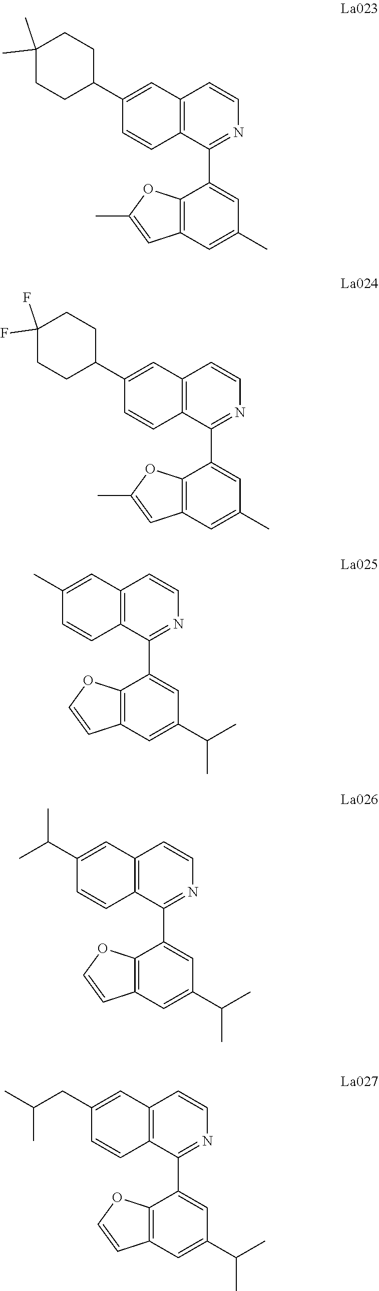

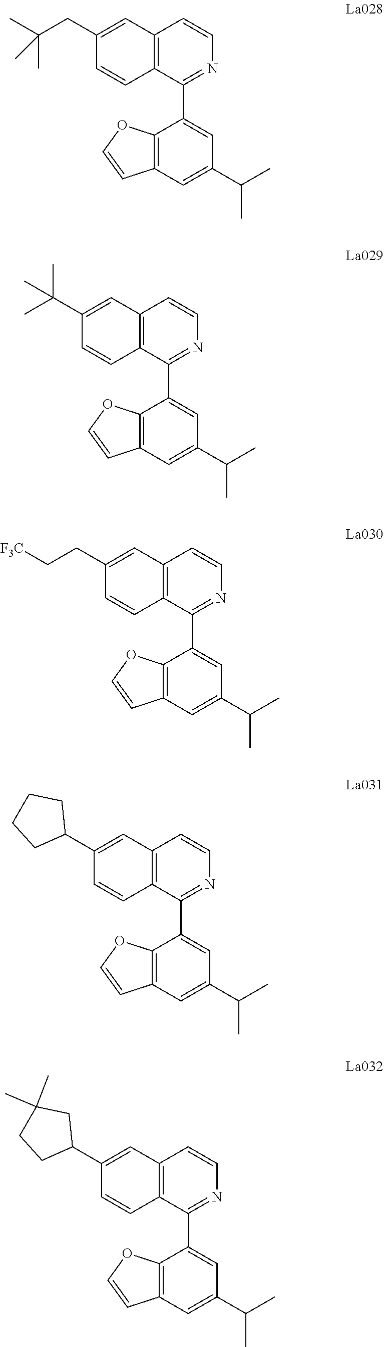

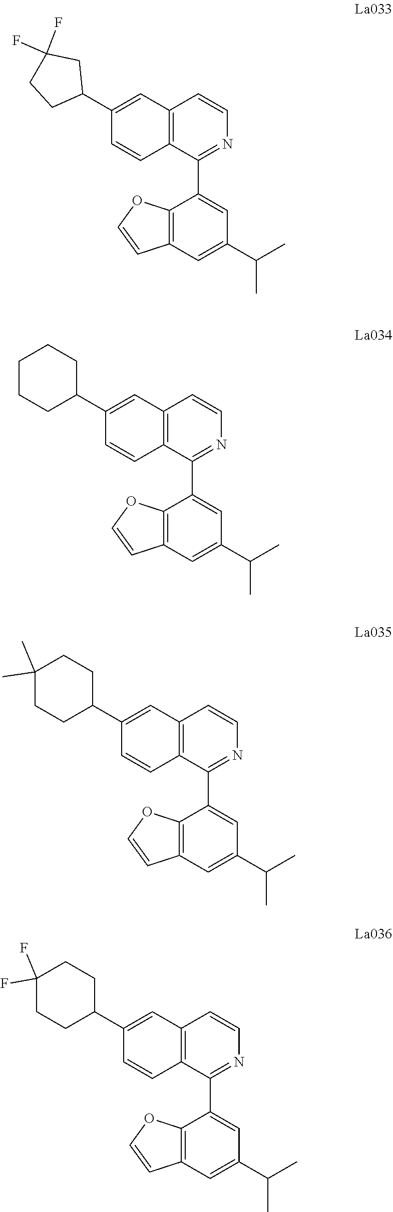

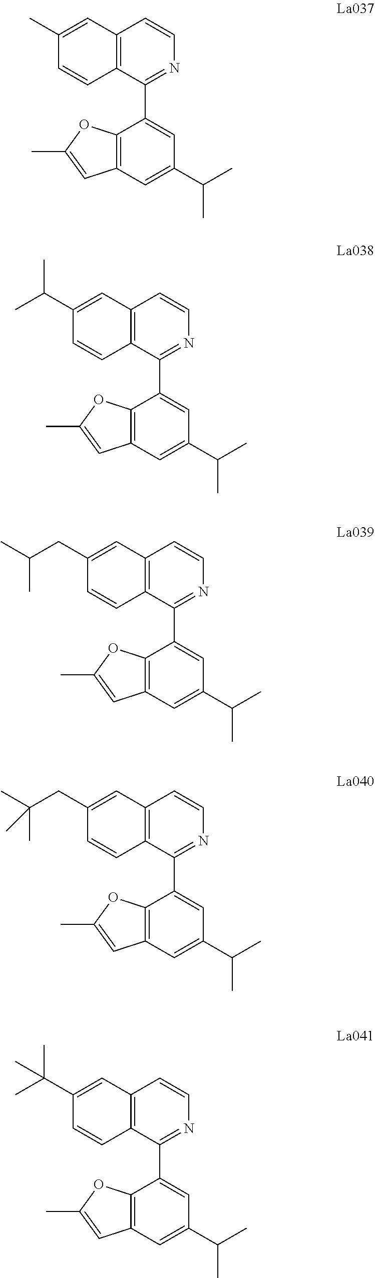

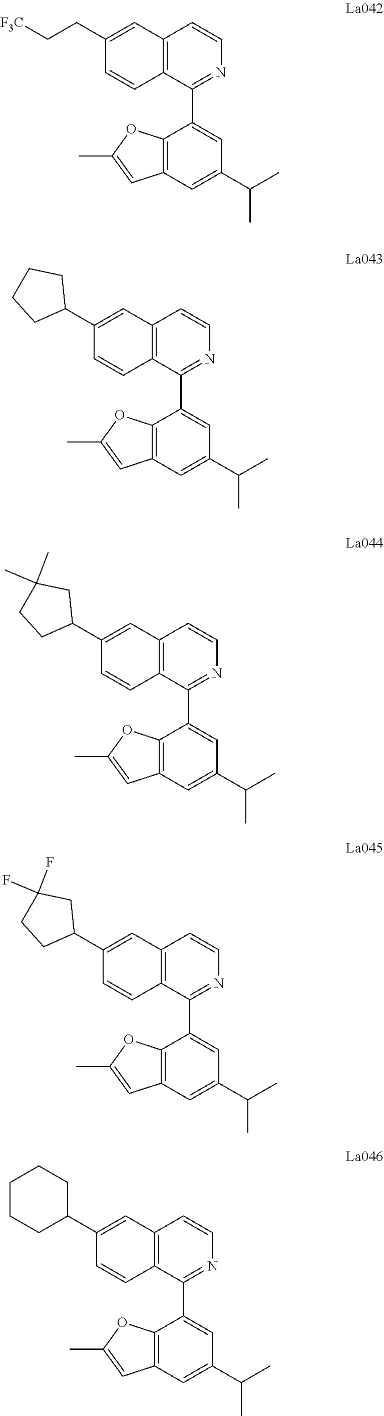

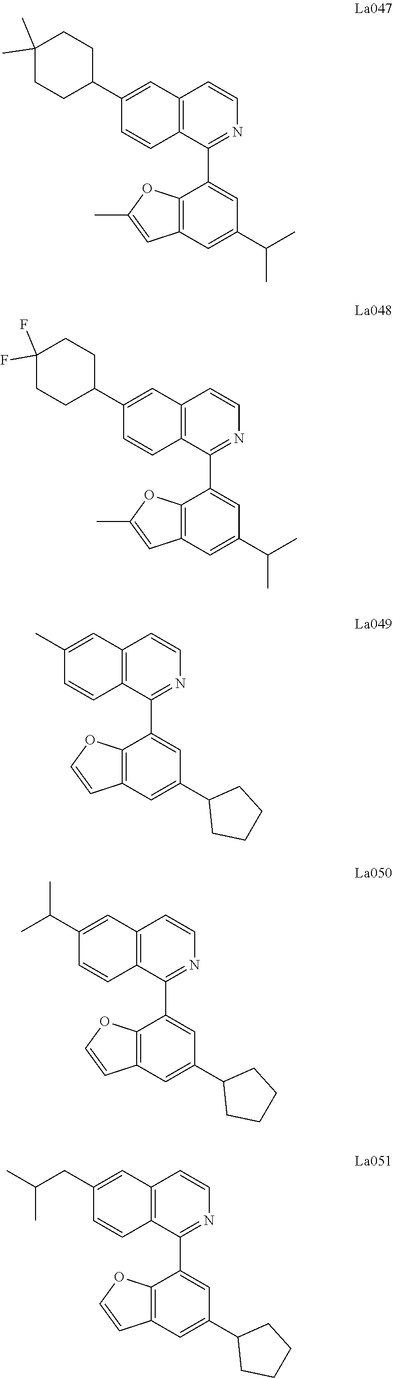

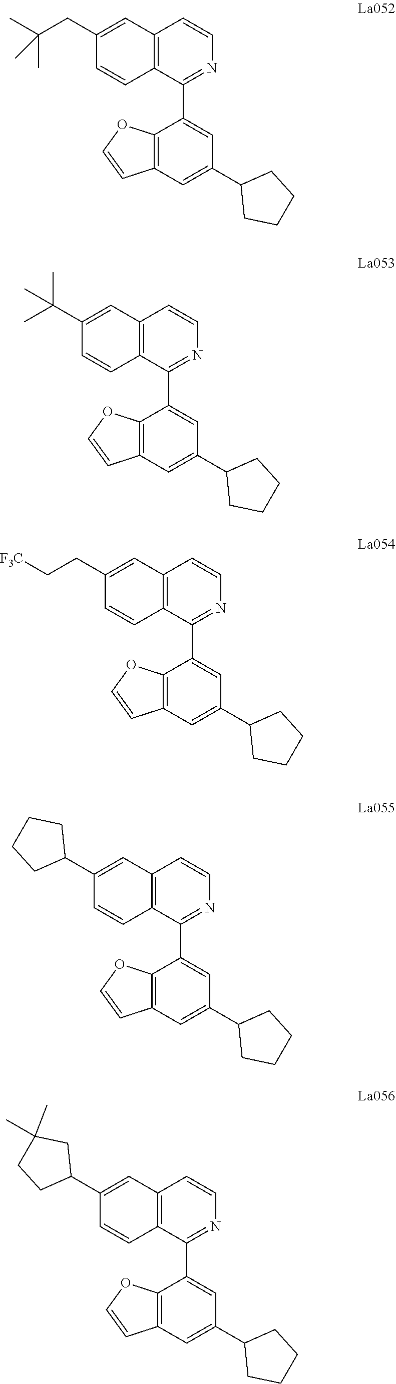 [SMILES: CC(C)(C)Cc1ccc2c(-c3cc(C4CCCC4)cc4ccoc34)nccc2c1 ; CC(C)(C)c1ccc2c(-c3cc(C4CCCC4)cc4ccoc34)nccc2c1 ; FC(F)(F)CCc1ccc2c(-c3cc(C4CCCC4)cc4ccoc34)nccc2c1 ; c1cc2cc(C3CCCC3)ccc2c(-c2cc(C3CCCC3)cc3ccoc23)n1 ; CC1(C)CCC(c2ccc3c(-c4cc(C5CCCC5)cc5ccoc45)nccc3c2)C1]

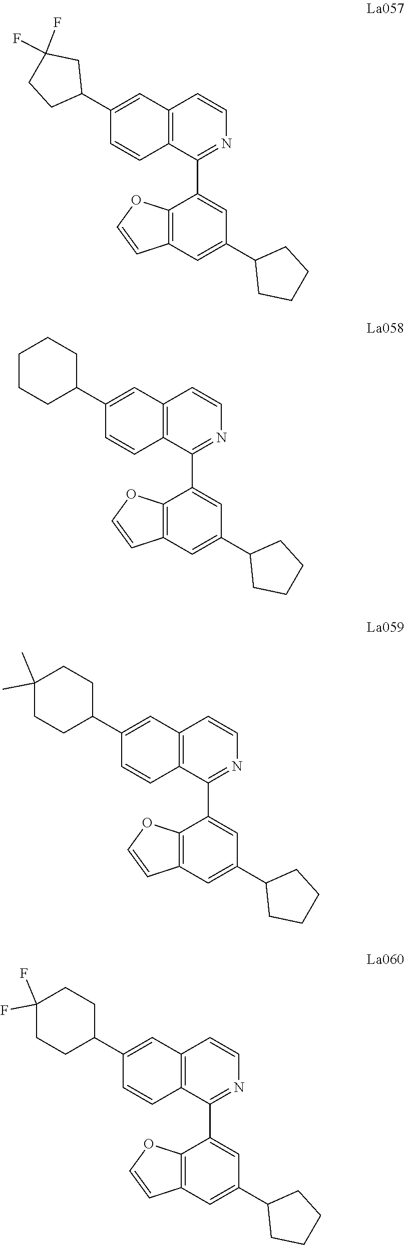 [SMILES: FC1(F)CCC(c2ccc3c(-c4cc(C5CCCC5)cc5ccoc45)nccc3c2)C1 ; c1cc2cc(C3CCCCC3)ccc2c(-c2cc(C3CCCC3)cc3ccoc23)n1 ; CC1(C)CCC(c2ccc3c(-c4cc(C5CCCC5)cc5ccoc45)nccc3c2)CC1 ; FC1(F)CCC(c2ccc3c(-c4cc(C5CCCC5)cc5ccoc45)nccc3c2)CC1]

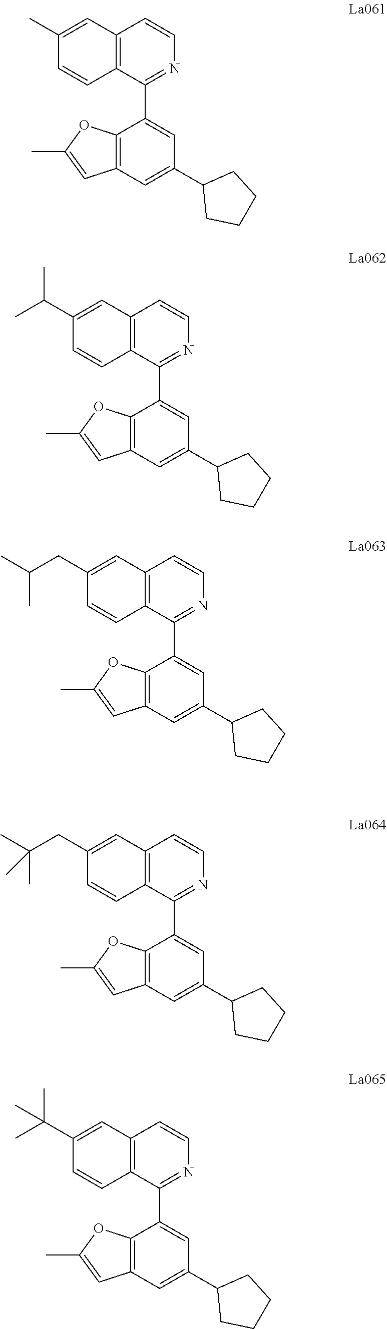 [SMILES: Cc1ccc2c(-c3cc(C4CCCC4)cc4cc(C)oc34)nccc2c1 ; Cc1cc2cc(C3CCCC3)cc(-c3nccc4cc(C(C)C)ccc34)c2o1 ; Cc1cc2cc(C3CCCC3)cc(-c3nccc4cc(CC(C)C)ccc34)c2o1 ; Cc1cc2cc(C3CCCC3)cc(-c3nccc4cc(CC(C)(C)C)ccc34)c2o1 ; Cc1cc2cc(C3CCCC3)cc(-c3nccc4cc(C(C)(C)C)ccc34)c2o1]

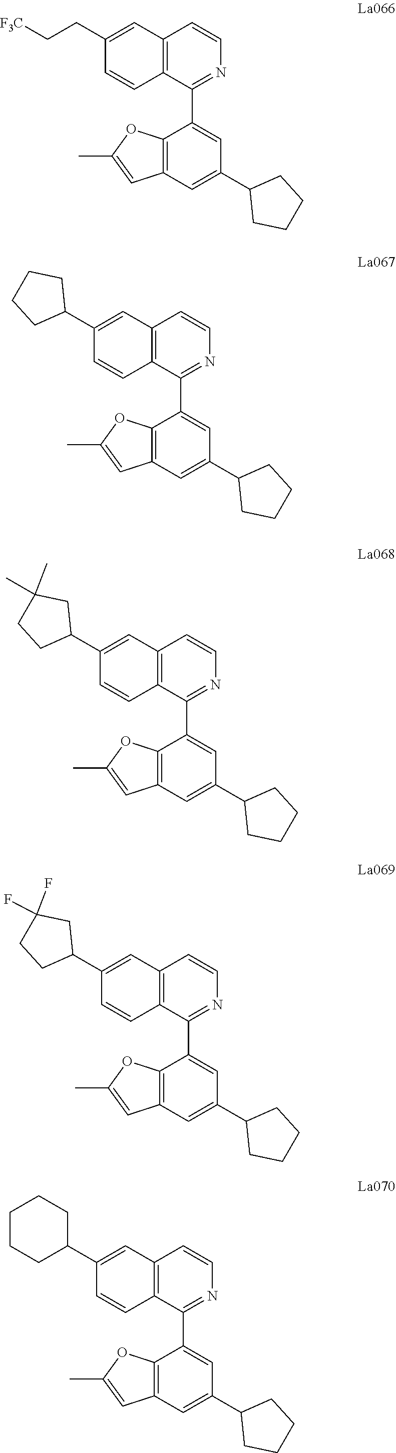 [SMILES: Cc1cc2cc(C3CCCC3)cc(-c3nccc4cc(CCC(F)(F)F)ccc34)c2o1 ; Cc1cc2cc(C3CCCC3)cc(-c3nccc4cc(C5CCCC5)ccc34)c2o1 ; Cc1cc2cc(C3CCCC3)cc(-c3nccc4cc(C5CCC(C)(C)C5)ccc34)c2o1 ; Cc1cc2cc(C3CCCC3)cc(-c3nccc4cc(C5CCC(F)(F)C5)ccc34)c2o1 ; Cc1cc2cc(C3CCCC3)cc(-c3nccc4cc(C5CCCCC5)ccc34)c2o1]

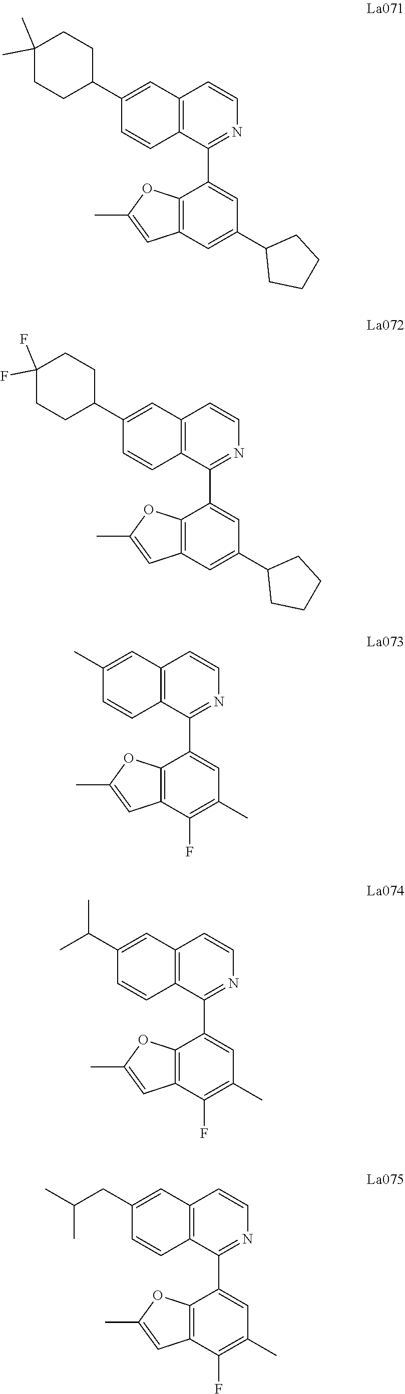

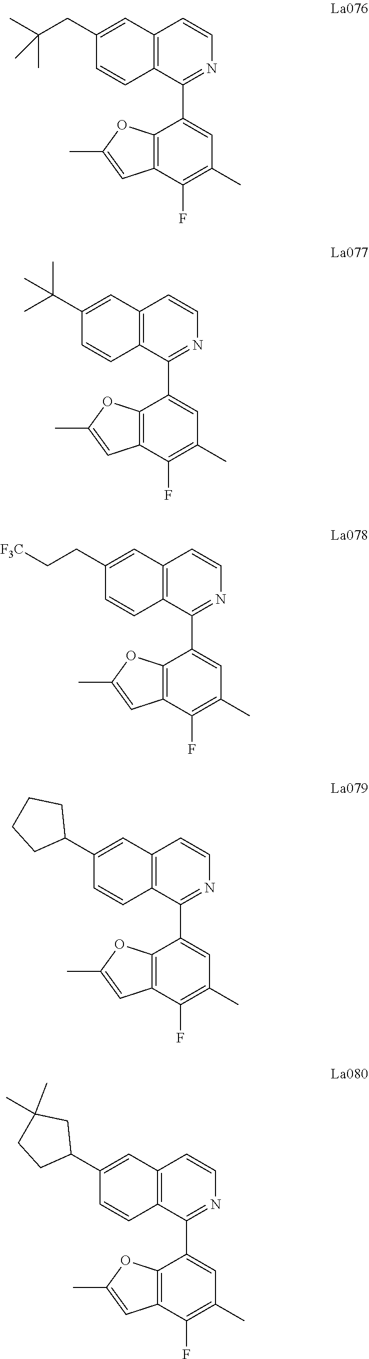

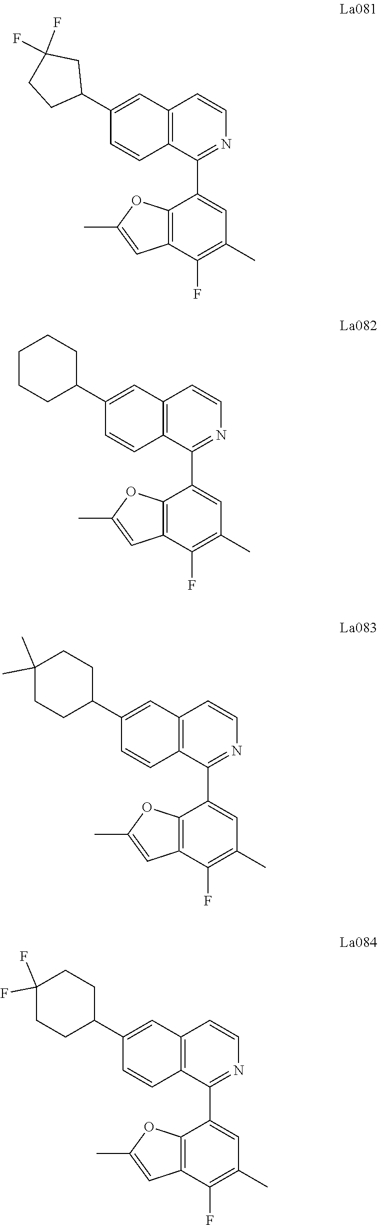

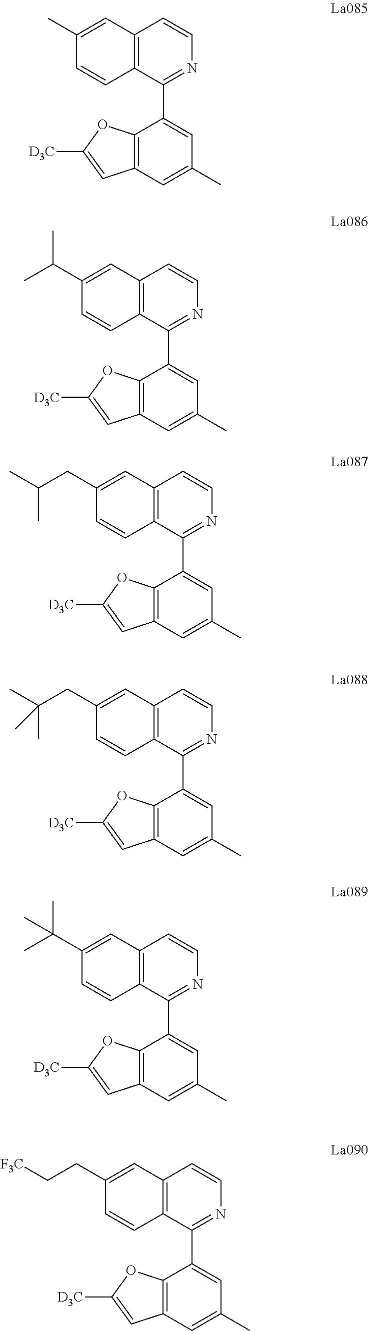

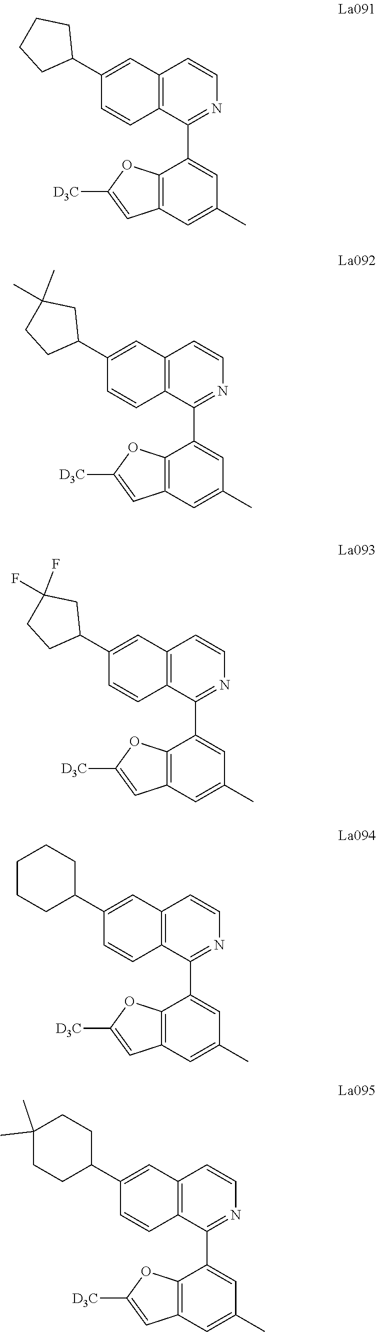

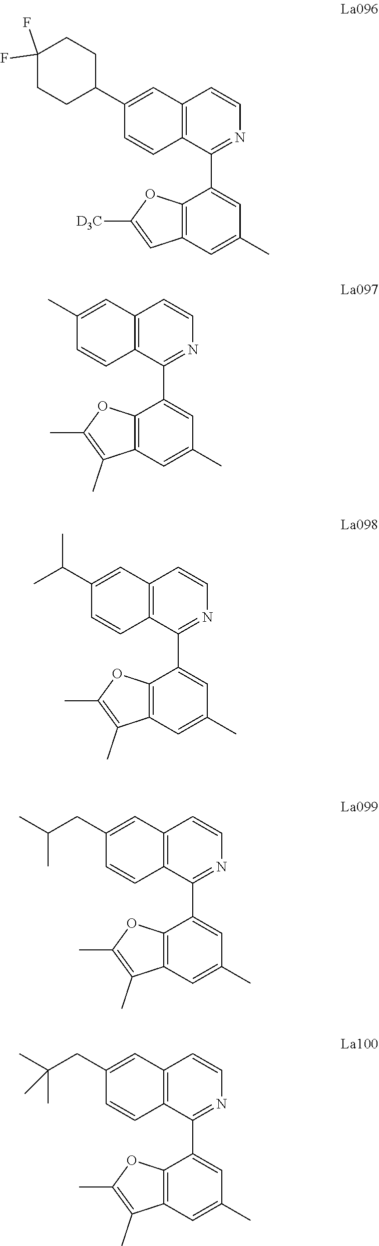

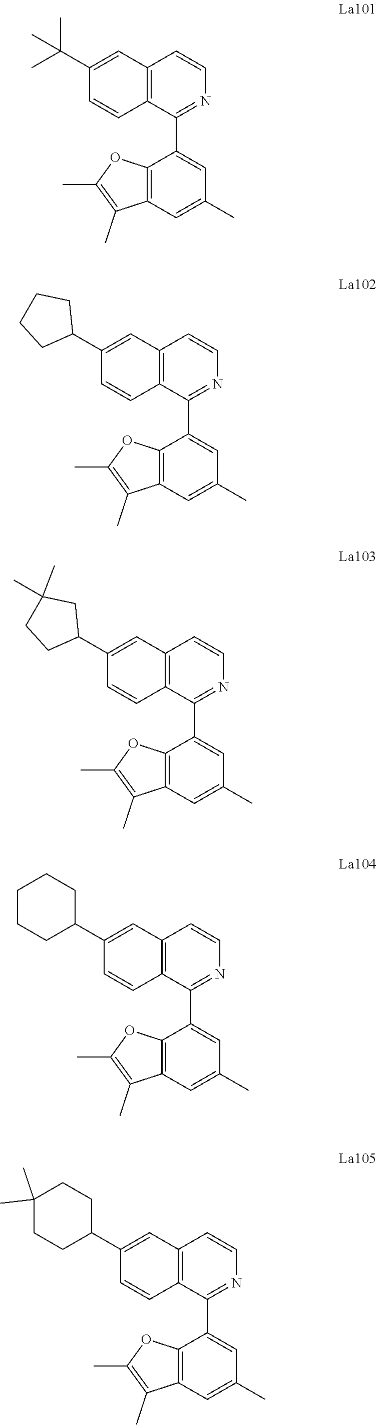

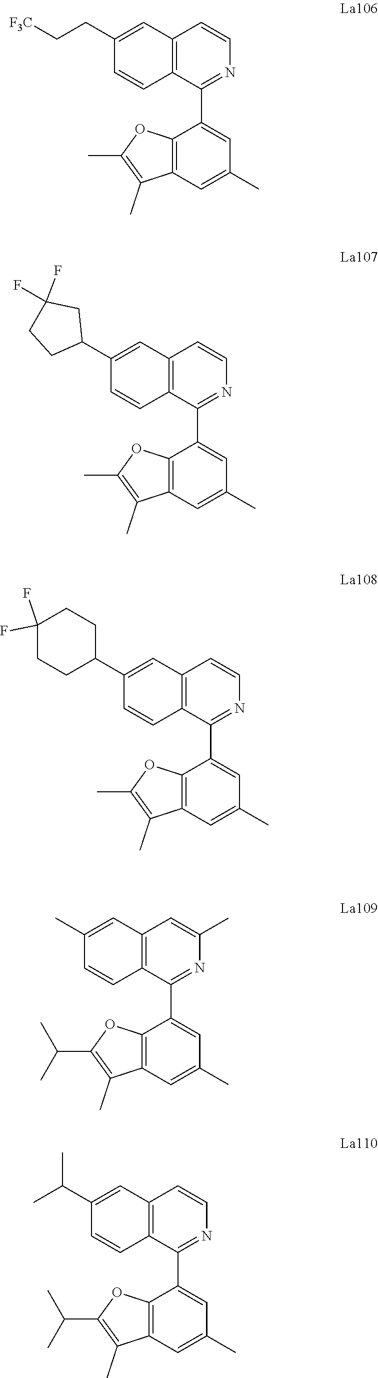

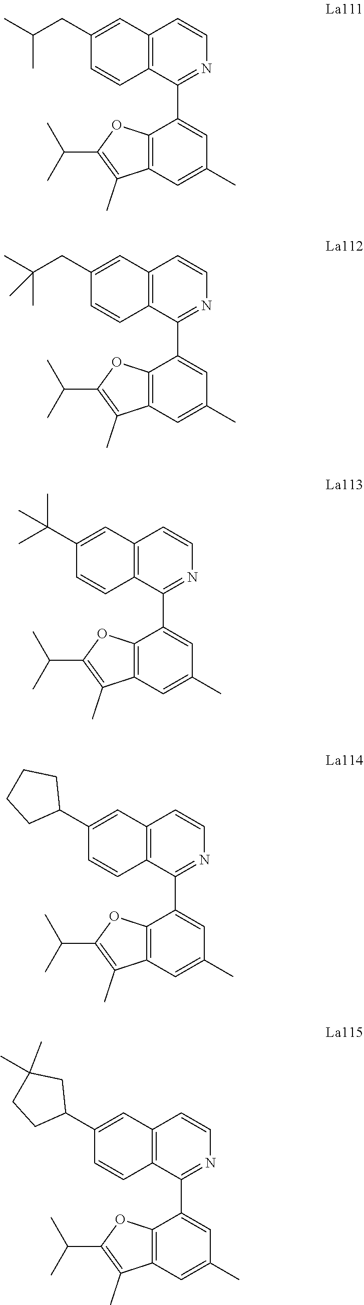

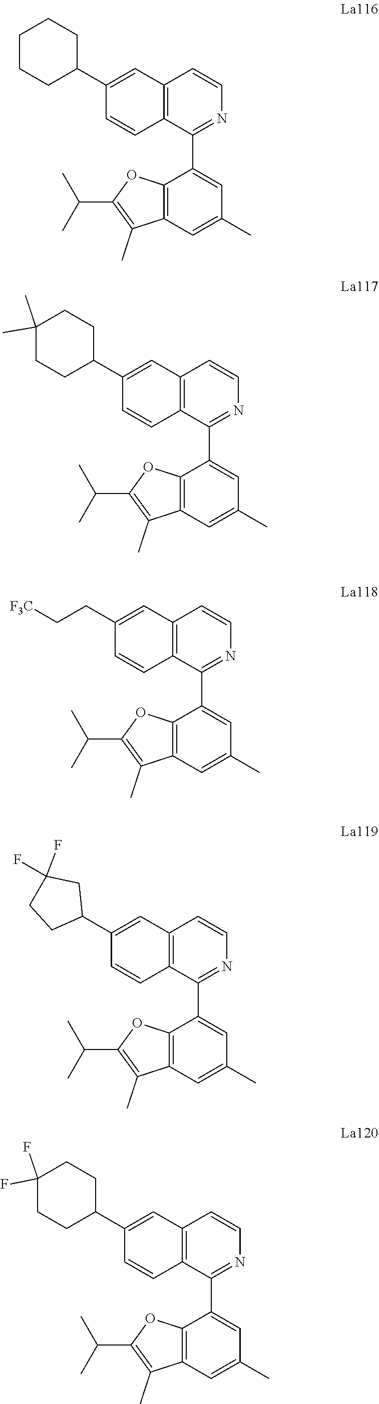

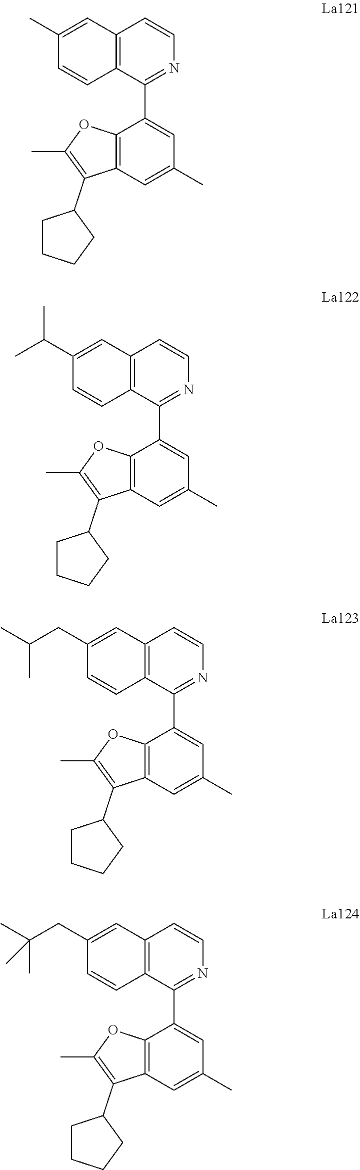

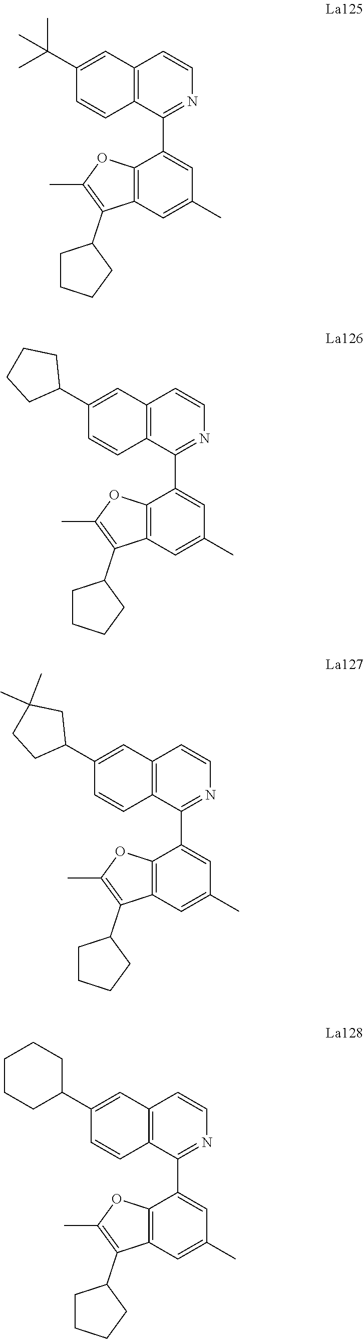

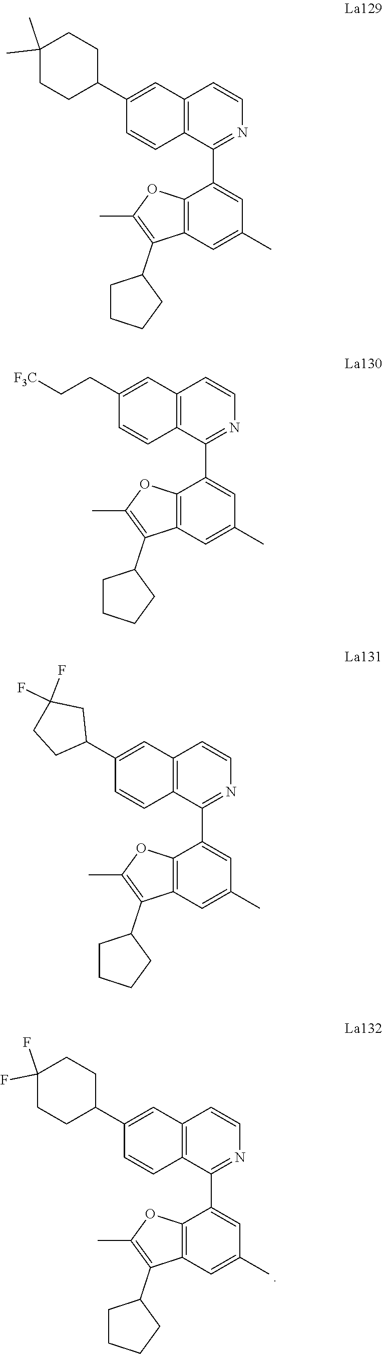

14. The organometallic iridium compound according to claim 2, wherein the Lb has one of the following structural formulas, or is partially or completely deuterated or fluorinated correspondingly,

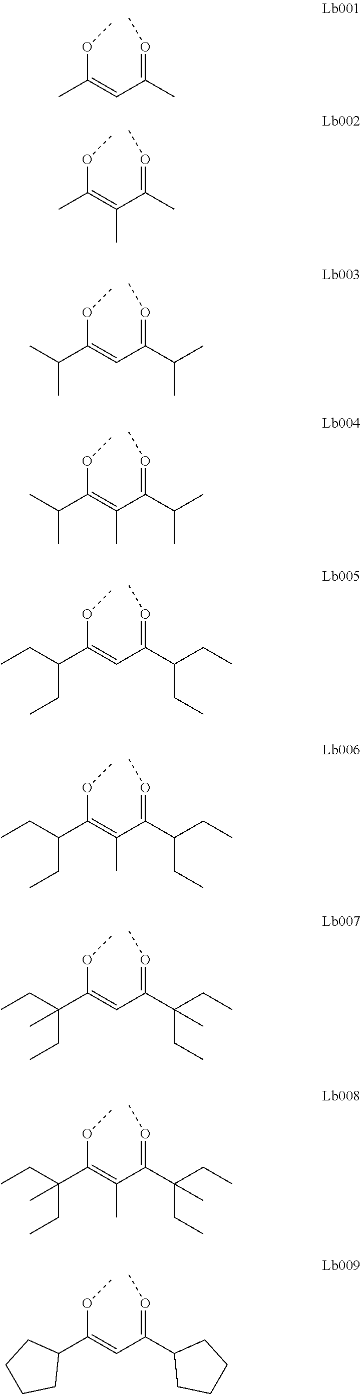

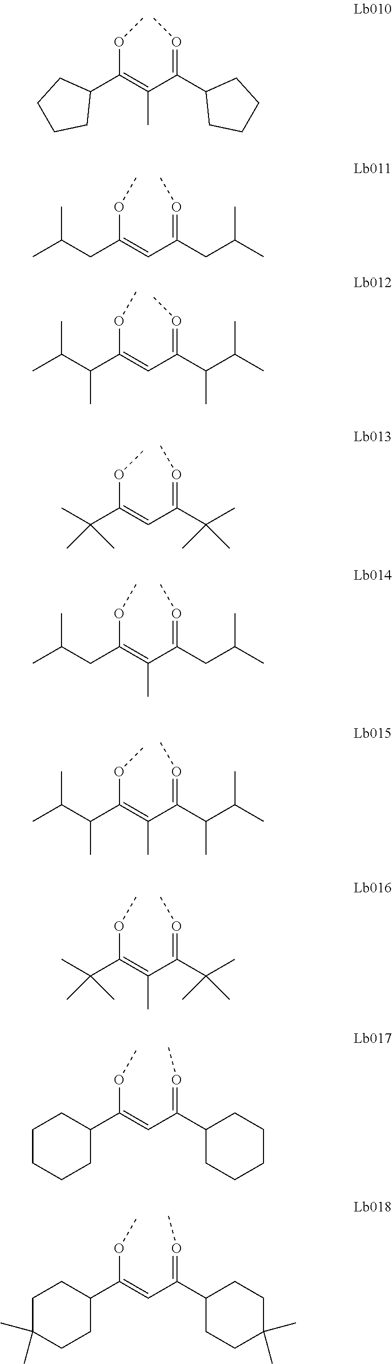

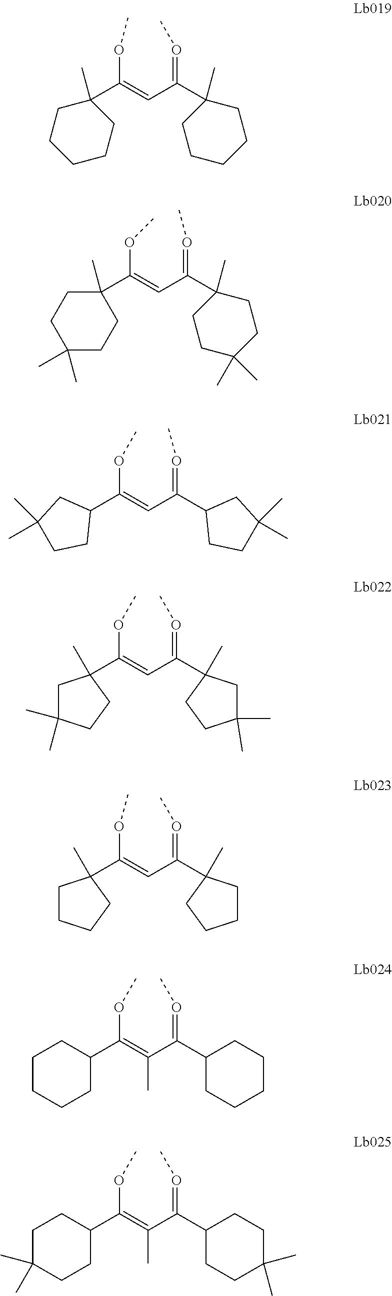

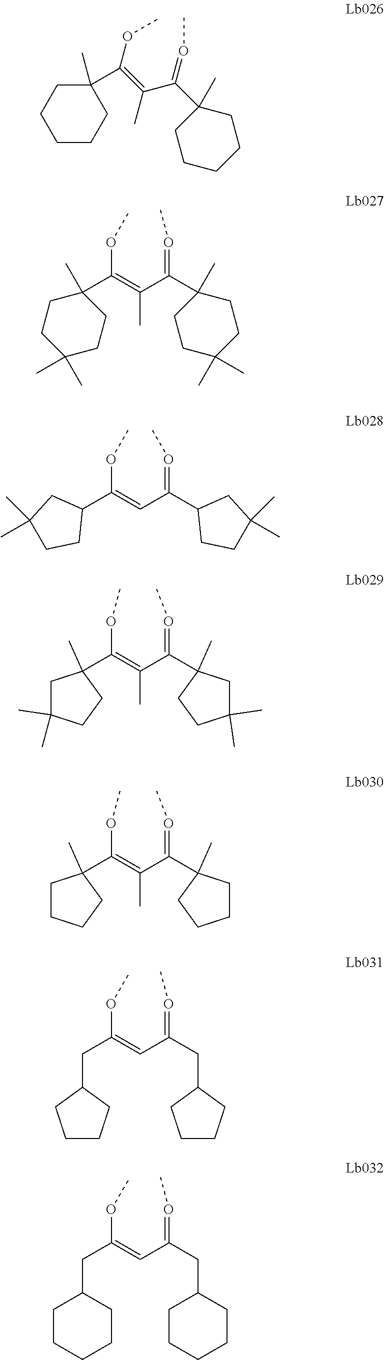

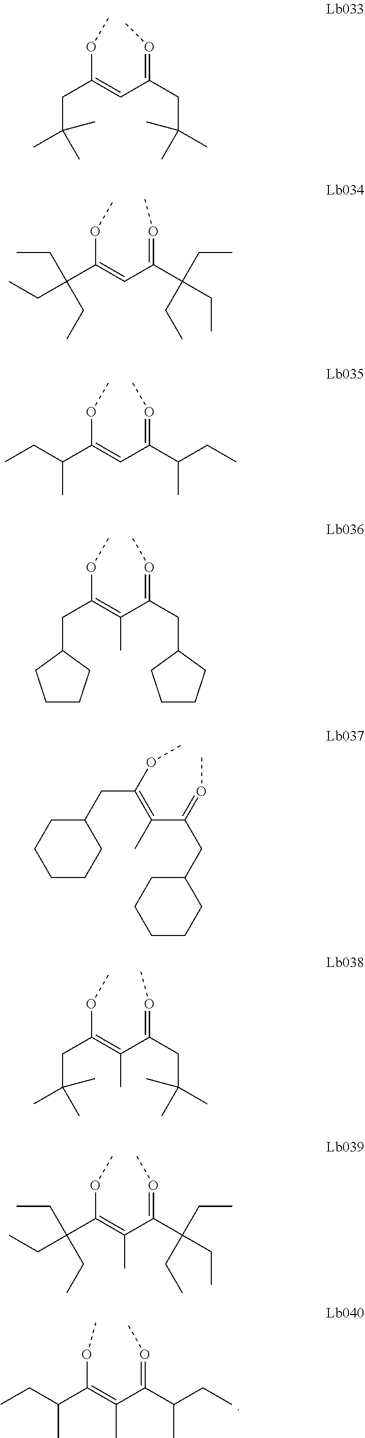

15. The organometallic iridium compound according to claim 2, wherein the Lc has one of the following structural formulas, or is partially or completely deuterated or fluorinated correspondingly,

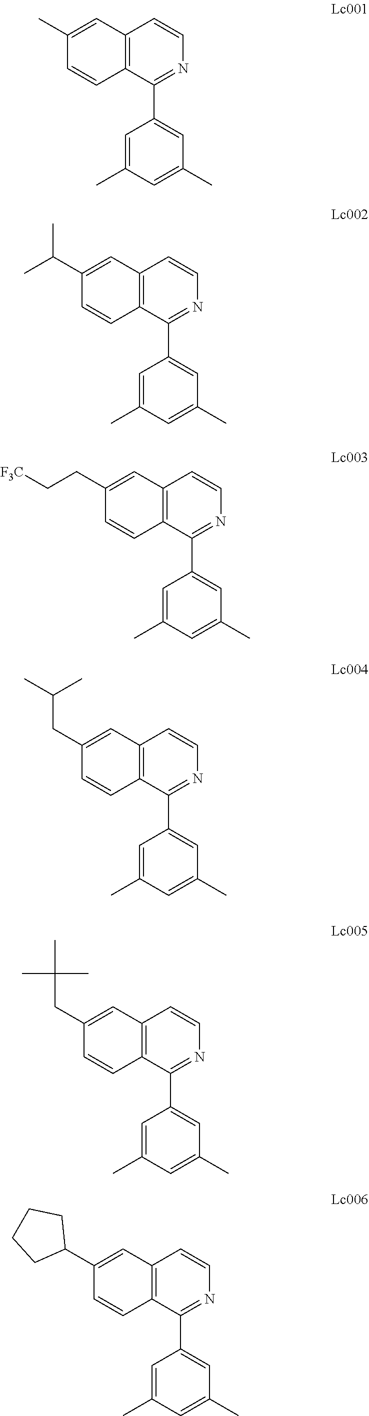

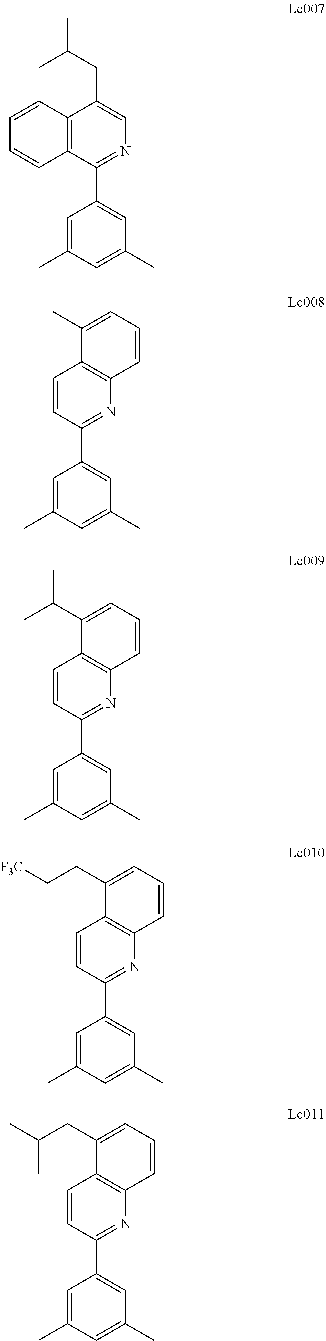

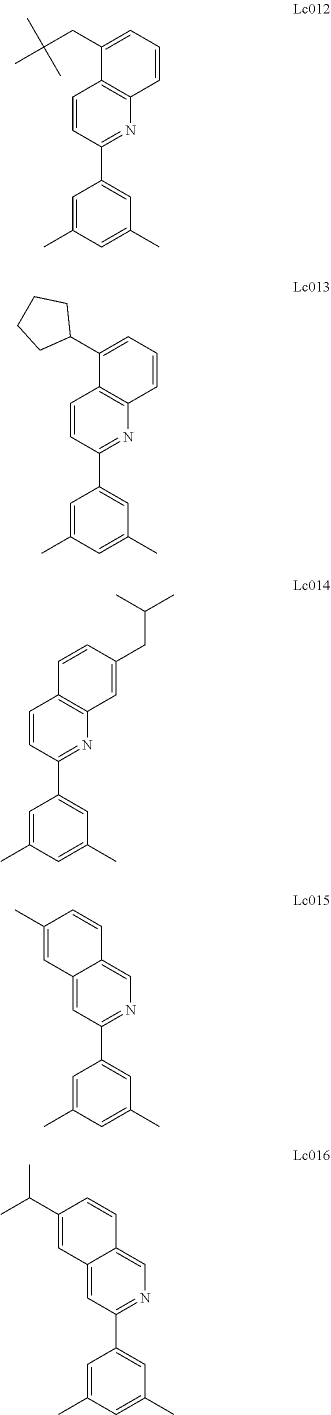

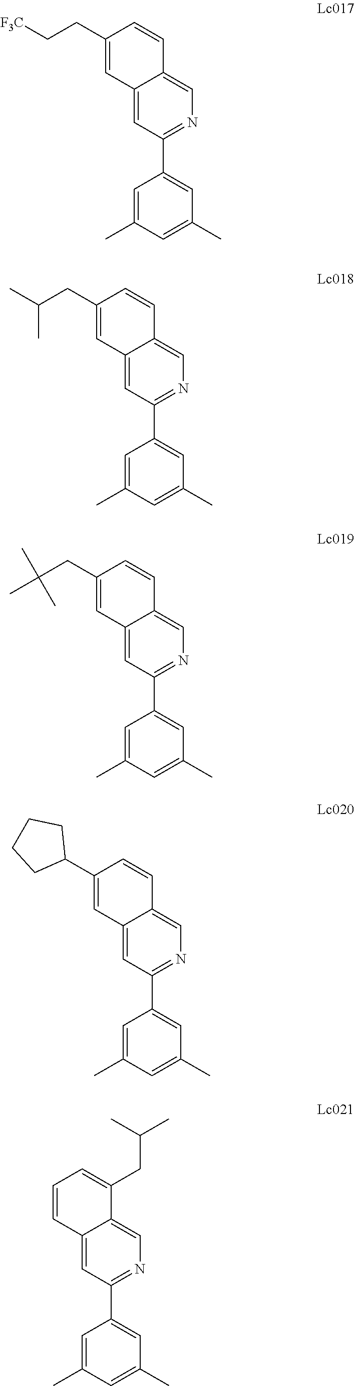

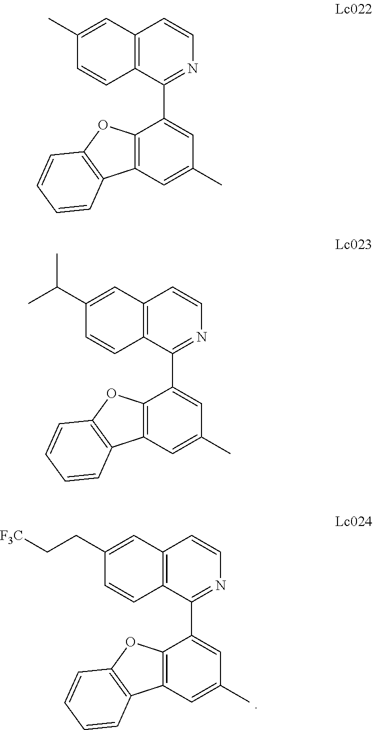

16. Application of the organometallic iridium compound according to any one of claims 1-15 in an organic electroluminescent device.

17. The application according to claim 16, wherein the organometallic iridium compound according to any one of claims 1-15 is used as a red light-emitting doping material for a light-emitting layer in the organic electroluminescent device.
